(19) United States
(12) Patent Application Publication
(10) Pub. No.: US 2025/0355357 A1
(43) Pub. Date: Nov. 20, 2025

(54) SILICON-CONTAINING RESIST UNDERLAYER FILM-FORMING COMPOSITION

(71) Applicant: NISSAN CHEMICAL CORPORATION, Tokyo (JP)

(72) Inventors: Kodai KATO, Toyama-shi (JP); Wataru SHIBAYAMA, Toyama-shi (JP)

(73) Assignee: NISSAN CHEMICAL CORPORATION, Tokyo (JP)

(21) Appl. No.: 18/285,324

(22) PCT Filed: Mar. 30, 2022
(86) PCT No.: PCT/JP2022/016230

§ 371 Date: Mar. 21, 2024

(30) Foreign Application Priority Data
Mar. 31, 2021 (JP) 2021-062394
Jun. 18, 2021 (JP) 2021-101439

(51) Int. Cl. G03F 7/075; B01D 39/16; C09D 183/04; G03F 7/16; H01L 21/311

(52) U.S. Cl. CPC G03F 7/0757; B01D 39/16; C09D 183/04; G03F 7/168; H01L 21/31144; B01D 2239/1216

(57) ABSTRACT

A silicon-containing resist underlayer film-forming composition for forming a silicon-containing resist underlayer film that enables the formation of a good resist pattern causing no pattern collapse even in ultra-fine patterning at a resolution (hp) of less than 25 nm, the composition comprising: [A] a polysiloxane containing a siloxane unit structure having an ester structure; and [B] a solvent.

### TECHNICAL FIELD

The present invention relates to a resist underlayer film-forming composition. More particularly, the present invention provides a silicon-containing resist underlayer film-forming composition capable of forming a silicon-containing resist underlayer film that has favorable lithographic properties and can be readily removed with a chemical.

### BACKGROUND ART

Fine processing by lithography using photoresists has been conventionally performed in the production of semiconductor devices. The fine processing is a processing method involving formation of a photoresist thin film on a semiconductor substrate (e.g., a silicon wafer); irradiation of the thin film with active rays (e.g., ultraviolet rays) through a mask pattern having a semiconductor device pattern drawn thereon; development of the irradiated thin film; and etching of the substrate with the resultant photoresist pattern serving as a protective film, to thereby form, on the surface of the substrate, fine irregularities corresponding to the pattern.

Active rays having a shorter wavelength have tended to be used (i.e., shifting from KrF excimer laser (248 nm) to ArF excimer laser (193 nm)) in association with an increase in the degree of integration of semiconductor devices. Furthermore, attempts have been made to develop an exposure technique using EUV (extreme ultraviolet) rays or electron beams. The use of such active rays having a shorter wavelength causes a serious problem in terms of reflection of active rays from a semiconductor substrate. In order to avoid such a problem, there has been widely used a method involving disposing a resist underlayer film called anti-reflective coating (Bottom Anti-Reflective Coating, BARC) between a photoresist and a to-be-processed substrate. Thus, a proposal has been made to use an underlayer film containing, for example, silicon as such a resist underlayer film (e.g., Patent Document 1).

In recent years, a keen demand has arisen for thinning of a resist in association with miniaturization of a resist pattern in state-of-the-art semiconductor devices. In particular, a tri-layer (including a resist film, a silicon-containing resist underlayer film, and an organic underlayer film) process requires favorable lithographic properties of the resist on the silicon-containing resist underlayer film.

### PRIOR ART DOCUMENTS

### Patent Documents

Patent Document 1: JP 2007-163846 A

### SUMMARY OF THE INVENTION

### Problems to be Solved by the Invention

Due to the aforementioned further thinning of a resist, pattern collapse and pattern shape deterioration have been occasionally observed even in a system that has conventionally been able to form a good resist pattern. Thus, the ability of a resist underlayer film to provide favorable lithographic properties is important in a recent semiconductor production process where a film used for a pattern has become noticeably thinner.

In particular, ultrafine patterning (e.g., EUV lithography) wherein the half pitch (hp) (i.e., an index of resolution) is 10 to 25 nm poses a serious problem in that a pattern of high aspect ratio collapses in association with miniaturization of the pattern. Under such circumstances, a resist underlayer film-forming composition containing a silane compound having a special functional group (e.g., norbornene ring) and a resist underlayer film formed from the composition have been proposed for the purpose of imparting high lithographic properties. However, such a silane compound having a special functional group is generally difficult to obtain and is expensive, and a lithography material that can achieve both high lithographic properties and reduced production cost has not yet been realized.

The present invention has been made in view of the above-described circumstances, and an object of the present invention is to provide a silicon-containing resist underlayer film-forming composition for forming a silicon-containing resist underlayer film that enables formation of a good resist pattern without causing pattern collapse even in ultrafine patterning with a resolution (hp) of less than 25 nm, even less than 20 nm.

### Means for Solving the Problems

A first aspect of the present invention is a silicon-containing resist underlayer film-forming composition comprising:
[A] a polysiloxane containing a siloxane unit structure having an ester structure; and
[B] a solvent.

A second aspect of the present invention is the silicon-containing resist underlayer film-forming composition according to the first aspect, wherein the siloxane unit structure having an ester structure contained in the polysiloxane [A] has an ester structure formed by reaction between a hydroxy group and/or an epoxy group and a compound selected from the group consisting of a carboxylic acid, a dicarboxylic acid, and a dicarboxylic anhydride.

A third aspect of the present invention is the silicon-containing resist underlayer film-forming composition according to the second aspect, wherein the carboxylic acid, the dicarboxylic acid, and the dicarboxylic anhydride have at least one group selected from the group consisting of an alicyclic group, an aromatic ring group, a cyano group, an alkenyl group, and an alkynyl group.

A fourth aspect of the present invention is the silicon-containing resist underlayer film-forming composition according to any one of the first to third aspects, wherein the amount of the siloxane unit structure having an ester structure contained in the polysiloxane [A] is 0.1% by mole to 10% by mole relative to the total amount by mole of all siloxane unit structures contained in the polysiloxane [A].

A fifth aspect of the present invention is the silicon-containing resist underlayer film-forming composition according to any one of the first to fourth aspects, wherein the polysiloxane [A] further contains a siloxane unit structure having an organic group containing a quaternary ammonium nitrate structure.

A sixth aspect of the present invention is the silicon-containing resist underlayer film-forming composition according to the first aspect, wherein the polysiloxane [A] contains a hydrolysis condensate [I] containing a siloxane unit structure having an ester structure; and the hydrolysis condensate [I] is a hydrolysis condensate of a hydrolyzable silane containing at least one hydrolyzable silane of the following Formula (1):

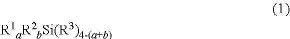

(wherein R¹ is a group bonded to the silicon atom and is of the following Formula (1-1):

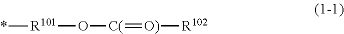

(in Formula (1-1), R¹⁰¹ is a C₂₋₂₀ alkylene group, C₆₋₁₂ arylene group, or combination of these that possibly contains an ether bond or is substitutable with a hydroxy group, and R¹⁰² is an organic group having at least one group selected from the group consisting of a substitutable alicyclic group, a substitutable aromatic ring group, a cyano group, an alkenyl group, and an alkynyl group);
R² is a group bonded to the silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, a sulfonyl group, or a cyano group, or any combination of these;
R³ is a group or atom bonded to the silicon atom, and is each independently an alkoxy group, an aralkyloxy group, an acyloxy group, or a halogen atom;
a is an integer of 1; b is an integer of 0 to 2; and a+b is an integer of 1 to 3).

A seventh aspect of the present invention is the silicon-containing resist underlayer film-forming composition according to the sixth aspect, wherein the amount of at least one hydrolyzable silane of Formula (1) contained in the hydrolyzable silane is 0.1% by mole to 10% by mole relative to the total amount by mole of all hydrolyzable silanes contained in the hydrolyzable silane.

An eighth aspect of the present invention is the silicon-containing resist underlayer film-forming composition according to the sixth or seventh aspect, wherein the polysiloxane [A] contains a hydrolysis condensate [I-1] containing a siloxane unit structure having an ester structure and a siloxane unit structure having an organic group containing a quaternary ammonium nitrate structure; and the hydrolysis condensate [I-1] is a hydrolysis condensate of a mixture of the hydrolyzable silane of Formula (1), a hydrolyzable silane containing a hydrolyzable silane of the following Formula (2) containing an amino group-containing organic group, and nitric acid:

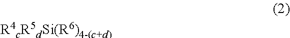

(wherein R⁴ is a group bonded to the silicon atom, and is an amino group-containing organic group;
R⁵ is a group bonded to the silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an acryloyl group, a methacryloyl group, a mercapto group, an amino group, an amide group, an alkoxy group, a sulfonyl group, or a cyano group, or any combination of these;
R⁶ is a group or atom bonded to the silicon atom, and is each independently an alkoxy group, an aralkyloxy group, an acyloxy group, or a halogen atom;
c is an integer of 1; d is an integer of 0 to 2; and c+d is an integer of 1 to 3).

A ninth aspect of the present invention is the silicon-containing resist underlayer film-forming composition according to any one of the first to eighth aspects, wherein the composition comprises a curing catalyst.

A tenth aspect of the present invention is the silicon-containing resist underlayer film-forming composition according to any one of the first to ninth aspects, wherein the solvent [B] contains water.

An eleventh aspect of the present invention is the silicon-containing resist underlayer film-forming composition according to any one of the first to tenth aspects, wherein the composition further comprises a pH adjuster.

A twelfth aspect of the present invention is the silicon-containing resist underlayer film-forming composition according to any one of the first to eleventh aspects, wherein the composition further comprises a metal oxide.

A thirteenth aspect of the present invention is the silicon-containing resist underlayer film-forming composition according to any one of the first to twelfth aspects, wherein the composition is used for formation of a resist underlayer film for EUV lithography.

A fourteenth aspect of the present invention is a resist underlayer film, which is a cured product of the silicon-containing resist underlayer film-forming composition according to any one of the first to thirteenth aspects.

A fifteenth aspect of the present invention is a semiconductor processing substrate comprising a semiconductor substrate and the resist underlayer film according to the fourteenth aspect.

A sixteenth aspect of the present invention is a semiconductor element production method comprising:
a step of forming an organic underlayer film on a substrate;
a step of forming, on the organic underlayer film, a silicon-containing resist underlayer film from the silicon-containing resist underlayer film-forming composition according to any one of the first to thirteenth aspects; and
a step of forming a resist film on the silicon-containing resist underlayer film.

A seventeenth aspect of the present invention is the production method according to the sixteenth aspect, wherein the step of forming a silicon-containing resist underlayer film involves the use of the silicon-containing resist underlayer film-forming composition subjected to filtration with a nylon filter.

An eighteenth aspect of the present invention is a pattern formation method comprising:
a step of forming an organic underlayer film on a semiconductor substrate;
a step of applying, onto the organic underlayer film, the silicon-containing resist underlayer film-forming composition according to any one of the first to thirteenth aspects, and baking the composition, to thereby form a silicon-containing resist underlayer film;
a step of applying a resist film-forming composition onto the silicon-containing resist underlayer film, to thereby form a resist film;
a step of exposing the resist film to light, and developing the resist film, to thereby form a resist pattern;
a step of etching the silicon-containing resist underlayer film with the resist pattern as a mask; and
a step of etching the organic underlayer film with the patterned silicon-containing resist underlayer film as a mask.

### Effects of the Invention

The present invention can provide a silicon-containing resist underlayer film-forming composition capable of forming a silicon-containing resist underlayer film that enables formation of a good resist pattern without causing pattern collapse even in ultrafine patterning with a resolution (hp) of less than 25 nm.

Also, the present invention can provide a silicon-containing resist underlayer film-forming composition that can be suitably used in a lithographic process requiring further thinning and miniaturization and can achieve a reduction in production cost.

### MODES FOR CARRYING OUT THE INVENTION

The present invention is directed to a composition for forming a silicon-containing resist underlayer film that can prevent resist pattern collapse in association with thinning and miniaturization of a semiconductor system, and relates to a silicon-containing resist underlayer film-forming composition (hereinafter may be referred to simply as “resist underlayer film-forming composition”) containing [A] a polysiloxane having an ester structure and [B] a solvent.

The present invention will next be described in detail.

### [A] Polysiloxane

No particular limitation is imposed on the polysiloxane [A] used in the present invention, so long as it is a polymer having a siloxane bond and containing a siloxane unit structure having an ester structure.

In a preferred embodiment, the aforementioned ester structure may be an ester structure formed by reaction between a hydroxy group and/or epoxy group bonded to a hydrocarbon group bonded to the silicon atom and a compound selected from the group consisting of a carboxylic acid, a dicarboxylic acid, and a dicarboxylic anhydride (hereinafter the compound may be referred to as “carboxylic acid compound”).

The aforementioned polysiloxane [A] may be a polysiloxane containing a siloxane unit structure further having an organic group containing a quaternary ammonium nitrate structure besides the aforementioned siloxane unit structure having an ester structure.

The aforementioned polysiloxane [A] may have a structure having a cage-shaped, ladder-shaped, linear, or branched main chain. The aforementioned polysiloxane may be a commercially available polysiloxane.

The aforementioned polysiloxane [A] contained in the silicon-containing resist underlayer film-forming composition of the present invention contains, for example, a hydrolysis condensate of a hydrolyzable silane.

In the present invention, the hydrolysis condensate (i.e., product of hydrolytic condensation) includes a polyorganosiloxane polymer which is a condensate prepared through complete condensation, and a polyorganosiloxane polymer which is a partial hydrolysis condensate prepared through incomplete condensation. Such a partial hydrolysis condensate is a polymer prepared through hydrolysis and condensation of a hydrolyzable silane compound, as in the case of a condensate prepared through complete condensation. However, the partial hydrolysis condensate contains remaining Si—OH groups, due to partial or incomplete hydrolysis and condensation of the silane compound. The silicon-containing resist underlayer film-forming composition of the present invention may contain, besides the hydrolysis condensate, an uncondensed hydrolysate (complete hydrolysate or partial hydrolysate) or a remaining monomer (hydrolyzable silane compound).

In the present specification, “hydrolyzable silane” may be referred to simply as “silane compound.”

As described below, the aforementioned hydrolyzable silane may contain a hydrolyzable silane of the following Formula (1), and, if desired, a hydrolyzable silane of the following Formula (2), and may further contain an additional hydrolyzable silane as appropriate.

The polysiloxane [A] may contain a hydrolysis condensate [I] containing a siloxane unit structure having an ester structure.

The hydrolysis condensate [I] may be, for example, a hydrolysis condensate of a hydrolyzable silane containing at least one hydrolyzable silane of the following Formula (1).

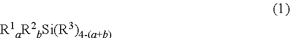

In Formula (1), R¹ is a group bonded to the silicon atom and is of the following Formula (1-1).

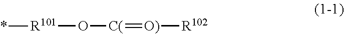

In Formula (1-1), R¹⁰¹ is a C₂₋₂₀ alkylene group, C₆₋₁₂ arylene group, or combination of these that possibly contains an ether bond and is substitutable with a hydroxy group.
R¹⁰² is an organic group having at least one group selected from the group consisting of a substitutable alicyclic group, a substitutable aromatic ring group, a cyano group, an alkenyl group, and an alkynyl group.

Specific examples of the C₂₋₂₀ alkylene group of R¹⁰¹ include, but are not limited to, linear alkylene groups such as ethylene group, trimethylene group, methylethylene group, tetramethylene group, pentamethylene group, hexamethylene group, heptamethylene group, octamethylene group, nonamethylene group, and decamethylene group; branched alkylene groups such as 1-methyltrimethylene group, 2-methyltrimethylene group, 1,1-dimethylethylene group, 1-methyltetramethylene group, 2-methyltetramethylene group, 1,1-dimethyltrimethylene group, 1,2-dimethyltrimethylene group, 2,2-dimethyltrimethylene group, and 1-ethyltrimethylene group; and cyclic alkylene groups such as 1,2-cyclopropanediyl group, 1,2-cyclobutanediyl group, 1,3-cyclobutanediyl group, 1,2-cyclohexanediyl group, 1,3-cyclohexanediyl group, and norbornanediyl group.

Specific examples of the C₆₋₁₂ arylene group of R¹⁰¹ include, but are not limited to, 1,2-phenylene group, 1,3-phenylene group, 1,4-phenylene group; groups derived from a condensed-ring aromatic hydrocarbon compound through removal of two hydrogen atoms on the aromatic ring, such as 1,5-naphthalenediyl group, 1,8-naphthalenediyl group, 2,6-naphthalenediyl group, 2,7-naphthalenediyl group, 1,2-anthracenediyl group, 1,3-anthracenediyl group, 1,4-anthracenediyl group, 1,5-anthracenediyl group, 1,6-anthracenediyl group, 1,7-anthracenediyl group, 1,8-anthracenediyl group, 2,3-anthracenediyl group, 2,6-anthracenediyl group, 2,7-anthracenediyl group, 2,9-anthracenediyl group, 2,10-anthracenediyl group, and 9,10-anthracenediyl group; and groups derived from a linked-ring aromatic hydrocarbon compound through removal of two hydrogen atoms on the aromatic ring, such as 4,4′-biphenyldiyl group and 4,4″-p-terphenyldiyl group.

R¹⁰¹ may be any combination of the aforementioned alkylene groups, the aforementioned arylene groups, or the aforementioned alkylene groups and arylene groups, and may contain one or more ether bonds. One or more hydrogen atoms of each of the aforementioned alkylene group and arylene group may be substituted with a hydroxy group.

Examples of the alicyclic group of R¹⁰² include groups derived through removal of one hydrogen atom from a cyclic group such as norbornene, bicyclo[2.2.2]-5-octene, or 3,6-epoxy-1-cyclohexene, and examples of the aromatic ring group include phenyl group.

Each of these alicyclic group and aromatic ring group may be substituted with, for example, an alkyl group such as a methyl group or an ethyl group, a carboxyl group, or a hydroxy group.

Examples of the alkenyl group of R¹⁰² include, but are not limited to, C₂₋₁₀ alkenyl groups such as ethenyl group, propenyl group, butenyl group, pentenyl group, hexenyl group, heptenyl group, octenyl group, and nonenyl group. Examples of the alkynyl group of R¹⁰² include, but are not limited to, C₂₋₁₀ alkynyl groups such as ethynyl group, propynyl group, butynyl group, pentynyl group, hexynyl group, heptynyl group, octynyl group, nonynyl group, and decynyl group.

R² is a group bonded to the silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, a sulfonyl group, or a cyano group, or any combination of these.

R³ is a group or atom bonded to the silicon atom, and is each independently an alkoxy group, an aralkyloxy group, an acyloxy group, or a halogen atom.

In Formula (1), a is an integer of 1, b is an integer of 0 to 2, and a+b is an integer of 1 to 3.

In Formula (1), the alkyl group is, for example, a linear or branched alkyl group having a carbon atom number of 1 to 10. Examples of the alkyl group include methyl group, ethyl group, n-propyl group, i-propyl group, n-butyl group, i-butyl group, s-butyl group, t-butyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, and 1-ethyl-2-methyl-n-propyl group.

The alkyl group may be a cyclic alkyl group. Examples of the cyclic alkyl group having a carbon atom number of 3 to 10 include cycloalkyl groups, such as cyclopropyl group, cyclobutyl group, 1-methyl-cyclopropyl group, 2-methyl-cyclopropyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, and 2-ethyl-3-methyl-cyclopropyl group; and bridged cyclic cycloalkyl groups, such as bicyclobutyl group, bicyclopentyl group, bicyclohexyl group, bicycloheptyl group, bicyclooctyl group, bicyclononyl group, and bicyclodecyl group.

The aryl group may be a phenyl group, a monovalent group derived from a condensed-ring aromatic hydrocarbon compound through removal of one hydrogen atom, or a monovalent group derived from a linked-ring aromatic hydrocarbon compound through removal of one hydrogen atom. No particular limitation is imposed on the carbon atom number of the aryl group, but the carbon atom number is preferably 40 or less, more preferably 30 or less, still more preferably 20 or less.

Examples of the aryl group include, but are not limited to, C₆₋₂₀ aryl groups, such as phenyl group, 1-naphthyl group, 2-naphthyl group, 1-anthryl group, 2-anthryl group, 9-anthryl group, 1-phenanthryl group, 2-phenanthryl group, 3-phenanthryl group, 4-phenanthryl group, 9-phenanthryl group, 1-naphthacenyl group, 2-naphthacenyl group, 5-naphthacenyl group, 2-chrysenyl group, 1-pyrenyl group, 2-pyrenyl group, pentacenyl group, benzopyrenyl group, triphenylenyl group, biphenyl-2-yl group (o-biphenylyl group), biphenyl-3-yl group (m-biphenylyl group), biphenyl-4-yl group (p-biphenylyl group), p-terphenyl-4-yl group, m-terphenyl-4-yl group, o-terphenyl-4-yl group, 1,1′-binaphthyl-2-yl group, and 2,2′-binaphthyl-1-yl group.

The aralkyl group is an alkyl group substituted with an aryl group, and specific examples of the aryl group and the alkyl group are the same as those described above. No particular limitation is imposed on the carbon atom number of the aralkyl group, but the carbon atom number is preferably 40 or less, more preferably 30 or less, still more preferably 20 or less.

Specific examples of the aralkyl group include, but are not limited to, phenylmethyl group (benzyl group), 2-phenylethylene group, 3-phenyl-n-propyl group, 4-phenyl-n-butyl group, 5-phenyl-n-pentyl group, 6-phenyl-n-hexyl group, 7-phenyl-n-heptyl group, 8-phenyl-n-octyl group, 9-phenyl-n-nonyl group, and 10-phenyl-n-decyl group.

The aforementioned halogenated alkyl group, halogenated aryl group, or halogenated aralkyl group is an alkyl group, aryl group, or aralkyl group substituted with one or more halogen atoms, and specific examples of the alkyl group, the aryl group, and the aralkyl group are the same as those described above.

Examples of the halogen atom include a fluorine atom, a chlorine atom, a bromine atom, and an iodine atom.

No particular limitation is imposed on the carbon atom number of the halogenated alkyl group, but the carbon atom number is preferably 40 or less, more preferably 30 or less, still more preferably 20 or less, much more preferably 10 or less.

Specific examples of the halogenated alkyl group include, but are not limited to, monofluoromethyl group, difluoromethyl group, trifluoromethyl group, bromodifluoromethyl group, 2-chloroethyl group, 2-bromoethyl group, 1,1-difluoroethyl group, 2,2,2-trifluoroethyl group, 1,1,2,2-tetrafluoroethyl group, 2-chloro-1,1,2-trifluoroethyl group, pentafluoroethyl group, 3-bromopropyl group, 2,2,3,3-tetrafluoropropyl group, 1,1,2,3,3,3-hexafluoropropyl group, 1,1,1,3,3,3-hexafluoropropan-2-yl group, 3-bromo-2-methylpropyl group, 4-bromobutyl group, and perfluoropentyl group.

No particular limitation is imposed on the carbon atom number of the halogenated aryl group, but the carbon atom number is preferably 40 or less, more preferably 30 or less, still more preferably 20 or less.

Specific examples of the halogenated aryl group include, but are not limited to, 2-fluorophenyl group, 3-fluorophenyl group, 4-fluorophenyl group, 2,3-difluorophenyl group, 2,4-difluorophenyl group, 2,5-difluorophenyl group, 2,6-difluorophenyl group, 3,4-difluorophenyl group, 3,5-difluorophenyl group, 2,3,4-trifluorophenyl group, 2,3,5-trifluorophenyl group, 2,3,6-trifluorophenyl group, 2,4,5-trifluorophenyl group, 2,4,6-trifluorophenyl group, 3,4,5-trifluorophenyl group, 2,3,4,5-tetrafluorophenyl group, 2,3,4,6-tetrafluorophenyl group, 2,3,5,6-tetrafluorophenyl group, pentafluorophenyl group, 2-fluoro-1-naphthyl group, 3-fluoro-1-naphthyl group, 4-fluoro-1-naphthyl group, 6-fluoro-1-naphthyl group, 7-fluoro-1-naphthyl group, 8-fluoro-1-naphthyl group, 4,5-difluoro-1-naphthyl group, 5,7-difluoro-1-naphthyl group, 5,8-difluoro-1-naphthyl group, 5,6,7,8-tetrafluoro-1-naphthyl group, heptafluoro-1-naphthyl group, 1-fluoro-2-naphthyl group, 5-fluoro-2-naphthyl group, 6-fluoro-2-naphthyl group, 7-fluoro-2-naphthyl group, 5,7-difluoro-2-naphthyl group, heptafluoro-2-naphthyl group, and groups prepared by arbitrary substitution of a fluorine atom (fluoro group) of any of the aforementioned groups with a chlorine atom (chloro group), a bromine atom (bromo group), or an iodine atom (iodo group).

No particular limitation is imposed on the carbon atom number of the halogenated aralkyl group, but the carbon atom number is preferably 40 or less, more preferably 30 or less, still more preferably 20 or less.

Specific examples of the halogenated aralkyl group include, but are not limited to, 2-fluorobenzyl group, 3-fluorobenzyl group, 4-fluorobenzyl group, 2,3-difluorobenzyl group, 2,4-difluorobenzyl group, 2,5-difluorobenzyl group, 2,6-difluorobenzyl group, 3,4-difluorobenzyl group, 3,5-difluorobenzyl group, 2,3,4-trifluorobenzyl group, 2,3,5-trifluorobenzyl group, 2,3,6-trifluorobenzyl group, 2,4,5-trifluorobenzyl group, 2,4,6-trifluorobenzyl group, 2,3,4,5-tetrafluorobenzyl group, 2,3,4,6-tetrafluorobenzyl group, 2,3,5,6-tetrafluorobenzyl group, 2,3,4,5,6-pentafluorobenzyl group, and groups prepared by arbitrary substitution of a fluorine atom (fluoro group) of any of the aforementioned groups with a chlorine atom (chloro group), a bromine atom (bromo group), or an iodine atom (iodo group).

The aforementioned alkoxyalkyl group, alkoxyaryl group, or alkoxyaralkyl group is an alkyl group, aryl group, or aralkyl group substituted with one or more alkoxy groups, and specific examples of the alkyl group, the aryl group, and the aralkyl group are the same as those described above.

The alkoxy group may be, for example, an alkoxy group having a linear, branched, or cyclic alkyl moiety having a carbon atom number of 1 to 20. Examples of the linear or branched alkoxy group include methoxy group, ethoxy group, n-propoxy group, i-propoxy group, n-butoxy group, i-butoxy group, s-butoxy group, t-butoxy group, n-pentyloxy group, 1-methyl-n-butoxy group, 2-methyl-n-butoxy group, 3-methyl-n-butoxy group, 1,1-dimethyl-n-propoxy group, 1,2-dimethyl-n-propoxy group, 2,2-dimethyl-n-propoxy group, 1-ethyl-n-propoxy group, n-hexyloxy group, 1-methyl-n-pentyloxy group, 2-methyl-n-pentyloxy group, 3-methyl-n-pentyloxy group, 4-methyl-n-pentyloxy group, 1,1-dimethyl-n-butoxy group, 1,2-dimethyl-n-butoxy group, 1,3-dimethyl-n-butoxy group, 2,2-dimethyl-n-butoxy group, 2,3-dimethyl-n-butoxy group, 3,3-dimethyl-n-butoxy group, 1-ethyl-n-butoxy group, 2-ethyl-n-butoxy group, 1,1,2-trimethyl-n-propoxy group, 1,2,2-trimethyl-n-propoxy group, 1-ethyl-1-methyl-n-propoxy group, and 1-ethyl-2-methyl-n-propoxy group. Examples of the cyclic alkoxy group include cyclopropoxy group, cyclobutoxy group, 1-methyl-cyclopropoxy group, 2-methyl-cyclopropoxy group, cyclopentyloxy group, 1-methyl-cyclobutoxy group, 2-methyl-cyclobutoxy group, 3-methyl-cyclobutoxy group, 1,2-dimethyl-cyclopropoxy group, 2,3-dimethyl-cyclopropoxy group, 1-ethyl-cyclopropoxy group, 2-ethyl-cyclopropoxy group, cyclohexyloxy group, 1-methyl-cyclopentyloxy group, 2-methyl-cyclopentyloxy group, 3-methyl-cyclopentyloxy group, 1-ethyl-cyclobutoxy group, 2-ethyl-cyclobutoxy group, 3-ethyl-cyclobutoxy group, 1,2-dimethyl-cyclobutoxy group, 1,3-dimethyl-cyclobutoxy group, 2,2-dimethyl-cyclobutoxy group, 2,3-dimethyl-cyclobutoxy group, 2,4-dimethyl-cyclobutoxy group, 3,3-dimethyl-cyclobutoxy group, 1-n-propyl-cyclopropoxy group, 2-n-propyl-cyclopropoxy group, 1-i-propyl-cyclopropoxy group, 2-i-propyl-cyclopropoxy group, 1,2,2-trimethyl-cyclopropoxy group, 1,2,3-trimethyl-cyclopropoxy group, 2,2,3-trimethyl-cyclopropoxy group, 1-ethyl-2-methyl-cyclopropoxy group, 2-ethyl-1-methyl-cyclopropoxy group, 2-ethyl-2-methyl-cyclopropoxy group, and 2-ethyl-3-methyl-cyclopropoxy group.

Specific examples of the aforementioned alkoxyalkyl group include, but are not limited to, lower (carbon atom number of about 5 or less) alkyloxy lower (carbon atom number of about 5 or less) alkyl groups, such as methoxymethyl group, ethoxymethyl group, 1-ethoxyethyl group, 2-ethoxyethyl group, and ethoxymethyl group.

Specific examples of the aforementioned alkoxyaryl group include, but are not limited to, 2-methoxyphenyl group, 3-methoxyphenyl group, 4-methoxyphenyl group, 2-(1-ethoxy) phenyl group, 3-(1-ethoxy) phenyl group, 4-(1-ethoxy) phenyl group, 2-(2-ethoxy) phenyl group, 3-(2-ethoxy) phenyl group, 4-(2-ethoxy) phenyl group, 2-methoxynaphthalen-1-yl group, 3-methoxynaphthalen-1-yl group, 4-methoxynaphthalen-1-yl group, 5-methoxynaphthalen-1-yl group, 6-methoxynaphthalen-1-yl group, and 7-methoxynaphthalen-1-yl group.

Specific examples of the aforementioned alkoxyaralkyl group include, but are not limited to, 3-(methoxyphenyl)benzyl group and 4-(methoxyphenyl)benzyl group.

The aforementioned alkenyl group may be, for example, a C₂₋₁₀ alkenyl group. Examples of the alkenyl group include ethenyl group (vinyl group), 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group, and 3-cyclohexenyl group. Other examples of the alkenyl group include bridged cyclic alkenyl groups such as bicycloheptenyl group (norbornyl group).

Examples of the substituent of the aforementioned alkyl group, aryl group, aralkyl group, halogenated alkyl group, halogenated aryl group, halogenated aralkyl group, alkoxyalkyl group, alkoxyaryl group, alkoxyaralkyl group, or alkenyl group include an alkyl group, an aryl group, an aralkyl group, a halogenated alkyl group, a halogenated aryl group, a halogenated aralkyl group, an alkoxyalkyl group, an aryloxy group, an alkoxyaryl group, an alkoxyaralkyl group, an alkenyl group, an alkoxy group, and an aralkyloxy group. Specific examples of these groups and preferred carbon atom numbers thereof are the same as those described above or below.

The aryloxy group described above as the substituent is a group wherein an aryl group is bonded to another group via an oxygen atom (—O—), and specific examples of the aryl group are the same as those described above. No particular limitation is imposed on the carbon atom number of the aryloxy group, but the carbon atom number is preferably 40 or less, more preferably 30 or less, still more preferably 20 or less. Specific examples of the aryloxy group include, but are not limited to, phenoxy group and naphthalen-2-yloxy group.

When two or more substituents are present, the substituents may be bonded together to form a ring.

Examples of the organic group containing an epoxy group include glycidoxymethyl group, glycidoxyethyl group, glycidoxypropyl group, glycidoxybutyl group, and epoxycyclohexyl group.

Examples of the organic group containing an acryloyl group include acryloylmethyl group, acryloylethyl group, and acryloylpropyl group.

Examples of the organic group containing a methacryloyl group include methacryloylmethyl group, methacryloylethyl group, and methacryloylpropyl group.

Examples of the organic group containing a mercapto group include ethylmercapto group, butylmercapto group, hexylmercapto group, octylmercapto group, and mercaptophenyl group.

Examples of the organic group containing an amino group include, but are not limited to, amino group, aminomethyl group, aminoethyl group, aminophenyl group, dimethylaminoethyl group, and dimethylaminopropyl group.

Examples of the organic group containing an alkoxy group include, but are not limited to, methoxymethyl group and methoxyethyl group. However, the organic group excludes a group wherein an alkoxy group is directly bonded to the silicon atom.

Examples of the organic group containing a sulfonyl group include, but are not limited to, sulfonylalkyl group and sulfonylaryl group.

Examples of the organic group containing a cyano group include cyanoethyl group, cyanopropyl group, cyanophenyl group, and thiocyanate group.

The aforementioned aralkyloxy group is a group derived from an aralkyl alcohol through removal of a hydrogen atom from the hydroxy group of the alcohol. Specific examples of the aralkyl group are the same as those described above.

No particular limitation is imposed on the carbon atom number of the aralkyloxy group, but the carbon atom number is, for example, 40 or less, preferably 30 or less, more preferably 20 or less.

Specific examples of the aralkyloxy group include, but are not limited to, phenylmethyloxy group (benzyloxy group), 2-phenylethyleneoxy group, 3-phenyl-n-propyloxy group, 4-phenyl-n-butyloxy group, 5-phenyl-n-pentyloxy group, 6-phenyl-n-hexyloxy group, 7-phenyl-n-heptyloxy group, 8-phenyl-n-octyloxy group, 9-phenyl-n-nonyloxy group, and 10-phenyl-n-decyloxy group.

The acyloxy group is a group derived from a carboxylic compound through removal of a hydrogen atom from the carboxyl group (—COOH) of the compound. Typical examples of the acyloxy group include, but are not limited to, an alkylcarbonyloxy group, an arylcarbonyloxy group, or an aralkylcarbonyloxy group, which is respectively derived from an alkylcarboxylic acid, an arylcarboxylic acid, or an aralkylcarboxylic acid through removal of a hydrogen atom from the carboxyl group of the acid. Specific examples of the alkyl group, the aryl group, and the aralkyl group of such alkylcarboxylic acid, arylcarboxylic acid, and aralkylcarboxylic acid are the same as those described above.

Specific examples of the acyloxy group include C₂₋₂₀ acyloxy groups, such as methylcarbonyloxy group, ethylcarbonyloxy group, n-propylcarbonyloxy group, i-propylcarbonyloxy group, n-butylcarbonyloxy group, i-butylcarbonyloxy group, s-butylcarbonyloxy group, t-butylcarbonyloxy group, n-pentylcarbonyloxy group, 1-methyl-n-butylcarbonyloxy group, 2-methyl-n-butylcarbonyloxy group, 3-methyl-n-butylcarbonyloxy group, 1,1-dimethyl-n-propylcarbonyloxy group, 1,2-dimethyl-n-propylcarbonyloxy group, 2,2-dimethyl-n-propylcarbonyloxy group, 1-ethyl-n-propylcarbonyloxy group, n-hexylcarbonyloxy group, 1-methyl-n-pentylcarbonyloxy group, 2-methyl-n-pentylcarbonyloxy group, 3-methyl-n-pentylcarbonyloxy group, 4-methyl-n-pentylcarbonyloxy group, 1,1-dimethyl-n-butylcarbonyloxy group, 1,2-dimethyl-n-butylcarbonyloxy group, 1,3-dimethyl-n-butylcarbonyloxy group, 2,2-dimethyl-n-butylcarbonyloxy group, 2,3-dimethyl-n-butylcarbonyloxy group, 3,3-dimethyl-n-butylcarbonyloxy group, 1-ethyl-n-butylcarbonyloxy group, 2-ethyl-n-butylcarbonyloxy group, 1,1,2-trimethyl-n-propylcarbonyloxy group, 1,2,2-trimethyl-n-propylcarbonyloxy group, 1-ethyl-1-methyl-n-propylcarbonyloxy group, 1-ethyl-2-methyl-n-propylcarbonyloxy group, phenylcarbonyloxy group, and tosylcarbonyloxy group.

The hydrolyzable silane of Formula (1) may be, for example, a product produced by esterification reaction between any of epoxy group-containing hydrolyzable silanes of the following Formulae and a carboxylic acid compound described below.

The product produced by esterification reaction between the epoxy group-containing hydrolyzable silane and the carboxylic acid compound may be used as is (i.e., without purification or separation) for preparation of a polysiloxane (a hydrolysis condensate of a hydrolyzable silane) described below. Specifically, the reaction mixture containing any of the epoxy group-containing hydrolyzable silanes of the following Formulae and the carboxylic acid compound besides the ester group-containing hydrolyzable silane may be used for the below-described hydrolysis and condensation of hydrolyzable silane. The hydrolysis and condensation may involve the use of, for example, a reaction mixture wherein the conversion ratio of the below-described epoxy group-containing hydrolyzable silane into the ester group-containing hydrolyzable silane is 50% or more, or 60% or more, or 70% or more.

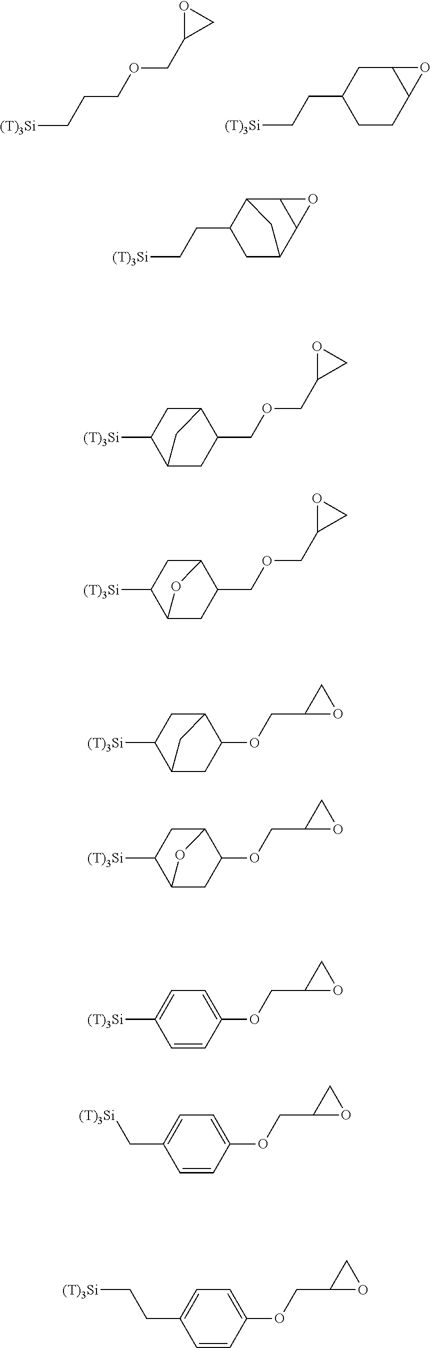

In the aforementioned Formulae, T is a methyl group or an ethyl group.

Specific examples of the aforementioned carboxylic acid compound (i.e., carboxylic acid, dicarboxylic acid, and dicarboxylic anhydride) include, but are not limited to, (mono) carboxylic acids such as formic acid, acetic acid, propionic acid, butyric acid, valeric acid, caproic acid, enanthic acid, caprylic acid, pelargonic acid, capric acid, oleic acid, linoleic acid, linolenic acid, arachidonic acid, eicosapentaenoic acid, docosahexaenoic acid, sorbic acid, lactic acid, malic acid, citric acid, benzoic acid, norbornenecarboxylic acid, norbornenecarboxylic acid analogs (3a,4,7,7a-tetrahydro-4,7-ethanoisobenzofuran-1,3-dione, 3a,4,7,7a-tetrahydro-4,7-epoxyisobenzofuran-1,3-dione, etc.), cyclohexenecarboxylic acid, acrylic acid, crotonic acid, tiglic acid, hexenoic acid, oleic acid, pentynoic acid, and heptenoic acid; dicarboxylic acids such as oxalic acid, malonic acid, succinic acid, glutaric acid, adipic acid, fumaric acid, maleic acid, phthalic acid, isophthalic acid, terephthalic acid, and norbornenedicarboxylic acid; dicarboxylic anhydrides such as succinic anhydride, phthalic anhydride, maleic anhydride, benzoic anhydride, and norbornenedicarboxylic anhydride; and cyano group-substituted compounds of these carboxylic acid compounds.

In a preferred embodiment, the aforementioned carboxylic acid compound has at least one group selected from the group consisting of an alicyclic group, an aromatic ring group, a cyano group, an alkenyl group, and an alkynyl group.

Other examples of the aforementioned carboxylic acid compound are described below. In the following Formulae, n is a natural number of 1 or more, and FG is a functional group.

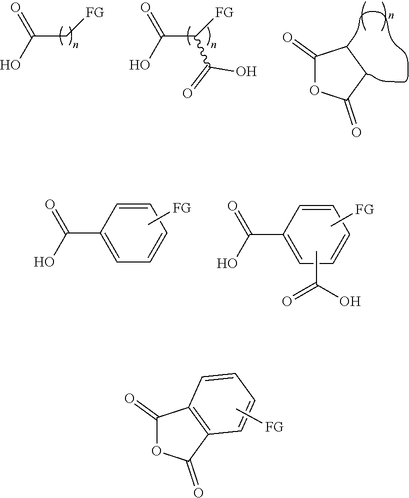

FG is, for example, a hydrogen atom, an alkyl group, an aryl group, an aralkyl group, a halogen atom, a halogenated alkyl group, a halogenated aryl group, a halogenated aralkyl group, an alkoxyalkyl group, an alkoxyaryl group, an alkoxyaralkyl group, an alkynyl group, an alkenyl group, an acryloyl group, a methacryloyl group, a mercapto group, an amino group, an amide group, an alkoxy group, an alkoxycarbonyl group, an acyloxy group, a sulfonyl group, a phosphonyl group, a cyano group, a carbonyl group, or an aldehyde group.

The alkoxycarbonyl group is prepared by bonding of an alkoxy group to a carbonyl group (—CO—), and specific examples of the alkoxy group are the same as those described above.

Specific examples of the aforementioned alkoxycarbonyl group include, but are not limited to, C₂₋₂₀ alkoxycarbonyl groups such as methoxycarbonyl group, ethoxycarbonyl group, n-propoxycarbonyl group, i-propoxycarbonyl group, n-butoxycarbonyl group, i-butoxycarbonyl group, s-butoxycarbonyl group, t-butoxycarbonyl group, n-pentyloxycarbonyl group, and phenoxycarbonyl group.

Specific examples of the groups other than the alkoxycarbonyl group and the halogen atom are the groups and atoms exemplified above in R¹, R³, and R¹⁰².

The polysiloxane [A] may contain, besides the aforementioned siloxane unit structure of Formula (1), a hydrolysis condensate [I-1] containing a siloxane unit structure having an organic group containing a quaternary ammonium nitrate structure.

The aforementioned hydrolysis condensate [I-1] may be, for example, a hydrolysis condensate of a mixture containing the aforementioned hydrolyzable silane of Formula (1), a hydrolyzable silane containing at least one hydrolyzable silane of the following Formula (2) containing an amino group-containing organic group, and nitric acid. The hydrolysis condensate contains a quaternary ammonium nitrate structure formed from the aforementioned nitric acid and amino group.

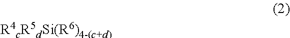

In Formula (2), R⁴ is a group bonded to the silicon atom, and is an amino group-containing organic group.

R⁵ is a group bonded to the silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an acryloyl group, a methacryloyl group, a mercapto group, an amino group, an amide group, an alkoxy group, a sulfonyl group, or a cyano group, or any combination of these.

Re is a group or atom bonded to the silicon atom, and is each independently an alkoxy group, an aralkyloxy group, an acyloxy group, or a halogen atom.

In Formula (2), c is an integer of 1, d is an integer of 0 to 2, and c+d is an integer of 1 to 3.

Specific examples of the aforementioned alkyl group, aryl group, aralkyl group, halogenated alkyl group, halogenated aryl group, halogenated aralkyl group, alkoxyalkyl group, alkoxyaryl group, alkoxyaralkyl group, alkenyl group, and organic group containing an acryloyl group, a methacryloyl group, a mercapto group, an amino group, an amide group, an alkoxy group, a sulfonyl group, or a cyano group of R⁵, the aforementioned alkoxy group, aralkyloxy group, acyloxy group, and halogen atom of R⁶, the substituents of these, and preferred carbon atom numbers thereof are the same as those described above regarding R² and R³.

No particular limitation is imposed on the amino group-containing organic group of R⁴ in Formula (2), so long as it is an amino group-containing organic group. One preferred example of the organic group is a group of the following Formula (A1).

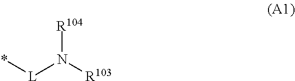

In Formula (A1), R¹⁰³ and R¹⁰⁴ are each independently a hydrogen atom or a hydrocarbon group; and L is each independently a substitutable alkylene group.

Examples of the aforementioned hydrocarbon group include, but are not limited to, an alkyl group, an alkenyl group, and an aryl group. Specific groups of the alkyl group, the alkenyl group, and the aryl group are the same as those described above regarding R².

The aforementioned alkylene group may have a linear or branched structure, and the carbon atom number of the alkylene group is generally 1 to 10, preferably 1 to 5. Examples of the alkylene group include linear alkylene groups such as methylene group, ethylene group, trimethylene group, tetramethylene group, pentamethylene group, hexamethylene group, heptamethylene group, octamethylene group, nonamethylene group, and decamethylene group.

Examples of the aforementioned amino group-containing organic group include, but are not limited to, amino group, aminomethyl group, aminoethyl group, aminophenyl group, dimethylaminoethyl group, dimethylaminopropyl group, allylaminopropyl group, and phenylaminopropyl group.

Specific examples of the hydrolyzable silane of Formula (2) include, but are not limited to, 3-allylaminopropyltrimethoxysilane, 3-allylaminopropyltriethoxysilane, 3-phenylaminopropyltrimethoxysilane, 3-phenylaminopropyltriethoxysilane, and dimethylaminopropyltrimethoxysilane.

### <Additional Silane Compound (Hydrolyzable Silane)>

The polysiloxane [A] may be, for example, a hydrolysis condensate of a hydrolyzable silane containing the aforementioned hydrolyzable silane of Formula (1), the aforementioned hydrolyzable silane of Formula (2) containing an amino group-containing organic group, and an additional hydrolyzable silane described below. The additional hydrolyzable silane may be, for example, a hydrolyzable silane of the following Formula (3) or a hydrolyzable silane of the following Formula (4).

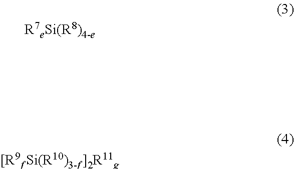

In Formula (3), R′ is a group bonded to the silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amide group, an alkoxy group, a sulfonyl group, or a cyano group, or any combination of these.

R⁸ is a group or atom bonded to the silicon atom, and is each independently an alkoxy group, an aralkyloxy group, an acyloxy group, or a halogen atom.

In Formula (3), e is an integer of 0 to 3.

Specific examples of the groups of R′ and preferred carbon atom numbers thereof are the same as those described above regarding R².

Specific examples of the groups of R⁸ and preferred carbon atom numbers thereof are the same as those described above regarding R³.

In Formula (4), R⁹ is a group bonded to the silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, a sulfonyl group, or a cyano group, or any combination of these.

R¹⁰ is a group or atom bonded to the silicon atom, and is each independently an alkoxy group, an aralkyloxy group, an acyloxy group, or a halogen atom.

R¹¹ is a group bonded to the silicon atom, and is each independently an alkylene group or an arylene group.

In Formula (4), f is an integer of 0 or 1, and g is an integer of 0 or 1.

Specific examples of the groups of R⁹ and preferred carbon atom numbers thereof are the same as those described above regarding R².

Specific examples of the groups and atom of R¹⁰ and preferred carbon atom numbers thereof are the same as those described above regarding R³.

Specific examples of the alkylene group of R¹¹ include, but are not limited to, branched alkylene groups such as methyltrimethylene group, 2-methyltrimethylene group, 1,1-dimethylethylene group, 1-methyltetramethylene group, 2-methyltetramethylene group, 1,1-dimethyltrimethylene group, 1,2-dimethyltrimethylene group, 2,2-dimethyltrimethylene group, and 1-ethyltrimethylene group; and alkanetriyl groups such as methanetriyl group, ethane-1,1,2-triyl group, ethane-1,2,2-triyl group, ethane-2,2,2-triyl group, propane-1,1,1-triyl group, propane-1,1,2-triyl group, propane-1,2,3-triyl group, propane-1,2,2-triyl group, propane-1,1,3-triyl group, butane-1,1,1-triyl group, butane-1,1,2-triyl group, butane-1,1,3-triyl group, butane-1,2,3-triyl group, butane-1,2,4-triyl group, butane-1,2,2-triyl group, butane-2,2,3-triyl group, 2-methylpropane-1,1,1-triyl group, 2-methylpropane-1,1,2-triyl group, and 2-methylpropane-1,1,3-triyl group.

Specific examples of the arylene group include, but are not limited to, 1,2-phenylene group, 1,3-phenylene group, 1,4-phenylene group; groups derived from a condensed-ring aromatic hydrocarbon compound through removal of two hydrogen atoms on the aromatic ring, such as 1,5-naphthalenediyl group, 1,8-naphthalenediyl group, 2,6-naphthalenediyl group, 2,7-naphthalenediyl group, 1,2-anthracenediyl group, 1,3-anthracenediyl group, 1,4-anthracenediyl group, 1,5-anthracenediyl group, 1,6-anthracenediyl group, 1,7-anthracenediyl group, 1,8-anthracenediyl group, 2,3-anthracenediyl group, 2,6-anthracenediyl group, 2,7-anthracenediyl group, 2,9-anthracenediyl group, 2,10-anthracenediyl group, and 9,10-anthracenediyl group; and groups derived from a linked-ring aromatic hydrocarbon compound through removal of two hydrogen atoms on the aromatic ring, such as 4,4′-biphenyldiyl group and 4,4″-p-terphenyldiyl group.

In Formula (4), f is preferably 0, and g is preferably 1.

Specific examples of the hydrolyzable silane of Formula (3) include, but are not limited to, tetramethoxysilane, tetrachlorosilane, tetraacetoxysilane, tetraethoxysilane, tetra-n-propoxysilane, tetra-i-propoxysilane, tetra-n-butoxysilane, methyltrimethoxysilane, methyltrichlorosilane, methyltriacetoxysilane, methyltriethoxysilane, methyltripropoxysilane, methyltributoxysilane, methyltriamyloxysilane, methyltriphenoxysilane, methyltribenzyloxysilane, methyltriphenethyloxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, δ-glycidoxybutyltrimethoxysilane, δ-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltrimethoxysilane, β-(3,4-epoxycyclohexyl)ethyltriethoxysilane, β-(3,4-epoxycyclohexyl)ethyltripropoxysilane, β-(3,4-epoxycyclohexyl)ethyltributoxysilane, β-(3,4-epoxycyclohexyl)ethyltriphenoxysilane, γ-(3,4-epoxycyclohexyl) propyltrimethoxysilane, γ-(3,4-epoxycyclohexyl) propyltriethoxysilane, δ-(3,4-epoxycyclohexyl) butyltrimethoxysilane, δ-(3,4-epoxycyclohexyl) butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldiphenoxysilane, γ-glycidoxypropylethyldimethoxysilane, γ-glycidoxypropylethyldiethoxysilane, γ-glycidoxypropylvinyldimethoxysilane, γ-glycidoxypropylvinyldiethoxysilane, ethyltrimethoxysilane, ethyltriethoxysilane, vinyltrimethoxysilane, vinyltriethoxysilane, vinyltrichlorosilane, vinyltriacetoxysilane, methylvinyldimethoxysilane, methylvinyldiethoxysilane, methylvinyldichlorosilane, methylvinyldiacetoxysilane, dimethylvinylmethoxysilane, dimethylvinylethoxysilane, dimethylvinylchlorosilane, dimethylvinylacetoxysilane, divinyldimethoxysilane, divinyldiethoxysilane, divinyldichlorosilane, divinyldiacetoxysilane, γ-glycidoxypropylvinyldimethoxysilane, γ-glycidoxypropylvinyldiethoxysilane, allyltrimethoxysilane, allyltriethoxysilane, allyltrichlorosilane, allyltriacetoxysilane, allylmethyldimethoxysilane, allylmethyldiethoxysilane, allylmethyldichlorosilane, allylmethyldiacetoxysilane, allyldimethylmethoxysilane, allyldimethylethoxysilane, allyldimethylchlorosilane, allyldimethylacetoxysilane, diallyldimethoxysilane, diallyldiethoxysilane, diallyldichlorosilane, diallyldiacetoxysilane, p-styryltrimethoxysilane, phenyltrimethoxysilane, phenyltriethoxysilane, phenyltrichlorosilane, phenyltriacetoxysilane, phenylmethyldimethoxysilane, phenylmethyldiethoxysilane, phenylmethyldichlorosilane, phenylmethyldiacetoxysilane, phenyldimethylmethoxysilane, phenyldimethylethoxysilane, phenyldimethylchlorosilane, phenyldimethylacetoxysilane, diphenylmethylmethoxysilane, diphenylmethylethoxysilane, diphenylmethylchlorosilane, diphenylmethylacetoxysilane, diphenyldimethoxysilane, diphenyldiethoxysilane, diphenyldichlorosilane, diphenyldiacetoxysilane, triphenylmethoxysilane, triphenylethoxysilane, triphenylacetoxysilane, triphenylchlorosilane, dimethoxymethyl-3-(3-phenoxypropylthiopropyl) silane, triethoxy ((2-methoxy-4-(methoxymethyl) phenoxy) methyl) silane, benzyltrimethoxysilane, benzyltriethoxysilane, benzylmethyldimethoxysilane, benzylmethyldiethoxysilane, benzyldimethylmethoxysilane, benzyldimethylethoxysilane, benzyldimethylchlorosilane, phenethyltrimethoxysilane, phenethyltriethoxysilane, phenethyltrichlorosilane, phenethyltriacetoxysilane, phenethylmethyldimethoxysilane, phenethylmethyldiethoxysilane, phenethylmethyldichlorosilane, phenethylmethyldiacetoxysilane, methoxyphenyltrimethoxysilane, methoxyphenyltriethoxysilane, methoxyphenyltriacetoxysilane, methoxyphenyltrichlorosilane, methoxybenzyltrimethoxysilane, methoxybenzyltriethoxysilane, methoxybenzyltriacetoxysilane, methoxybenzyltrichlorosilane, methoxyphenethyltrimethoxysilane, methoxyphenethyltriethoxysilane, methoxyphenethyltriacetoxysilane, methoxyphenethyltrichlorosilane, ethoxyphenyltrimethoxysilane, ethoxyphenyltriethoxysilane, ethoxyphenyltriacetoxysilane, ethoxyphenyltrichlorosilane, ethoxybenzyltrimethoxysilane, ethoxybenzyltriethoxysilane, ethoxybenzyltriacetoxysilane, ethoxybenzyltrichlorosilane, i-propoxyphenyltrimethoxysilane, i-propoxyphenyltriethoxysilane, i-propoxyphenyltriacetoxysilane, i-propoxyphenyltrichlorosilane, i-propoxybenzyltrimethoxysilane, i-propoxybenzyltriethoxysilane, i-propoxybenzyltriacetoxysilane, i-propoxybenzyltrichlorosilane, t-butoxyphenyltrimethoxysilane, t-butoxyphenyltriethoxysilane, t-butoxyphenyltriacetoxysilane, t-butoxyphenyltrichlorosilane, t-butoxybenzyltrimethoxysilane, t-butoxybenzyltriethoxysilane, t-butoxybenzyltriacetoxysilane, t-butoxybenzyltrichlorosilane, methoxynaphthyltrimethoxysilane, methoxynaphthyltriethoxysilane, methoxynaphthyltriacetoxysilane, methoxynaphthyltrichlorosilane, ethoxynaphthyltrimethoxysilane, ethoxynaphthyltriethoxysilane, ethoxynaphthyltriacetoxysilane, ethoxynaphthyltrichlorosilane, γ-chloropropyltrimethoxysilane, γ-chloropropyltriethoxysilane, γ-chloropropyltriacetoxysilane, 3,3,3-trifluoropropyltrimethoxysilane, γ-methacryloxypropyltrimethoxysilane, γ-mercaptopropyltrimethoxysilane, γ-mercaptopropyltriethoxysilane, β-cyanoethyltriethoxysilane, thiocyanatopropyltriethoxysilane, chloromethyltrimethoxysilane, chloromethyltriethoxysilane, triethoxysilylpropyldiallyl isocyanurate, bicyclo[2,2,1] heptenyltriethoxysilane, benzenesulfonylpropyltriethoxysilane, benzenesulfonamidepropyltriethoxysilane, dimethyldimethoxysilane, phenylmethyldimethoxysilane, dimethyldiethoxysilane, phenylmethyldiethoxysilane, γ-chloropropylmethyldimethoxysilane, γ-chloropropylmethyldiethoxysilane, dimethyldiacetoxysilane, γ-methacryloxypropylmethyldimethoxysilane, γ-methacryloxypropylmethyldiethoxysilane, γ-mercaptopropylmethyldimethoxysilane, γ-mercaptopropylmethyldiehoxysilane, methylvinyldimethoxysilane, methylvinyldiethoxysilane, and silanes of the following Formulae (A-1) to (A-41).

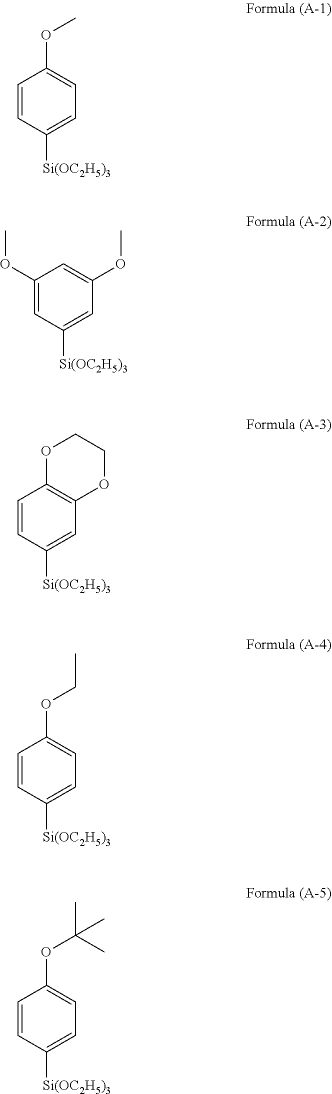

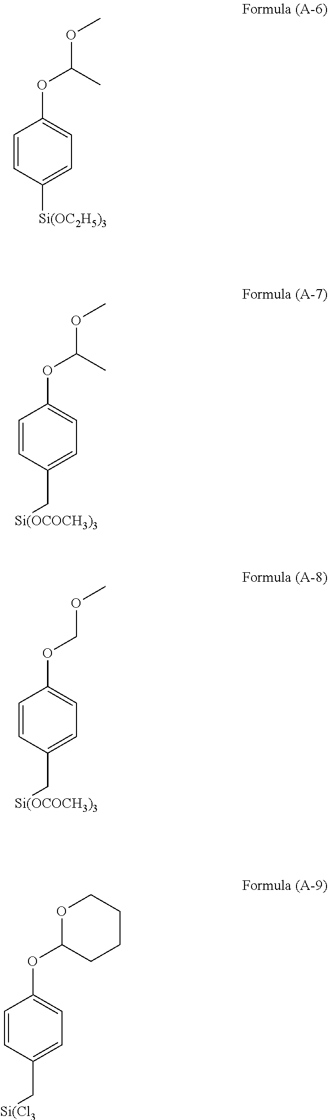

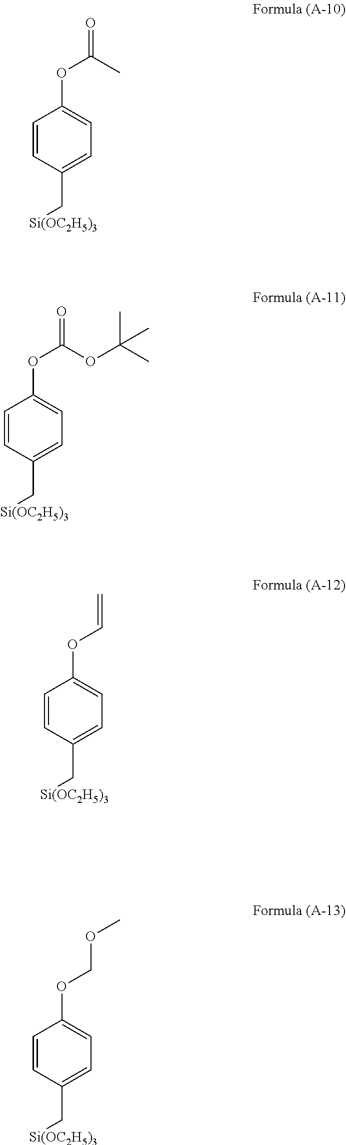

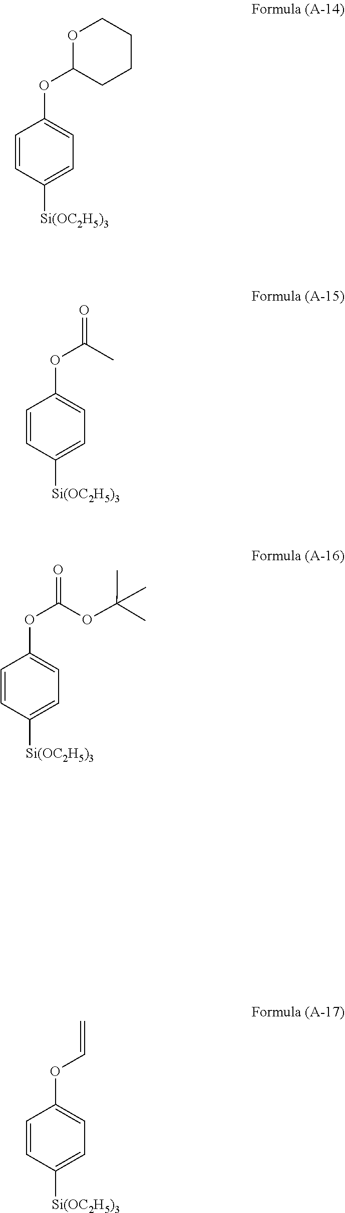

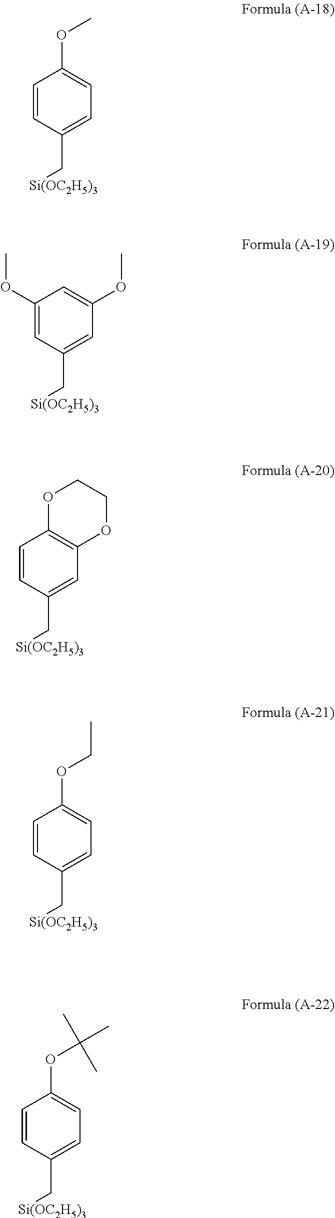

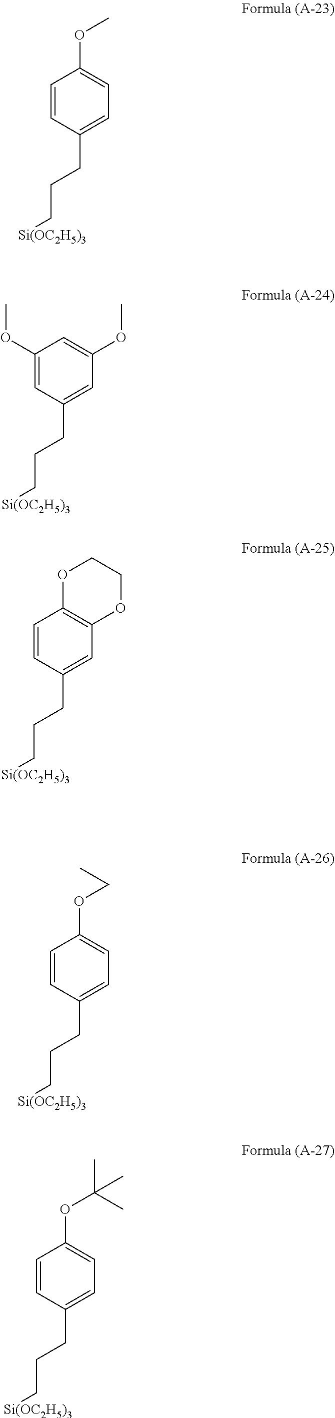

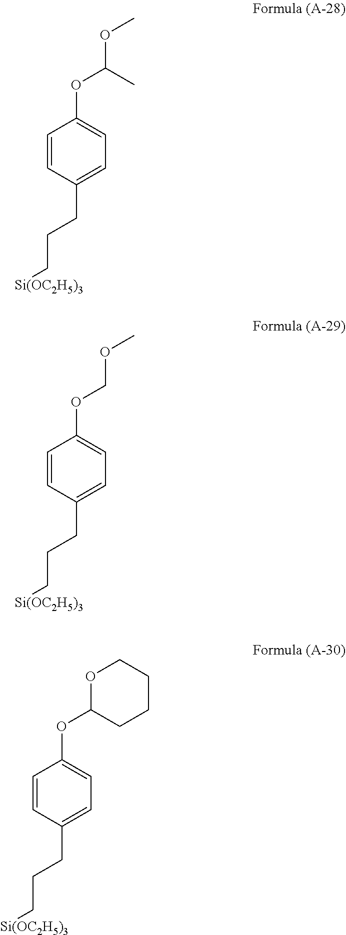

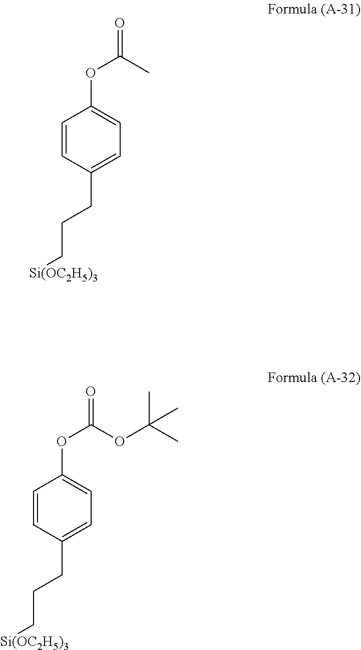

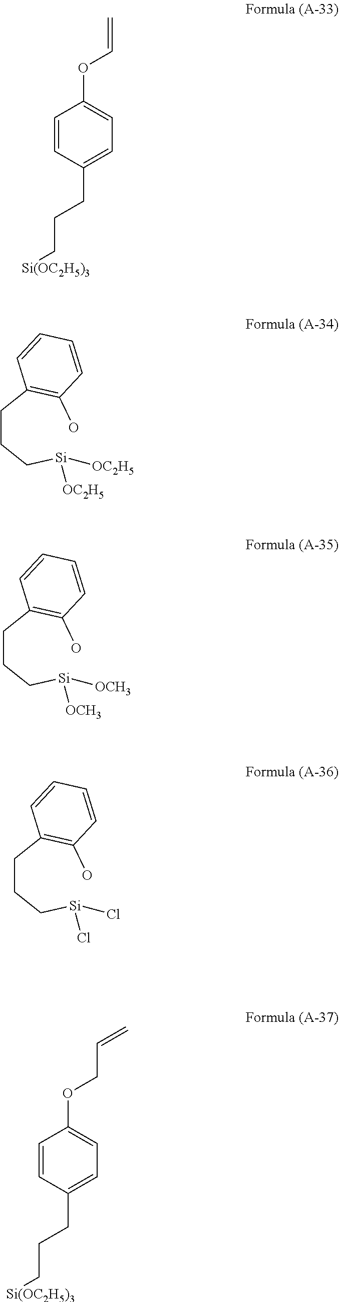

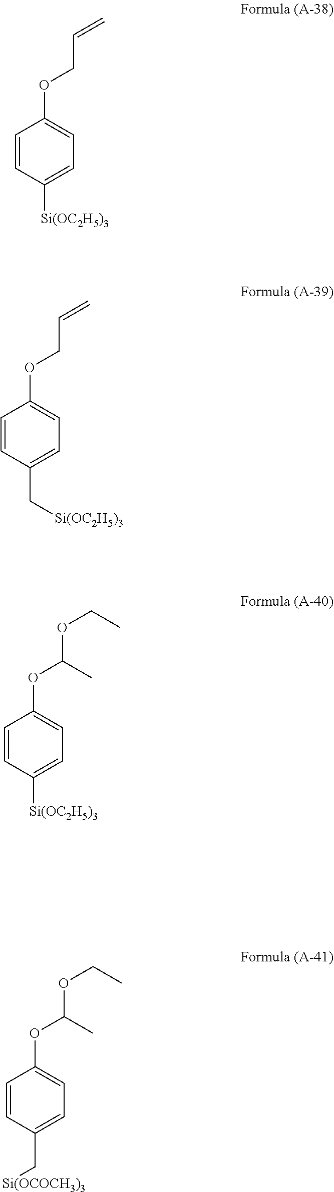

Specific examples of the hydrolyzable silane of Formula (4) include, but are not limited to, methylenebistrimethoxysilane, methylenebistrichlorosilane, methylenebistriacetoxysilane, ethylenebistriethoxysilane, ethylenebistrichlorosilane, ethylenebistriacetoxysilane, propylenebistriethoxysilane, butylenebistrimethoxysilane, phenylenebistrimethoxysilane, phenylenebistriethoxysilane, phenylenebismethyldiethoxysilane, phenylenebismethyldimethoxysilane, naphthylenebistrimethoxysilane, bistrimethoxydisilane, bistriethoxydisilane, bisethyldiethoxydisilane, and bismethyldimethoxydisilane.

Examples of the aforementioned additional hydrolyzable silane include, but are not limited to, a silane compound having an onium group in the molecule, a silane compound having a sulfone group, a silane compound having a sulfonamide group, and a silane compound having a cyclic urea structure in the molecule.

### <Silane Compound Having Onium Group in Molecule (Hydrolyzable Organosilane)>

A silane compound having an onium group in the molecule is expected to promote the crosslinking reaction of a hydrolyzable silane in an effective and efficient manner.

One preferred example of the silane compound having an onium group in the molecule is shown in the following Formula (5).

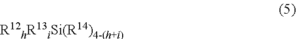

R¹² is a group bonded to the silicon atom, and is an onium group or an organic group containing the onium group.

R¹³ is a group bonded to the silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an acryloyl group, a methacryloyl group, a mercapto group, or a cyano group, or any combination of these.

R¹⁴ is a group or atom bonded to the silicon atom, and is each independently an alkoxy group, an aralkyloxy group, an acyloxy group, or a halogen atom.

In Formula (5), h is 1 or 2; i is 0 or 1; and h and i satisfy a relation of 1≤h+i≤2.

Specific examples of the aforementioned alkyl group, aryl group, aralkyl group, halogenated alkyl group, halogenated aryl group, halogenated aralkyl group, alkoxyalkyl group, alkoxyaryl group, alkoxyaralkyl group, alkenyl group, and organic group containing an acryloyl group, a methacryloyl group, a mercapto group, or a cyano group, an alkoxy group, an aralkyloxy group, acyloxy group, and a halogen atom, and specific examples of the substituent of the alkyl group, the aryl group, the aralkyl group, the halogenated alkyl group, the halogenated aryl group, the halogenated aralkyl group, the alkoxyalkyl group, the alkoxyaryl group, the alkoxyaralkyl group, and the alkenyl group, and preferred carbon atom numbers thereof are the same as those described above regarding R² (for R¹³) and regarding R³ (for R¹⁴).

More specifically, the onium group is, for example, a cyclic ammonium group or a chain ammonium group, and is preferably a tertiary ammonium group or a quaternary ammonium group.

Preferred specific examples of the onium group or the organic group containing the onium group include a cyclic ammonium group or a chain ammonium group, or an organic group containing at least one of these ammonium groups. Preferred is a tertiary ammonium group or a quaternary ammonium group, or an organic group containing at least one of these ammonium groups

When the onium group is a cyclic ammonium group, the nitrogen atom forming the ammonium group also serves as an atom forming the ring. In this case, the nitrogen atom forming the ring and the silicon atom are bonded directly or via a divalent linking group, or the carbon atom forming the ring and the silicon atom are bonded directly or via a divalent linking group.

In one preferred embodiment of the present invention, R¹² (i.e., the group bonded to the silicon atom) is a heteroaromatic cyclic ammonium group of the following Formula (S1).

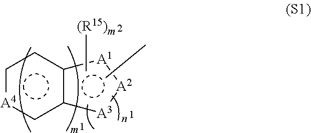

In Formula (S1), A¹, A², A³, and A⁴ are each independently a group of any of the following Formulae (J1) to (J3), and at least one of A¹ to A⁴ is a group of the following Formula (J2). Depending on the bonding between the silicon atom in Formula (5) and any of A¹ to A⁴, each of A¹ to A⁴ and the ring-forming atom adjacent thereto forms a single bond or a double bond so that the thus-formed ring exhibits aromaticity.

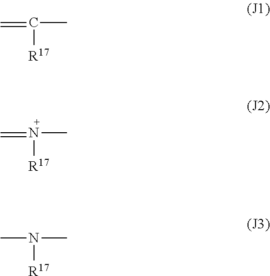

In Formulae (J1) to (J3), R¹⁷ is each independently a single bond, a hydrogen atom, an alkyl group, an aryl group, an aralkyl group, a halogenated alkyl group, a halogenated aryl group, a halogenated aralkyl group, or an alkenyl group. Specific examples of the alkyl group, the aryl group, the aralkyl group, the halogenated alkyl group, the halogenated aryl group, the halogenated aralkyl group, and the alkenyl group, and preferred carbon atom numbers thereof are the same as those described above.

In Formula (S1), R¹⁵ is each independently an alkyl group, an aryl group, an aralkyl group, a halogenated alkyl group, a halogenated aryl group, a halogenated aralkyl group, an alkenyl group, or a hydroxy group. When two or more R¹⁵s are present, the two R¹⁵s may be bonded together to form a ring, and the ring formed by the two R¹⁵s may have a crosslinked ring structure. In such a case, the cyclic ammonium group has, for example, an adamantane ring, a norbornene ring, or a spiro ring.

Specific examples of these alkyl group, aryl group, aralkyl group, halogenated alkyl group, halogenated aryl group, halogenated aralkyl group, and alkenyl group, and preferred carbon atom numbers thereof are the same as those described above.

In Formula (S1), n¹ is an integer of 1 to 8; m¹ is 0 or 1; and m² is 0 or a positive integer raging from 1 to the possible maximum number of R¹⁵s substituted on a monocyclic or polycyclic ring.

When m¹ is 0, a (4+n¹)-membered ring including A¹ to A⁴ is formed. Specifically, when n¹ is 1, a 5-membered ring is formed; when n¹ is 2, a 6-membered ring is formed; when n¹ is 3, a 7-membered ring is formed; when n¹ is 4, a 8-membered ring is formed; when n¹ is 5, a 9-membered ring is formed; when n¹ is 6, a 10-membered ring is formed; when n¹ is 7, a 11-membered ring is formed; and when n¹ is 8, a 12-membered ring is formed.

When m¹ is 1, a condensed ring is formed by condensation between a (4+n¹)-membered ring including A¹ to A³ and a 6-membered ring including A⁴.

Since each of A¹ to A⁴ is any of the groups of Formulae (J1) to (J3), the ring-forming atom has or does not have a hydrogen atom. In each of A¹ to A⁴, when the ring-forming atom has a hydrogen atom, the hydrogen atom may be substituted with R¹⁵. Alternatively, a ring-forming atom other than the ring-forming atom in each of A¹ to A⁴ may be substituted with R¹⁵. Because of these circumstances, m² is 0 or an integer raging from 1 to the possible maximum number of R¹⁵s substituted on a monocyclic or polycyclic ring.

The dangling bond of the heteroaromatic cyclic ammonium group of Formula (S1) is present on any carbon atom or nitrogen atom present in such a monocyclic or polycyclic ring, and is directly bonded to the silicon atom. Alternatively, the dangling bond is bonded to a linking group to form an organic group containing the cyclic ammonium group, and the organic group is bonded to the silicon atom.

Examples of the linking group include, but are not limited to, an alkylene group, an arylene group, and an alkenylene group.

Specific examples of the alkylene group and the arylene group, and preferred carbon atom numbers thereof are the same as those described above.

The alkenylene group is a divalent group derived from an alkenyl group through removal of one hydrogen atom. Specific examples of the alkenyl group are the same as those described above. No particular limitation is imposed on the carbon atom number of the alkenylene group, but the carbon atom number is preferably 40 or less, more preferably 30 or less, still more preferably 20 or less.

Specific examples of the alkenylene group include, but are not limited to, vinylene group, 1-methylvinylene group, propenylene group, 1-butenylene group, 2-butenylene group, 1-pentenylene group, and 2-pentenylene group.

Specific examples of the silane compound (hydrolyzable organosilane) of Formula (5) having the heteroaromatic cyclic ammonium group of Formula (S1) include, but are not limited to, silanes of the following Formulae (I-1) to (I-50).

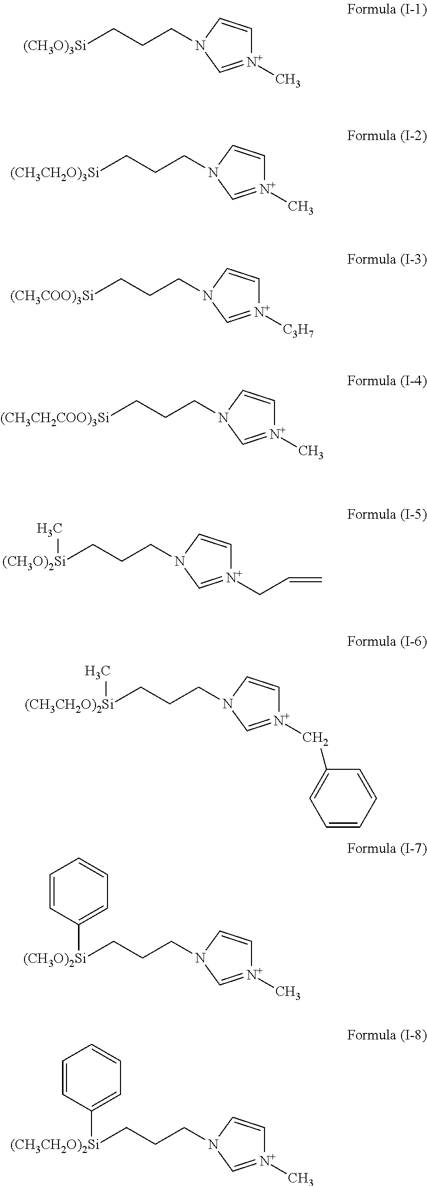

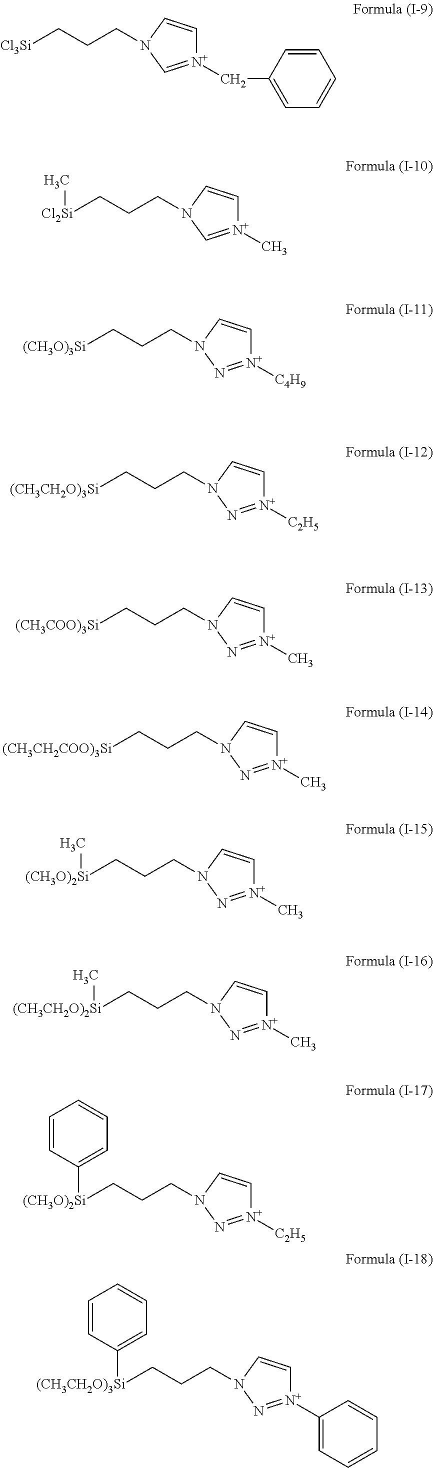

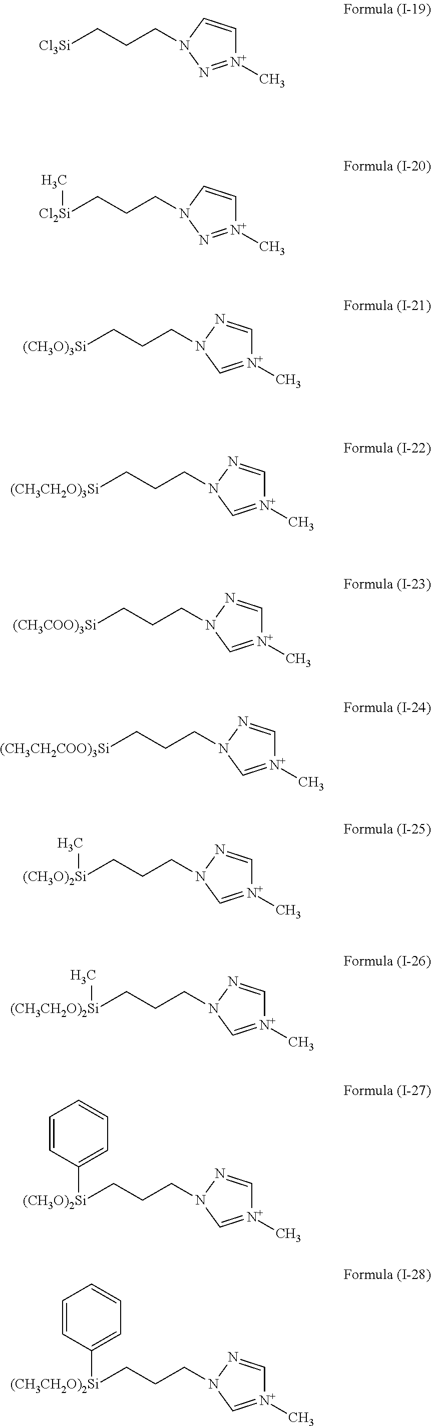

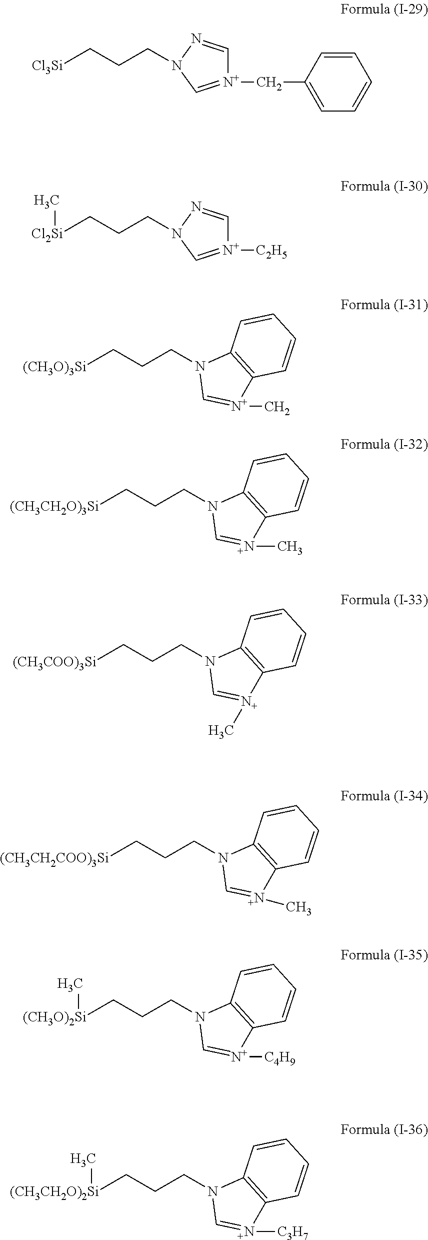

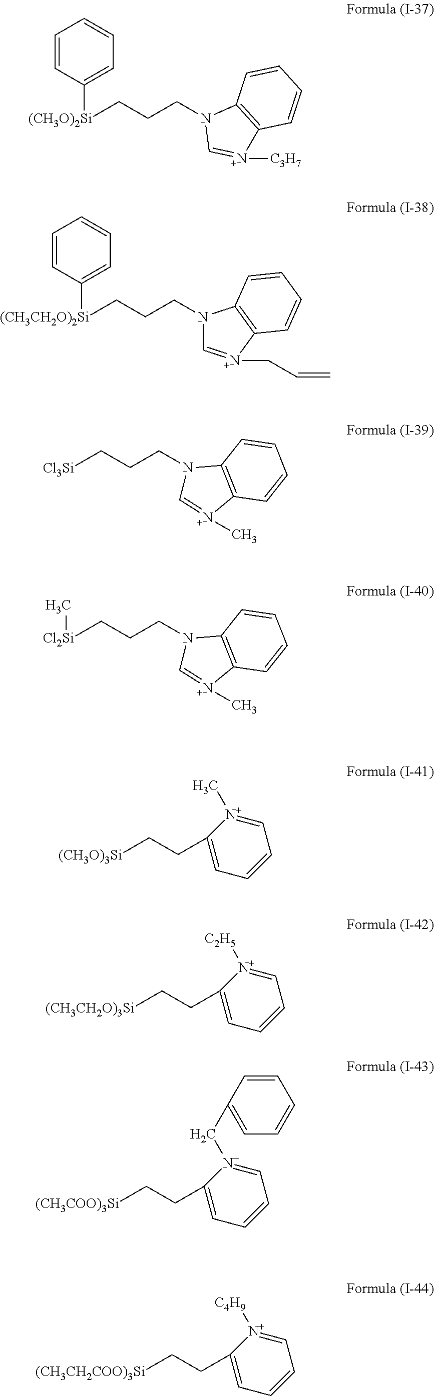

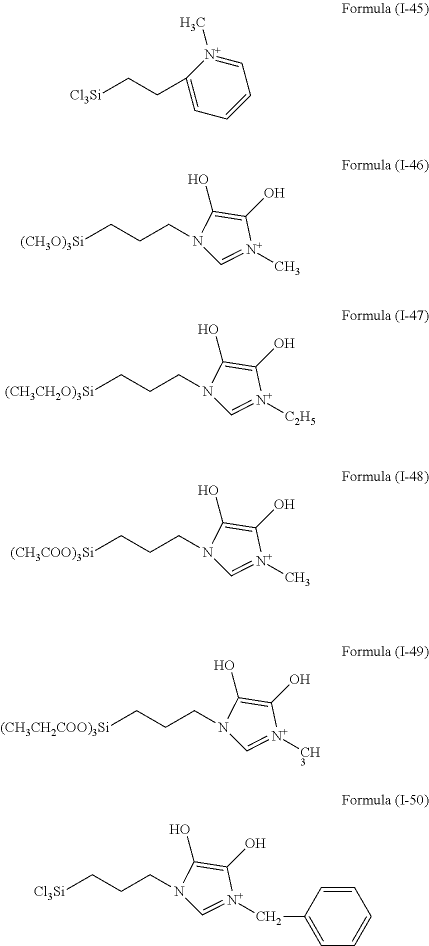

In another embodiment. R 2 (i.e., the group bonded to the silicon atom in Formula (5)) is a heteroaliphatic cyclic ammonium group of the following Formula (S2).

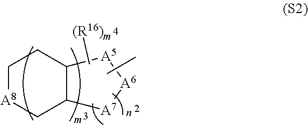

In Formula (S2), A⁵, A⁶, A⁷, and A⁸ are each independently a group of any of the following Formulae (J4) to (J6), and at least one of A⁵ to A⁸ is a group of the following Formula (J5). Depending on the bonding between the silicon atom in Formula (5) and any of A⁵ to A⁸, each of A⁵ to A⁸ and the ring-forming atom adjacent thereto forms a single bond or a double bond so that the thus-formed ring exhibits anti-aromaticity.

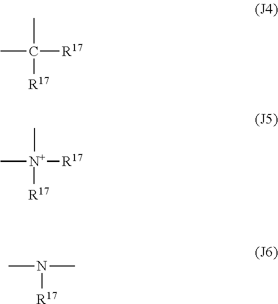

In Formulae (J4) to (J6), R¹⁷ is each independently a single bond, a hydrogen atom, an alkyl group, an aryl group, an aralkyl group, a halogenated alkyl group, a halogenated aryl group, a halogenated aralkyl group, or an alkenyl group. Specific examples of the alkyl group, the aryl group, the aralkyl group, the halogenated alkyl group, the halogenated aryl group, the halogenated aralkyl group, and the alkenyl group, and preferred carbon atom numbers thereof are the same as those described above.

In Formula (S2), R¹⁶ is each independently an alkyl group, an aryl group, an aralkyl group, a halogenated alkyl group, a halogenated aryl group, a halogenated aralkyl group, an alkenyl group, or a hydroxy group. When two or more R¹⁶s are present, the two R¹⁶s may be bonded together to form a ring, and the ring formed by the two R¹⁶s may have a crosslinked ring structure. In such a case, the cyclic ammonium group has, for example, an adamantane ring, a norbornene ring, or a spiro ring.

Specific examples of the alkyl group, the aryl group, the aralkyl group, the halogenated alkyl group, the halogenated aryl group, the halogenated aralkyl group, and the alkenyl group, and preferred carbon atom numbers thereof are the same as those described above.

In Formula (S2), n² is an integer of 1 to 8; m³ is 0 or 1; and m⁴ is 0 or a positive integer raging from 1 to the possible maximum number of R¹⁶s substituted on a monocyclic or polycyclic ring.

When m³ is 0, a (4+n²)-membered ring including A⁵ to A⁸ is formed. Specifically, when n² is 1, a 5-membered ring is formed; when n² is 2, a 6-membered ring is formed; when n² is 3, a 7-membered ring is formed; when n² is 4, a 8-membered ring is formed; when n² is 5, a 9-membered ring is formed; when n² is 6, a 10-membered ring is formed; when n² is 7, a 11-membered ring is formed; and when n² is 8, a 12-membered ring is formed.

When m³ is 1, a condensed ring is formed by condensation between a (4+n²)-membered ring including A⁵ to A⁷ and a 6-membered ring including A⁸.

Since each of A⁵ to A⁸ is any of the groups of Formulae (J4) to (J6), the ring-forming atom has or does not have a hydrogen atom. In each of A⁵ to A⁸, when the ring-forming atom has a hydrogen atom, the hydrogen atom may be substituted with R¹⁶. Alternatively, a ring-forming atom other than the ring-forming atom in each of A⁵ to A⁸ may be substituted with R¹⁶.

Because of these circumstances, m⁴ is 0 or an integer raging from 1 to the possible maximum number of R¹⁶s substituted on a monocyclic or polycyclic ring.

The dangling bond of the heteroaliphatic cyclic ammonium group of Formula (S2) is present on any carbon atom or nitrogen atom present in such a monocyclic or polycyclic ring, and is directly bonded to the silicon atom. Alternatively, the dangling bond is bonded to a linking group to form an organic group containing the cyclic ammonium group, and the organic group is bonded to the silicon atom.

The linking group is, for example, an alkylene group, an arylene group, or an alkenylene group. Specific examples of the alkylene group, the arylene group, and the alkenylene group, and preferred carbon atom numbers thereof are the same as those described above.

Specific examples of the silane compound (hydrolyzable organosilane) of Formula (5) having the heteroaliphatic cyclic ammonium group of Formula (S2) include, but are not limited to, silanes of the following Formulae (II-1) to (II-30).

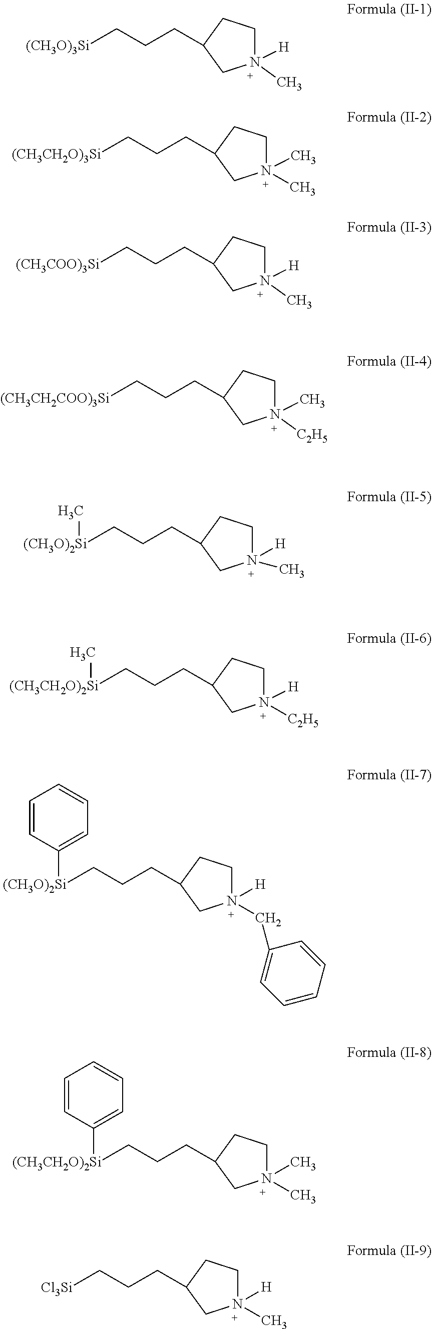

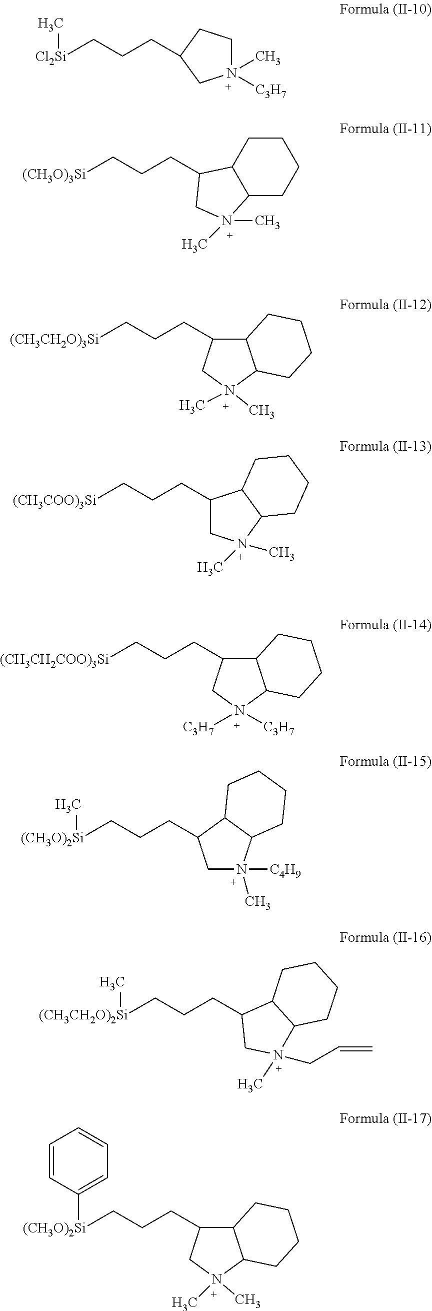

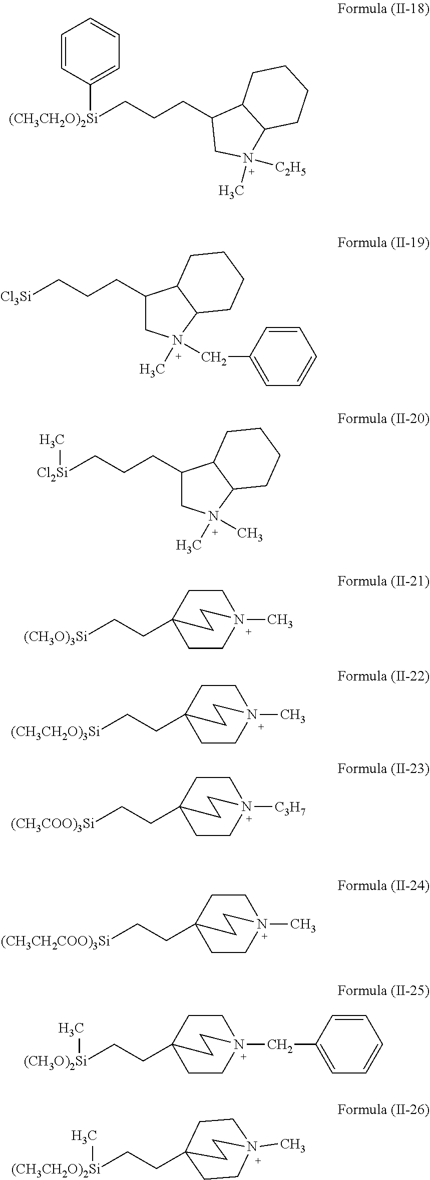

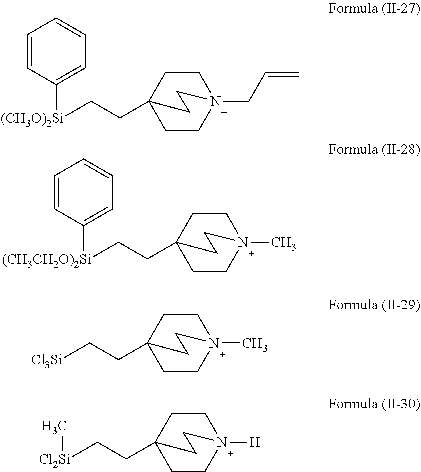

In yet another embodiment, R¹² (i.e., the group bonded to the silicon atom in Formula (5)) is a chain ammonium group of the following Formula (S3).

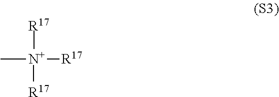

In Formula (S3), R¹⁷ is each independently a hydrogen atom, an alkyl group, an aryl group, an aralkyl group, a halogenated alkyl group, a halogenated aryl group, a halogenated aralkyl group, or an alkenyl group. Specific examples of the alkyl group, the aryl group, the aralkyl group, the halogenated alkyl group, the halogenated aryl group, the halogenated aralkyl group, and the alkenyl group, and preferred carbon atom numbers thereof are the same as those described above.

The chain ammonium group of Formula (S3) is directly bonded to the silicon atom. Alternatively, the chain ammonium group is bonded to a linking group to form an organic group containing the chain ammonium group, and the organic group is bonded to the silicon atom.

The linking group is, for example, an alkylene group, an arylene group, or an alkenylene group. Specific examples of the alkylene group, the arylene group, and the alkenylene group are the same as those described above.

Specific examples of the silane compound (hydrolyzable organosilane) of Formula (5) having the chain ammonium group of Formula (S3) include, but are not limited to, silanes of the following Formulae (III-1) to (III-28).

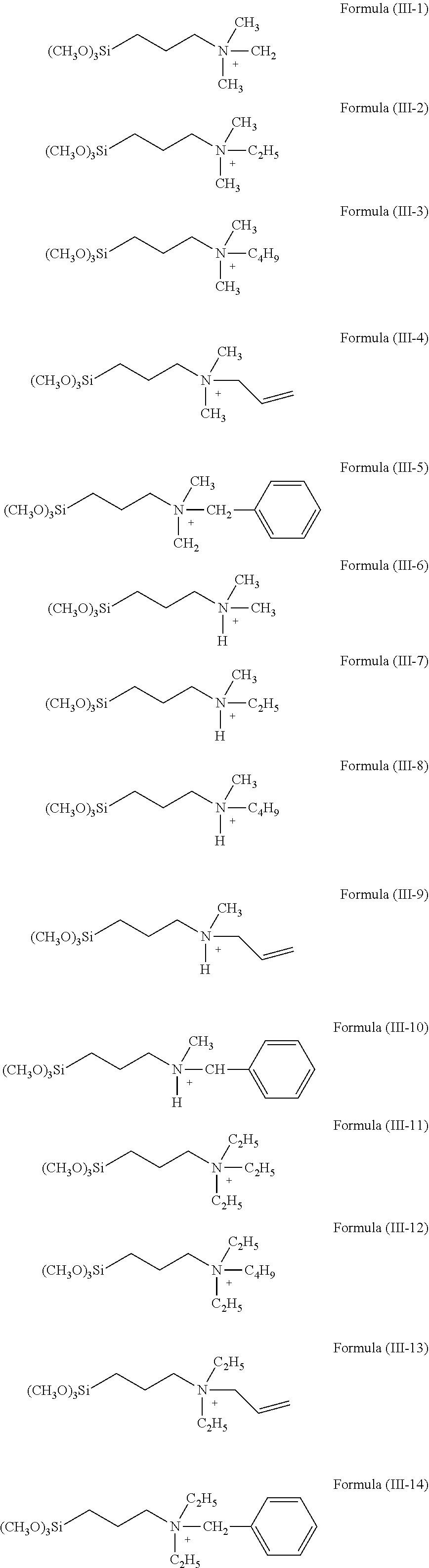

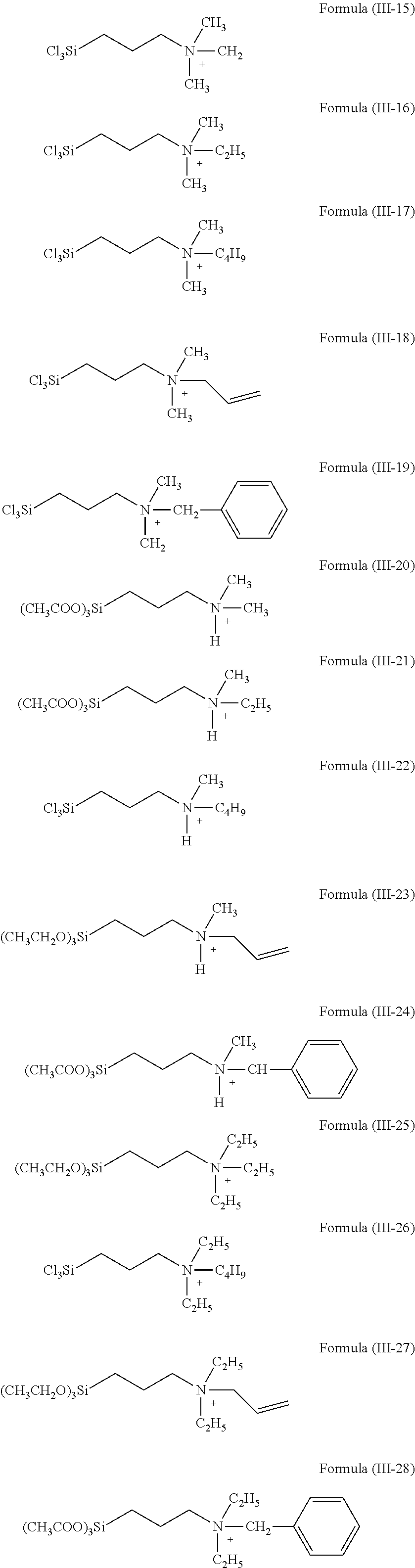

### <Silane Compound Having Sulfone Group or Sulfonamide Group (Hydrolyzable Organosilane)>

Examples of the silane compound having a sulfone group and the silane compound having a sulfonamide group include, but are not limited to, compounds of the following Formulae (B-1) to (B-36).

In the following Formulae, Me denotes a methyl group, and Et denotes an ethyl group.

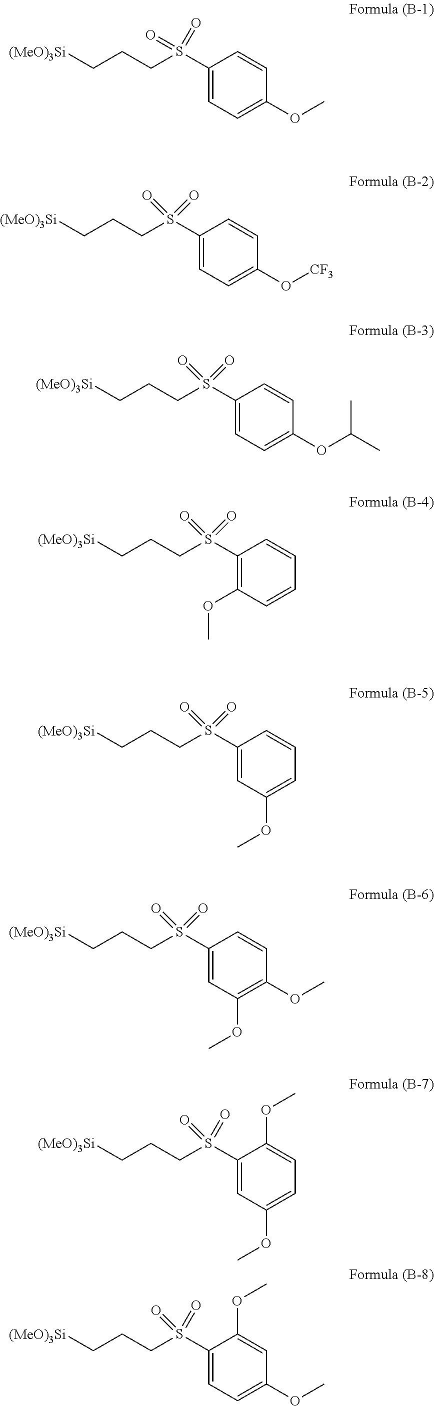

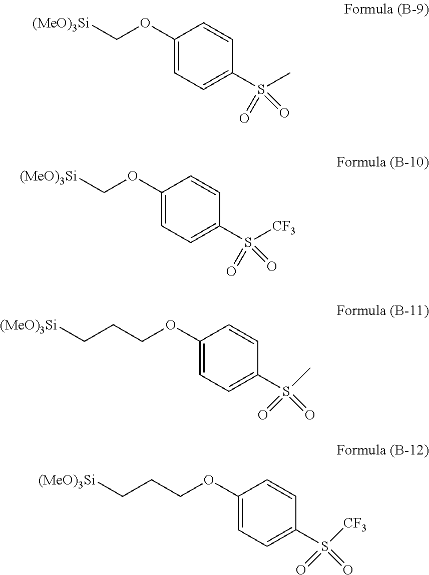

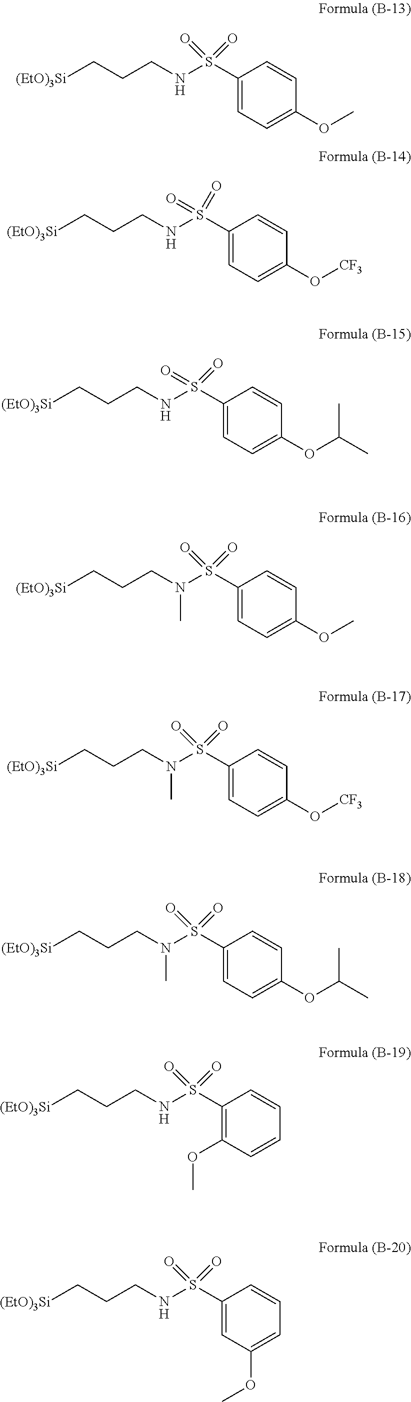

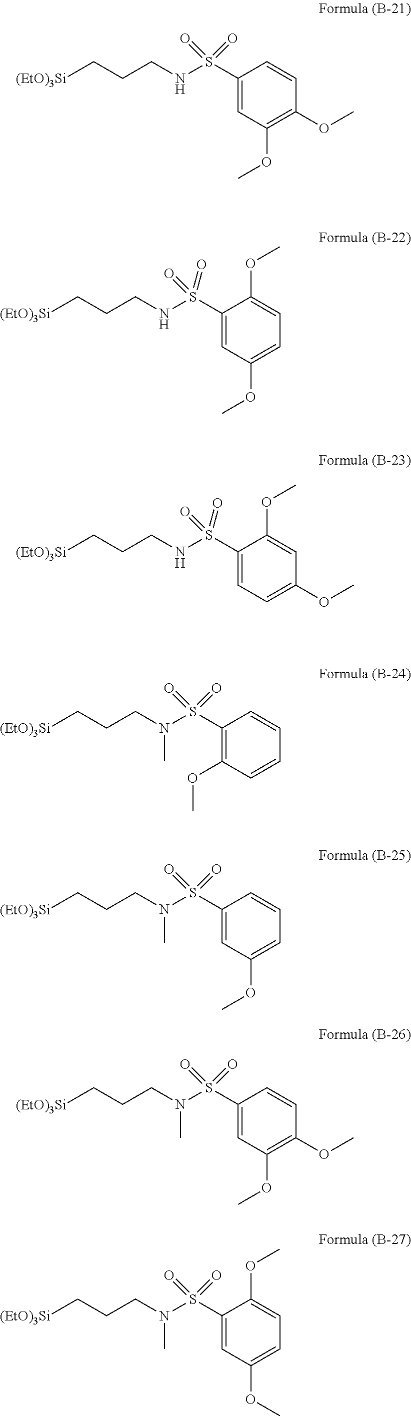

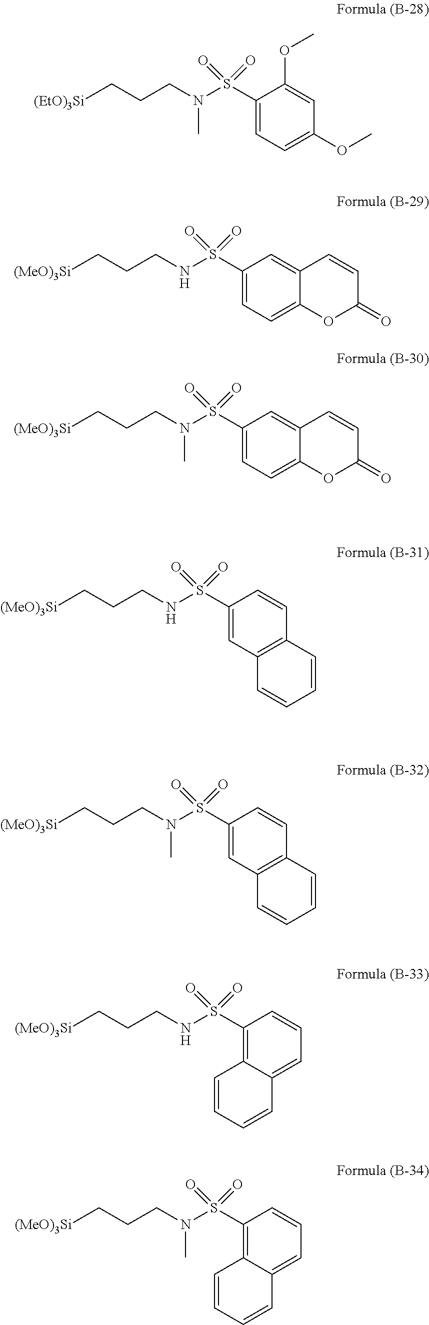

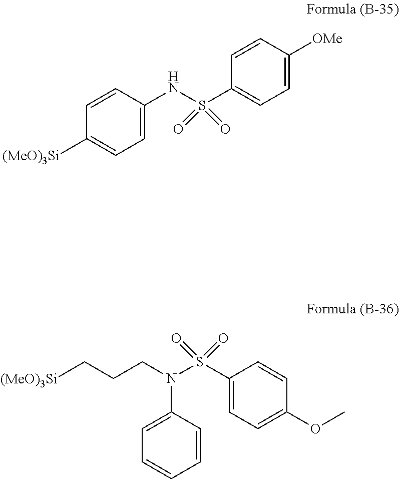

### <Silane Compound Having Cyclic Urea Structure in Molecule (Hydrolyzable Organosilane)>

The hydrolyzable organosilane having a cyclic urea structure in the molecule is, for example, a hydrolyzable organosilane of the following Formula (6-1).

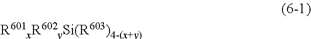

In Formula (6-1), R⁶⁰¹ is a group bonded to the silicon atom, and is each independently a group of the following Formula (6-2).

R⁶⁰² is a group bonded to the silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, or a cyano group.

R⁰⁰³ is a group or atom bonded to the silicon atom, and is each independently an alkoxy group, an aralkyloxy group, an acyloxy group, or a halogen atom.

In Formula (6-1), x is 1 or 2; y is 0 or 1; and x and y satisfy a relation of x+y≤2.

Specific examples of the alkyl group, aryl group, aralkyl group, halogenated alkyl group, halogenated aryl group, halogenated aralkyl group, alkoxyalkyl group, alkoxyaryl group, alkoxyaralkyl group, alkenyl group, and organic group containing an epoxy group, an acryloyl group, a methacryloyl group, a mercapto group, or a cyano group of R⁶⁰², the alkoxy group, aralkyloxy group, acyloxy group, and halogen atom of R⁶⁰³, and the substituent of each of these groups, and preferred carbon atom numbers thereof are the same as those described above regarding R² and R³.

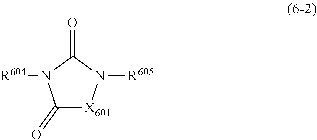

In Formula (6-2), R⁶⁰⁴ is each independently a hydrogen atom, a substitutable alkyl group, a substitutable alkenyl group, or an organic group containing an epoxy group or a sulfonyl group; and R⁶⁰⁵ is each independently an alkylene group, a hydroxyalkylene, a sulfide bond (—S—), an ether bond (—O—), or an ester bond (—CO—O— or —O—CO—).

Specific examples of the substitutable alkyl group, the substitutable alkenyl group, and the organic group containing an epoxy group of R⁶⁰⁴, and preferred carbon atom numbers thereof are the same as those described above regarding R². Other preferred examples of the substitutable alkyl group of R⁶⁰⁴ include an alkyl group wherein the terminal hydrogen atom is substituted with a vinyl group. Specific examples of the alkyl group include allyl group, 2-vinylethyl group, 3-vinylpropyl group, and 4-vinylbutyl group.

No particular limitation is imposed on the organic group containing a sulfonyl group, so long as it contains a sulfonyl group. Examples of the organic group containing a sulfonyl group include substitutable alkylsulfonyl group, substitutable arylsulfonyl group, substitutable aralkylsulfonyl group, substitutable halogenated alkylsulfonyl group, substitutable halogenated arylsulfonyl group, substitutable halogenated aralkylsulfonyl group, substitutable alkoxyalkylsulfonyl group, substitutable alkoxyarylsulfonyl group, substitutable alkoxyaralkylsulfonyl group, and substitutable alkenylsulfonyl group.

Specific examples of the alkyl group, aryl group, aralkyl group, halogenated alkyl group, halogenated aryl group, halogenated aralkyl group, alkoxyalkyl group, alkoxyaryl group, alkoxyaralkyl group, and alkenyl group of the aforementioned groups, the substituent of these groups, and preferred carbon atom numbers thereof are the same as those described above regarding R².

The alkylene group of R⁶⁰⁵ is a divalent group derived from the aforementioned alkyl group through removal of one hydrogen atom, and may have a linear, branched, or cyclic structure. Specific examples of the alkylene group are the same as those described above. No particular limitation is imposed on the carbon atom number of the alkylene group, but the carbon atom number is preferably 40 or less, more preferably 30 or less, still more preferably 20 or less, much more preferably 10 or less.

The alkylene group of R⁶⁰⁵ may have one or more selected from among a sulfide bond, an ether bond, and an ester bond at an end or middle portion (preferably at a middle portion) of the alkylene group.

Specific examples of the alkylene group include, but are not limited to, linear alkylene groups, such as methylene group, ethylene group, trimethylene group, methylethylene, tetramethylene group, pentamethylene group, hexamethylene group, heptamethylene group, octamethylene group, nonamethylene group, and decamethylene group; branched alkylene groups, such as 1-methyltrimethylene group, 2-methyltrimethylene group, 1,1-dimethylethylene group, 1-methyltetramethylene group, 2-methyltetramethylene group, 1,1-dimethyltrimethylene group, 1,2-dimethyltrimethylene group, 2,2-dimethyltrimethylene group, and 1-ethyltrimethylene group; cyclic alkylene groups, such as 1,2-cyclopropanediyl group, 1,2-cyclobutanediyl group, 1,3-cyclobutanediyl group, 1,2-cyclohexanediyl group, and 1,3-cyclohexanediyl group; and alkylene groups containing an ether group, etc. such as —CH₂OCH₂—, —CH₂CH₂OCH₂—, —CH₂CH₂OCH₂CH₂—, —CH₂CH₂CH₂OCH₂CH₂—, —CH₂CH₂OCH₂CH₂CH₂—, —CH₂CH₂CH₂OCH₂CH₂CH₂—, —CH₂SCH₂—, —CH₂CH₂SCH₂—, —CH₂CH₂SCH₂CH₂—, —CH₂CH₂CH₂SCH₂CH₂—, —CH₂CH₂SCH₂CH₂CH₂—, —CH₂CH₂CH₂SCH₂CH₂CH₂—, and —CH₂OCH₂CH₂SCH₂—.

The hydroxyalkylene group is prepared by substitution of at least one hydrogen atom of the aforementioned alkylene group with a hydroxy group. Specific examples of the hydroxyalkylene group include, but are not limited to, hydroxymethylene group, 1-hydroxyethylene group, 2-hydroxyethylene group, 1,2-dihydroxyethylene group, 1-hydroxytrimethylene group, 2-hydroxytrimethylene group, 3-hydroxytrimethylene group, 1-hydroxytetramethylene group, 2-hydroxytetramethylene group, 3-hydroxytetramethylene group, 4-hydroxytetramethylene group, 1,2-dihydroxytetramethylene group, 1,3-dihydroxytetramethylene group, 1,4-dihydroxytetramethylene group, 2,3-dihydroxytetramethylene group, 2,4-dihydroxytetramethylene group, and 4,4-dihydroxytetramethylene group.

In Formula (6-2), X₆₀₁ is each independently a group of any of the following Formulae (6-3) to (6-5), and the carbon atom of the ketone group in each of the following Formulae (6-4) and (6-5) is bonded to the nitrogen atom bonded to R⁶⁰⁵ in Formula (6-2).

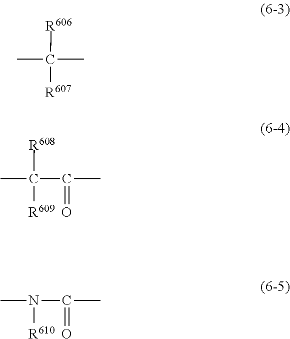

In Formulae (6-3) to (6-5), R⁶⁰⁶ to R⁶¹⁰ are each independently a hydrogen atom, a substitutable alkyl group, a substitutable alkenyl group, or an organic group containing an epoxy group or a sulfonyl group. Specific examples of the substitutable alkyl group, substitutable alkenyl group, and organic group containing an epoxy group or a sulfonyl group, and preferred carbon atom numbers thereof are the same as those described above regarding R⁶⁰⁴.

In particular, X₆₀₁ is preferably a group of Formula (6-5), from the viewpoint of achieving excellent lithographic property at high reproducibility.

At least one of R⁶⁰⁴ and R⁶⁰⁶ to R⁶¹⁰ is preferably an alkyl group wherein the terminal hydrogen atom is substituted with a vinyl group, from the viewpoint of achieving excellent lithographic property at high reproducibility.

The hydrolyzable organosilane of Formula (6-1) may be a commercially available product, or may be synthesized by a known method described in, for example, WO 2011/102470.

Specific examples of the hydrolyzable organosilane of Formula (6-1) include, but are not limited to, silanes of the following Formulae (6-1-1) to (Jun. 1, 2029).

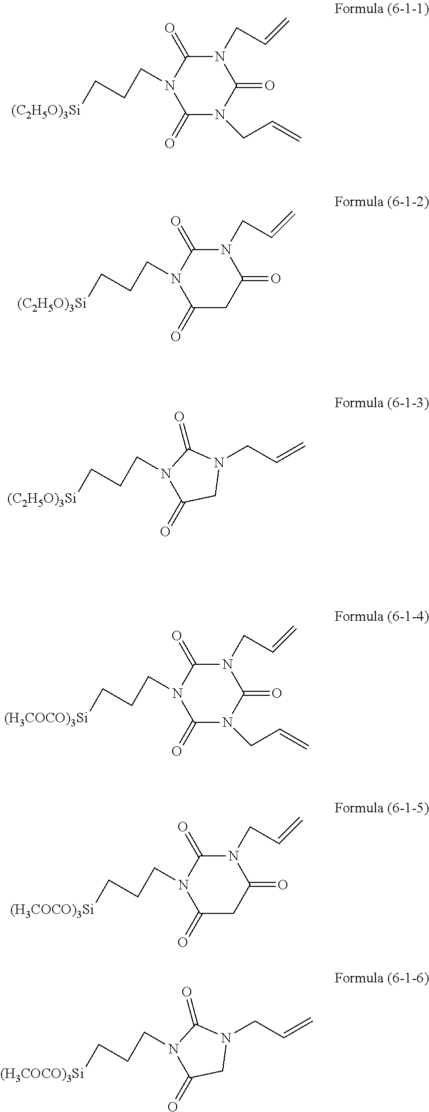

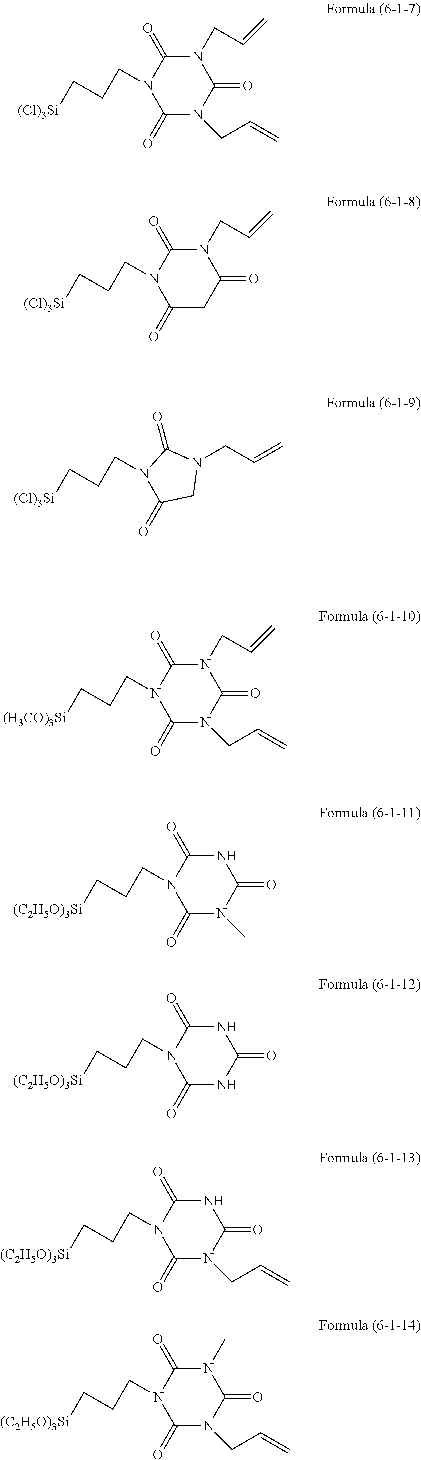

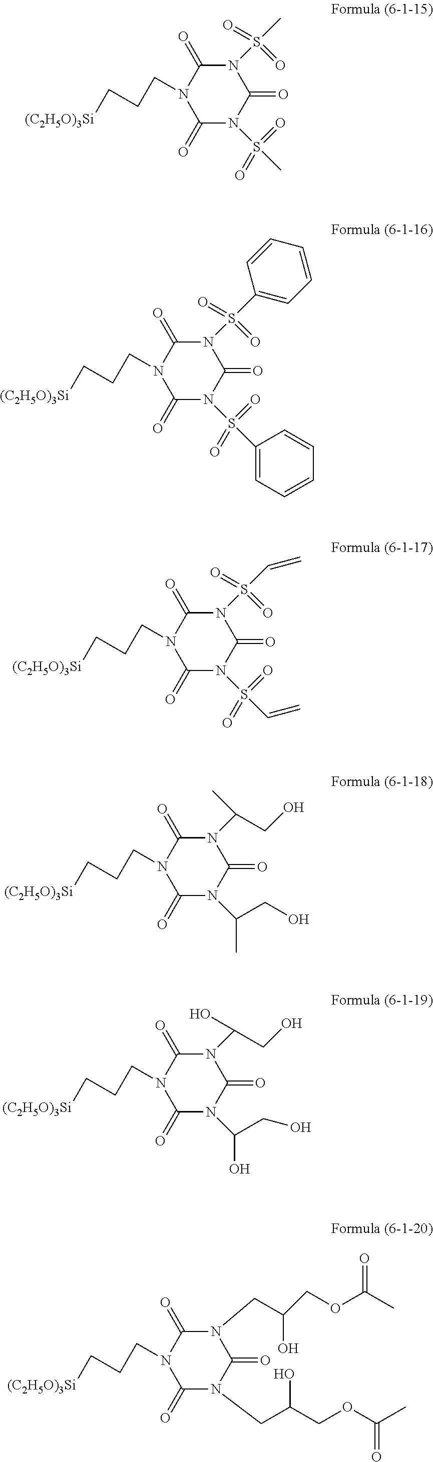

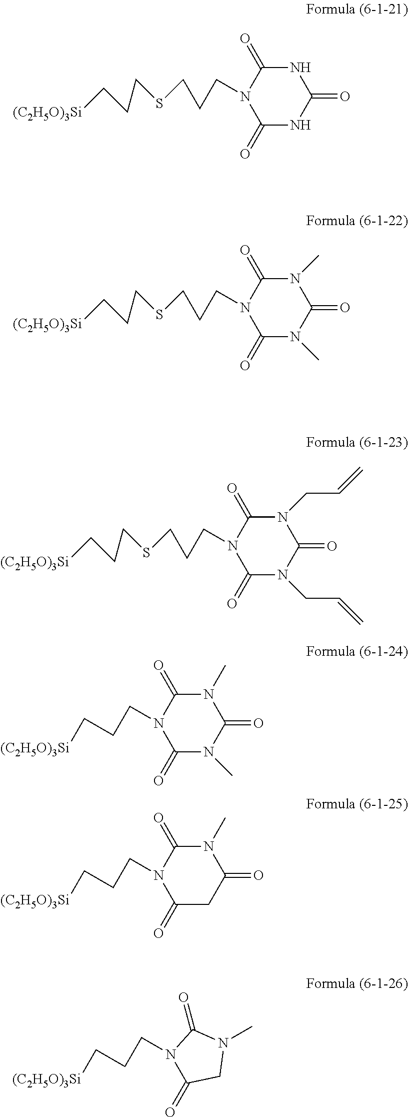

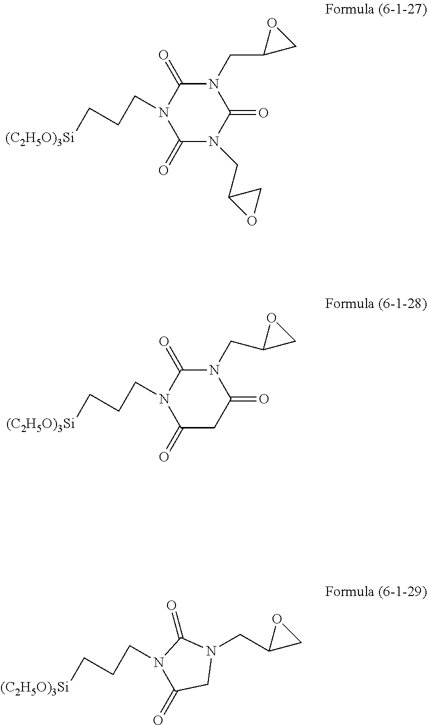

The polysiloxane [A] may be a hydrolysis condensate of a hydrolyzable silane containing a silane compound other than those exemplified above, so long as the effects of the present invention are not impaired.

In one preferred embodiment of the present invention, the polysiloxane [A] contains a hydrolysis condensate of a hydrolyzable silane containing a hydrolyzable silane of Formula (1) and, if desired, a hydrolyzable silane of Formula (2) containing an amino group-containing organic group and an additional hydrolyzable silane.

The aforementioned hydrolysis condensate may be a hydrolysis condensate of a hydrolyzable silane containing a hydrolyzable silane of Formula (1) in an amount of, for example, 0.1% by mole to 10% by mole relative to the total amount of the hydrolyzable silane.

The aforementioned hydrolysis condensate may be a hydrolysis condensate of a hydrolyzable silane containing a hydrolyzable silane of Formula (2) containing an amino group-containing organic group in an amount of, for example, 0.1% by mole or more, preferably 1% by mole or more, relative to the total amount of the hydrolyzable silane.

When a hydrolyzable silane other than the hydrolyzable silane of Formula (1) is used, the amount of the hydrolyzable silane of Formula (1) added may be, for example, 0.1% by mole to 10% by mole relative to the total amount (100% by mole) of the hydrolyzable silane added.

When the hydrolyzable silane of Formula (2) containing an amino group-containing organic group is used as the aforementioned hydrolyzable silane, the amount of the hydrolyzable silane of Formula (2) added may be, for example, 0.1% by mole or more, preferably 1% by mole or more, relative to the total amount (100% by mole) of the hydrolyzable silane added.

When a hydrolyzable organosilane of Formula (4) having an onium group in the molecule is used in the hydrolyzable silane mixture, the amount of the organosilane added is generally 0.01% by mole or more, preferably 0.1% by mole or more, and generally 30% by mole or less, preferably 10% by mole or less, relative to the total amount of all silane compounds (hydrolyzable silanes) added.

The aforementioned hydrolysis condensate of hydrolyzable silane may have a weight average molecular weight of, for example, 500 to 1,000,000. From the viewpoint of, for example, preventing the precipitation of the hydrolysis condensate in the composition, the weight average molecular weight is preferably 500,000 or less, more preferably 250,000 or less, still more preferably 100,000 or less. From the viewpoint of, for example, the compatibility between storage stability and applicability, the weight average molecular weight is preferably 700 or more, more preferably 1,000 or more.

The weight average molecular weight is determined by GPC analysis in terms of polystyrene. The GPC analysis can be performed under, for example, the following conditions: GPC apparatus (trade name: HLC-8220GPC, available from Tosoh Corporation), GPC columns (trade name: Shodex (registered trademark) KF803L, KF802, and KF801, available from Showa Denko K.K.), a column temperature of 40° C., tetrahydrofuran serving as an eluent (elution solvent), a flow amount (flow rate) of 1.0 mL/min, and polystyrene (available from Showa Denko K.K.) as a standard sample.

The hydrolysis condensate of hydrolyzable silane is prepared by hydrolysis and condensation of the aforementioned silane compound (hydrolyzable silane).

The aforementioned silane compound (hydrolyzable silane) contains an alkoxy group, aralkyloxy group, acyloxy group, or halogen atom directly bonded to the silicon atom; i.e., an alkoxysilyl group, an aralkyloxysilyl group, an acyloxysilyl group, or a halogenated silyl group (hereinafter such a group may be referred to as “hydrolyzable group”).

For the hydrolysis of the hydrolyzable group, generally 0.1 to 100 mol, for example, 0.5 to 100 mol (preferably 1 to 10 mol) of water is used per mol of the hydrolyzable group.

A hydrolysis catalyst may be used during the hydrolysis and condensation of the hydrolyzable silane for the purpose of, for example, promoting the reaction. Alternatively, the hydrolysis and condensation may be performed without use of a hydrolysis catalyst. In the present invention, nitric acid (which also serves as a hydrolysis catalyst) is preferably used, since the hydrolysis and condensation in the presence of nitric acid produces a hydrolysis condensate containing a quaternary ammonium nitrate structure when the amino group-containing silane compound of Formula (2) is used. The amount of the hydrolysis catalyst used may be generally 0.0001 to 10 mol, preferably 0.001 to 1 mol per mol of the hydrolyzable group.

The reaction temperature for the hydrolysis and condensation is generally equal to or higher than room temperature and equal to or lower than the reflux temperature (at ambient pressure) of an organic solvent usable for the hydrolysis. The reaction temperature may be, for example, 20 to 110° C., or, for example, 20 to 80° C.

The hydrolysis may be performed completely; i.e., all hydrolyzable groups may be converted into silanol groups, or may be performed partially; i.e., unreacted hydrolyzable groups may remain.

Examples of the hydrolysis catalyst usable for the hydrolysis and condensation include a metal chelate compound, an organic acid, an inorganic acid, an organic base, and an inorganic base.

Examples of the metal chelate compound serving as a hydrolysis catalyst include, but are not limited to, titanium chelate compounds, such as triethoxy·mono(acetylacetonato) titanium, tri-n-propoxy·mono(acetylacetonato) titanium, tri-i-propoxy·mono(acetylacetonato) titanium, tri-n-butoxy·mono(acetylacetonato) titanium, tri-sec-butoxy·mono(acetylacetonato) titanium, tri-t-butoxy·mono(acetylacetonato) titanium, diethoxy·bis(acetylacetonato) titanium, di-n-propoxy·bis(acetylacetonato) titanium, di-i-propoxy·bis(acetylacetonato) titanium, di-n-butoxy·bis(acetylacetonato) titanium, di-sec-butoxy·bis(acetylacetonato) titanium, di-t-butoxy·bis(acetylacetonato) titanium, monoethoxy·tris(acetylacetonato) titanium, mono-n-propoxy·tris(acetylacetonato) titanium, mono-i-propoxy·tris(acetylacetonato) titanium, mono-n-butoxy·tris(acetylacetonato) titanium, mono-sec-butoxy·tris(acetylacetonato) titanium, mono-t-butoxy·tris(acetylacetonato) titanium, tetrakis(acetylacetonato) titanium, triethoxy·mono(ethylacetoacetato) titanium, tri-n-propoxy·mono(ethylacetoacetato) titanium, tri-i-propoxy·mono(ethylacetoacetato) titanium, tri-n-butoxy·mono(ethylacetoacetato) titanium, tri-sec-butoxy·mono(ethylacetoacetato) titanium, tri-t-butoxy·mono(ethylacetoacetato) titanium, diethoxy·bis(ethylacetoacetato) titanium, di-n-propoxy·bis(ethylacetoacetato) titanium, di-i-propoxy·bis(ethylacetoacetato) titanium, di-n-butoxy·bis(ethylacetoacetato) titanium, di-sec-butoxy·bis(ethylacetoacetato) titanium, di-t-butoxy·bis(ethylacetoacetato) titanium, monoethoxy·tris(ethylacetoacetato) titanium, mono-n-propoxy·tris(ethylacetoacetato) titanium, mono-i-propoxy·tris(ethylacetoacetato) titanium, mono-n-butoxy·tris(ethylacetoacetato) titanium, mono-sec-butoxy·tris(ethylacetoacetato) titanium, mono-t-butoxy·tris(ethylacetoacetato) titanium, tetrakis(ethylacetoacetato) titanium, mono(acetylacetonato) tris(ethylacetoacetato) titanium, bis(acetylacetonato) bis(ethylacetoacetato) titanium, and tris(acetylacetonato) mono(ethylacetoacetato) titanium; zirconium chelate compounds, such as triethoxy·mono(acetylacetonato) zirconium, tri-n-propoxy·mono(acetylacetonato) zirconium, tri-i-propoxy·mono(acetylacetonato) zirconium, tri-n-butoxy·mono(acetylacetonato) zirconium, tri-sec-butoxy·mono(acetylacetonato) zirconium, tri-t-butoxy·mono(acetylacetonato) zirconium, diethoxy·bis(acetylacetonato) zirconium, di-n-propoxy·bis(acetylacetonato) zirconium, di-i-propoxy·bis(acetylacetonato) zirconium, di-n-butoxy·bis(acetylacetonato) zirconium, di-sec-butoxy·bis(acetylacetonato) zirconium, di-t-butoxy·bis(acetylacetonato) zirconium, monoethoxy·tris(acetylacetonato) zirconium, mono-n-propoxy·tris(acetylacetonato) zirconium, mono-i-propoxy·tris(acetylacetonato) zirconium, mono-n-butoxy·tris(acetylacetonato) zirconium, mono-sec-butoxy·tris(acetylacetonato) zirconium, mono-t-butoxy·tris(acetylacetonato) zirconium, tetrakis(acetylacetonato) zirconium, triethoxy·mono(ethylacetoacetato) zirconium, tri-n-propoxy·mono(ethylacetoacetato) zirconium, tri-i-propoxy·mono(ethylacetoacetato) zirconium, tri-n-butoxy·mono(ethylacetoacetato) zirconium, tri-sec-butoxy·mono(ethylacetoacetato) zirconium, tri-t-butoxy·mono(ethylacetoacetato) zirconium, diethoxy·bis(ethylacetoacetato) zirconium, di-n-propoxy·bis(ethylacetoacetato) zirconium, di-i-propoxy·bis(ethylacetoacetato) zirconium, di-n-butoxy·bis(ethylacetoacetato) zirconium, di-sec-butoxy·bis(ethylacetoacetato) zirconium, di-t-butoxy·bis(ethylacetoacetato) zirconium, monoethoxy·tris(ethylacetoacetato) zirconium, mono-n-propoxy·tris(ethylacetoacetato) zirconium, mono-i-propoxy·tris(ethylacetoacetato) zirconium, mono-n-butoxy·tris(ethylacetoacetato) zirconium, mono-sec-butoxy·tris(ethylacetoacetato) zirconium, mono-t-butoxy·tris(ethylacetoacetato) zirconium, tetrakis(ethylacetoacetato) zirconium, mono(acetylacetonato) tris(ethylacetoacetato) zirconium, bis(acetylacetonato) bis(ethylacetoacetato) zirconium, and tris(acetylacetonato) mono(ethylacetoacetato) zirconium; and aluminum chelate compounds, such as tris(acetylacetonato) aluminum and tris(ethylacetoacetato) aluminum.

Examples of the organic acid serving as a hydrolysis catalyst include, but are not limited to, acetic acid, propionic acid, butanoic acid, pentanoic acid, hexanoic acid, heptanoic acid, octanoic acid, nonanoic acid, decanoic acid, oxalic acid, maleic acid, methylmalonic acid, adipic acid, sebacic acid, gallic acid, butyric acid, mellitic acid, arachidonic acid, 2-ethylhexanoic acid, oleic acid, stearic acid, linoleic acid, linolenic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, sulfonic acid, phthalic acid, fumaric acid, citric acid, and tartaric acid.

Examples of the inorganic acid serving as a hydrolysis catalyst include, but are not limited to, hydrochloric acid, sulfuric acid, hydrofluoric acid, and phosphoric acid in addition to nitric acid described above.

Examples of the organic base serving as a hydrolysis catalyst include, but are not limited to, pyridine, pyrrole, piperazine, pyrrolidine, piperidine, picoline, trimethylamine, triethylamine, monoethanolamine, diethanolamine, dimethylmonoethanolamine, monomethyldiethanolamine, triethanolamine, diazabicyclooctane, diazabicyclononane, diazabicycloundecene, tetramethylammonium hydroxide, tetraethylammonium hydroxide, tetrapropylammonium hydroxide, tetrabutylammonium hydroxide, trimethylphenylammonium hydroxide, benzyltrimethylammonium hydroxide, and benzyltriethylammonium hydroxide.

Examples of the inorganic base serving as a hydrolysis catalyst include, but are not limited to, ammonia, sodium hydroxide, potassium hydroxide, barium hydroxide, and calcium hydroxide.

Among these catalysts, a metal chelate compound, an organic acid, or an inorganic acid is preferred. These catalysts may be used alone or in combination of two or more species.

In particular, nitric acid is preferably used as a hydrolysis catalyst in the present invention. The use of nitric acid enables an improvement in the storage stability of a reaction solution after the hydrolysis and condensation, and particularly enables suppression of a change in the molecular weight of a hydrolysis condensate. It is known that the stability of the hydrolysis condensate contained in the reaction solution depends on the pH of the solution. The present inventors have conducted extensive studies, and as a result have found that the pH of the reaction mixture falls in a stable range by use of an appropriate amount of nitric acid.

As described above, the use of nitric acid is preferred, from the viewpoint of producing a hydrolysis condensate containing a quaternary ammonium nitrate structure when the amino group-containing silane compound is used.

An organic solvent may be used for the hydrolysis and condensation. Specific examples of the organic solvent include, but are not limited to, aliphatic hydrocarbon solvents, such as n-pentane, i-pentane, n-hexane, i-hexane, n-heptane, i-heptane, 2,2,4-trimethylpentane, n-octane, i-octane, cyclohexane, and methylcyclohexane; aromatic hydrocarbon solvents, such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, and n-amylnaphthalene; monohydric alcohol solvents, such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, n-heptanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; polyhydric alcohol solvents, such as ethylene glycol, propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and glycerin; ketone solvents, such as acetone, methyl ethyl ketone, methyl-n-propyl ketone, methyl-n-butyl ketone, diethyl ketone, methyl-1-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchone; ether or ether alcohol solvents, such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether (1-methoxy-2-propanol), propylene glycol monoethyl ether (1-ethoxy-2-propanol), propylene glycol monopropyl ether, propylene glycol monobutyl ether, propylene glycol monomethyl ether acetate (1-methoxy-2-propanol acetate), dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran; ester solvents, such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethylene glycol diacetate, triethylene glycol methyl ether acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate; nitrogen-containing solvents, such as N-methylformamide, N,N-dimethylformamide, N,N-diethylformamide, acetamide, N-methylacetamide, N,N-dimethylacetamide, N-methylpropionamide, and N-methyl-2-pyrrolidone; and sulfur-containing solvents, such as dimethyl sulfide, diethyl sulfide, thiophene, tetrahydrothiophene, dimethyl sulfoxide, sulfolane, and 1,3-propanesultone. These solvents may be used alone or in combination of two or more species.

After completion of the hydrolysis and condensation reactions, the reaction solution is used as is, or diluted or concentrated. The resultant reaction solution can be neutralized and treated with an ion-exchange resin, to thereby remove the hydrolysis catalyst (e.g., an acid or a base) used for the hydrolysis and condensation. Before or after such a treatment, alcohols (i.e., by-products), water, the used hydrolysis catalyst, etc. can be removed from the reaction solution through, for example, distillation under reduced pressure.

The thus-prepared hydrolysis condensate (hereinafter may be referred to as “polysiloxane”) is in the form of a polysiloxane varnish dissolved in an organic solvent. The polysiloxane varnish may be used as is for preparation of the resist underlayer film-forming composition described below. Thus, the aforementioned reaction solution may be used as is (or may be diluted) for preparation of the resist underlayer film-forming composition. In this case, the hydrolysis catalyst used for the hydrolysis and condensation, by-products, etc. may remain in the reaction solution, so long as the effects of the present invention are not impaired.

The resultant polysiloxane varnish may be subjected to solvent replacement, or may be appropriately diluted with a solvent. If the resultant polysiloxane varnish does not exhibit poor storage stability, the organic solvent may be distilled off to thereby achieve a solid content concentration of 100%.

The organic solvent used for the solvent replacement or dilution of the polysiloxane varnish may be identical to or different from the organic solvent used for the hydrolysis and condensation reactions of the hydrolyzable silane. No particular limitation is imposed on the type of the solvent for dilution, and one solvent or two or more solvents may be arbitrarily selected and used.

### [B] Solvent

No particular limitation is imposed on the solvent [B] used in the silicon-containing resist underlayer film-forming composition of the present invention, so long as the solvent can dissolve and mix the aforementioned polysiloxane [A] and additional components described below.

Specific examples of the solvent [B] include methylcellosolve acetate, ethylcellosolve acetate, propylene glycol, propylene glycol monomethyl ether (1-methoxy-2-propanol), propylene glycol monoethyl ether (1-ethoxy-2-propanol), methyl isobutyl carbinol (4-methyl-2-pentanol), propylene glycol monobutyl ether, propylene glycol monomethyl ether acetate (1-methoxy-2-propanol monoacetate), propylene glycol monoethyl ether acetate, propylene glycol monopropyl ether acetate, propylene glycol monobutyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropinoate, ethyl 3-methoxypropionate, ethyl 3-ethoxypropionate, methyl 3-ethoxypropionate, methyl pyruvate, ethyl pyruvate, ethylene glycol monomethyl ether, ethylene glycol monoethyl ether, ethylene glycol monopropyl ether, ethylene glycol monobutyl ether, ethylene glycol monomethyl ether acetate, ethylene glycol mooethyl ether acetate, ethylene glycol monopropyl ether acetate, ethylene glycol monobutyl ether acetate, diethylene glycol dimethyl ether, diethylene glycol diethyl ether, diethylene glycol dipropyl ether, diethylene glycol dibutyl ether, propylene glycol dimethyl ether, propylene glycol diethyl ether, propylene glycol dipropyl ether, propylene glycol dibutyl ether, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methybutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, methyl propyl ketone, methyl butyl ketone, 2-heptanone, 3-heptanone, 4-heptanone, N,N-dimethylformamide, N-methylacetamide, N,N-dimethylacetamide, N-methyl-2-pyrrolidone, and γ-butyrolactone. In addition to these, an organic solvent used for the production of the aforementioned polysiloxane [A] may be used. These solvents [B] may be used alone or in combination of two or more species.

The silicon-containing resist underlayer film-forming composition of the present invention may contain water as a solvent. When the composition contains water as a solvent, the amount of water is, for example, 30% by mass or less, preferably 20% by mass or less, more preferably 15% by mass or less, relative to the total mass of the solvents contained in the composition.

### [Silicon-Containing Resist Underlayer Film-Forming Composition]

The silicon-containing resist underlayer film-forming composition of the present invention contains the aforementioned polysiloxane [A] and solvent [B], and may further contain an additional component described below.

The concentration of the solid content in the resist underlayer film-forming composition may be, for example, 0.1 to 50% by mass, 0.1 to 30% by mass, 0.1 to 25% by mass, or 0.5 to 20.0% by mass, relative to the total mass of the composition. The “solid content” as described above refers to all components (except for the solvent [B] component) contained in the composition.

The amount of the polysiloxane [A] in the solid content is generally 20% by mass to 100% by mass. From the viewpoint of, for example, achieving the aforementioned effects of the present invention at high reproducibility, the lower limit of the amount of the polysiloxane [A] is preferably 50% by mass, more preferably 60% by mass, still more preferably 70% by mass, much more preferably 80% by mass, and the upper limit of the amount is preferably 99% by mass. The balance may be an additive described below.

The resist underlayer film-forming composition has a pH of, for example, 2 to 5, and may have a pH of 3 to 4.

The resist underlayer film-forming composition can be produced by mixing of the aforementioned polysiloxane [A] and solvent [B] and, as appropriate, an additional component (if incorporated). In this case, a solution containing the polysiloxane [A] may be preliminarily prepared, and the solution may be mixed with the solvent [B] and an additional component. The reaction solution produced during preparation of the polysiloxane [A] may be used as is for preparation of the resist underlayer film-forming composition.

No particular limitation is imposed on the order of mixing of these components. For example, the solvent [B] may be added to and mixed with a solution containing the polysiloxane [A], and an additional component may be added to the resultant mixture. Alternatively, a solution containing the polysiloxane [A], the solvent [B], and an additional component may be mixed simultaneously.

If necessary, the solvent [B] may be finally added, or some components that can be relatively easily dissolved in the solvent [B] may be finally added without being incorporated into the mixture. However, from the viewpoint of preventing aggregation or separation of components to prepare a highly homogeneous composition with high reproducibility, the composition is preferably prepared from a preliminarily prepared solution containing the well-dissolved polysiloxane [A]. It should be noted that the polysiloxane [A] may be aggregated or precipitated when mixed with the solvent [B] or an additional component, depending on, for example, the type or amount of the solvent [B] or the amount or nature of the component. It should also be noted that when a composition is prepared from a solution containing the polysiloxane [A], the concentration of the solution of the polysiloxane [A] or the amount of the solution used must be determined so as to achieve a desired amount of the polysiloxane [A] contained in the finally produced composition.

During preparation of the composition, the composition may be appropriately heated so long as the components are not decomposed or denatured.

In the present invention, the resist underlayer film-forming composition may be filtered with, for example, a submicrometer-order filter during production of the composition or after mixing of all the components. No limitation is imposed on the type of the material of the filter used. For example, a nylon-made filter or a fluororesin-made filter may be used.

The silicon-containing resist underlayer film-forming composition of the present invention can be suitably used as a composition for forming a resist underlayer film used for a lithographic process.

### [Additional Additive]

The silicon-containing resist underlayer film-forming composition of the present invention may contain various additives depending on the intended use of the composition.

Examples of the additives include known additives incorporated in materials (compositions) for forming various films (e.g., resist underlayer film, anti-reflective coating, and pattern reversing film) that can be used in the production of a semiconductor device, such as a curing catalyst (e.g., an ammonium salt, a phosphine compound, a phosphonium salt, a sulfonium salt, or a nitrogen-containing silane compound), a crosslinking agent, a crosslinking catalyst, a stabilizer (e.g., an organic acid, water, or an alcohol), an organic polymer compound, an acid generator, a surfactant (e.g., a nonionic surfactant, an anionic surfactant, a cationic surfactant, a silicon-containing surfactant, a fluorine-containing surfactant, or a UV-curable surfactant), a pH adjuster, a metal oxide, a rheology controlling agent, and an adhesion aid.

Examples of various additives include, but are not limited to, those described below.

### <Curing Catalyst>

The silicon-containing resist underlayer film-forming composition of the present invention may contain no curing catalyst. Alternatively, the composition may contain a curing catalyst.

The aforementioned curing catalyst may be, for example, an ammonium salt, a phosphine compound, a phosphonium salt, or a sulfonium salt. The salt described below as an example of a curing catalyst may be added in the form of a salt, or may be a compound that forms a salt in the aforementioned composition (i.e., a compound that forms a salt in the reaction system, but is in a form different from the salt during addition).

Examples of the ammonium salt include:
a quaternary ammonium salt having a structure of the following Formula (D-1):

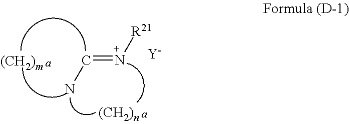

(wherein m^{a} is an integer of 2 to 11; n^{a} is an integer of 2 or 3; R²¹ is an alkyl group or an aryl group; and Y is an anion);
a quaternary ammonium salt having a structure of the following Formula (D-2):

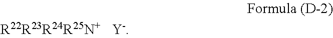

(wherein R²², R²³, R²⁴, and R²⁵ are each an alkyl group or an aryl group; N is a nitrogen atom; Y is an anion; and each of R²², R²³, R²⁴, and R²⁵ is bonded to the nitrogen atom);
a quaternary ammonium salt having a structure of the following Formula (D-3):

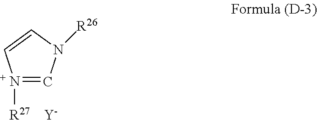

(wherein R²⁶ and R²⁷ are each an alkyl group or an aryl group; N is a nitrogen atom; and Y⁻ is an anion);
a quaternary ammonium salt having a structure of the following Formula (D-4):

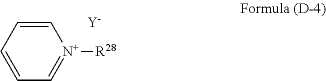

(wherein R²⁸ is an alkyl group or an aryl group; N is a nitrogen atom; and Y⁻ is an anion);
a quaternary ammonium salt having a structure of the following Formula (D-5):

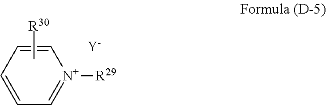

(wherein R²⁹ and R³⁰ are each an alkyl group or an aryl group; N is a nitrogen atom; and Y⁻ is an anion); and
a tertiary ammonium salt having a structure of the following Formula (D-6):

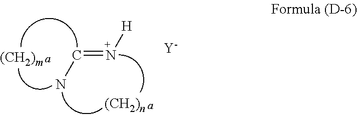

(wherein m^{a} is an integer of 2 to 11; n^{a} is an integer of 2 or 3; H is a hydrogen atom; N is a nitrogen atom; and Y is an anion).

Examples of the phosphonium salt include a quaternary phosphonium salt of the following Formula (D-7):

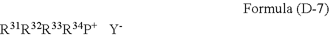

(wherein R³¹, R³², R³³, and R³⁴ are each an alkyl group or an aryl group; P is a phosphorus atom; Y⁻ is an anion; and each of R³¹, R³², R³³, and R³⁴ is bonded to the phosphorus atom).

Examples of the sulfonium salt include a tertiary sulfonium salt of the following Formula (D-8):

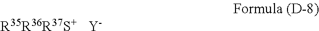

(wherein R³⁵, R³⁶, and R³⁷ are each an alkyl group or an aryl group; S is a sulfur atom; Y⁻ is an anion; and each of R³⁵, R³⁶, and R³⁷ is bonded to the sulfur atom).

The compound of Formula (D-1) is a quaternary ammonium salt derived from an amine. In Formula (D-1), m^{a} is an integer of 2 to 11, and n^{a} is an integer of 2 or 3. R²¹ of the quaternary ammonium salt is a C₁₋₁₈ (preferably C₂₋₁₀) alkyl group, or a C₆₋₁₈ aryl group. Examples thereof include linear alkyl groups, such as ethyl group, propyl group, and butyl group, benzyl group, cyclohexyl group, cyclohexylmethyl group, and dicyclopentadienyl group. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻).

The compound of Formula (D-2) is a quaternary ammonium salt having a structure of R²²R²³R²⁴R²⁵N⁺Y⁻. R²², R²³, R²⁴, and R²⁵ of the quaternary ammonium salt are each a C₁₋₁₈ alkyl group or a C₆₋₁₈ aryl group. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). The quaternary ammonium salt is commercially available, and examples of the quaternary ammonium salt include tetramethylammonium acetate, tetrabutylammonium acetate, triethylbenzylammonium chloride, triethylbenzylammonium bromide, trioctylmethylammonium chloride, tributylbenzylammonium chloride, and trimethylbenzylammonium chloride.

The compound of Formula (D-3) is a quaternary ammonium salt derived from 1-substituted imidazole. The carbon atom number of each of R²⁶ and R²⁷ is 1 to 18, and the total number of carbon atoms of R²⁶ and R²⁷ is preferably 7 or more. Examples of R²⁶ include methyl group, ethyl group, propyl group, phenyl group, and benzyl group. Examples of R²⁷ include benzyl group, octyl group, and octadecyl group. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). Although this compound is commercially available, the compound may be produced through, for example, reaction between an imidazole compound (e.g., 1-methylimidazole or 1-benzylimidazole) and an alkyl halide or an aryl halide (e.g., benzyl bromide or methyl bromide).

The compound of Formula (D-4) is a quaternary ammonium salt derived from pyridine. In Formula (D-4), R²⁸ is a C₁₋₁₈ (preferably C₄₋₁₈) alkyl group, or a C₆₋₁₈ aryl group. Examples thereof include butyl group, octyl group, benzyl group, and lauryl group. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). Although this compound is commercially available, the compound may be produced through, for example, reaction between pyridine and an alkyl halide or an aryl halide, such as lauryl chloride, benzyl chloride, benzyl bromide, methyl bromide, or octyl bromide. Examples of this compound include N-laurylpyridinium chloride and N-benzylpyridinium bromide.

The compound of Formula (D-5) is a quaternary ammonium salt derived from a substituted pyridine, such as picoline. In Formula (D-5), R²⁹ is a C₁₋₁₈ (preferably C₄₋₁₈) alkyl group, or a C₆₋₁₈ aryl group. Examples thereof include methyl group, octyl group, lauryl group, and benzyl group. R³⁰ is a C₁₋₁₈ alkyl group or a C₆₋₁₈ aryl group, and, for example, R³⁰ is a methyl group when the compound is a quaternary ammonium salt derived from picoline. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). Although this compound is commercially available, the compound may be produced through, for example, reaction between a substituted pyridine (e.g., picoline) and an alkyl halide or an aryl halide, such as methyl bromide, octyl bromide, lauryl chloride, benzyl chloride, or benzyl bromide. Examples of this compound include N-benzylpicolinium chloride, N-benzylpicolinium bromide, and N-laurylpicolinium chloride.

The compound of Formula (D-6) is a tertiary ammonium salt derived from an amine. In Formula (D-6), m^{a} is an integer of 2 to 11, and n^{a} is an integer of 2 or 3. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). The compound may be produced through, for example, reaction between an amine and a weak acid, such as a carboxylic acid or phenol. Examples of the carboxylic acid include formic acid and acetic acid. When formic acid is used, the anion (Y⁻) is (HCOO⁻). When acetic acid is used, the anion (Y⁻) is (CH₃COO⁻). When phenol is used, the anion (Y⁻) is (C₆H₅O⁻).

The compound of Formula (D-7) is a quaternary phosphonium salt having a structure of R³¹R³²R³³R³⁴P⁺Y⁻. R³¹, R³², R³³, and R³⁴ are each a C₁₋₁₈ alkyl group or a C₆₋₁₈ aryl group. Three of the four substituents R³¹ to R³⁴ are preferably a phenyl group or a substituted phenyl group, such as a phenyl group or a tolyl group. The remaining one substituent is a C₁₋₁₈ alkyl group or a C₆₋₁₈ aryl group. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). This compound is commercially available, and examples of the compound include tetraalkylphosphonium halides, such as tetra-n-butylphosphonium halides and tetra-n-propylphosphonium halides; trialkylbenzylphosphonium halides, such as triethylbenzylphosphonium halides; triphenylmonoalkylphosphonium halides, such as triphenylmethylphosphonium halides and triphenylethylphosphonium halides; triphenylbenzylphosphonium halides; tetraphenylphosphonium halides; tritolylmonoarylphosphonium halides; or tritolylmonoalkylphosphonium halides (wherein the halogen atom is a chlorine atom or a bromine atom). Particularly preferred are triphenylmonoalkylphosphonium halides, such as triphenylmethylphosphonium halides and triphenylethylphosphonium halides; triphenylmonoarylphosphonium halides, such as triphenylbenzylphosphonium halides; tritolylmonoarylphosphonium halides, such as tritolylmonophenylphosphonium halides; and tritolylmonoalkylphosphonium halides, such as tritolylmonomethylphosphonium halides (wherein the halogen atom is a chlorine atom or a bromine atom).

Examples of the phosphine compound include primary phosphines, such as methylphosphine, ethylphosphine, propylphosphine, isopropylphosphine, isobutylphosphine, and phenylphosphine; secondary phosphines, such as dimethylphosphine, diethylphosphine, diisopropylphosphine, diisoamylphosphine, and diphenylphosphine; and tertiary phosphines, such as trimethylphosphine, triethylphosphine, triphenylphosphine, methyldiphenylphosphine, and dimethylphenylphosphine.

The compound of Formula (D-8) is a tertiary sulfonium salt having a structure of R³⁵R³⁶R³⁷S⁺Y⁻. R³⁵, R³⁶, and R³⁷ are each a C₁₋₁₈ alkyl group or a C₆₋₁₈ aryl group. Two of the three substituents R³⁵ to R³⁷ are preferably a phenyl group or a substituted phenyl group, such as a phenyl group or a tolyl group. The remaining one substituent is a C₁₋₁₈ alkyl group or a C₆₋₁₈ aryl group. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), alcoholate (—O⁻), maleate anion, and nitrate anion. This compound is commercially available, and examples of the compound include trialkylsulfonium halides, such as tri-n-butylsulfonium halides and tri-n-propylsulfonium halides; dialkylbenzylsulfonium halides, such as diethylbenzylsulfonium halides; diphenylmonoalkylsulfonium halides, such as diphenylmethylsulfonium halides and diphenylethylsulfonium halides; triphenylsulfonium halides (wherein the halogen atom is a chlorine atom or a bromine atom); trialkylsulfonium carboxylates, such as tri-n-butylsulfonium carboxylate and tri-n-propylsulfonium carboxylate; dialkylbenzylsulfonium carboxylates, such as diethylbenzylsulfonium carboxylate; diphenylmonoalkylsulfonium carboxylates, such as diphenylmethylsulfonium carboxylate and diphenylethylsulfonium carboxylate; and triphenylsulfonium carboxylate. Triphenylsulfonium halides and triphenylsulfonium carboxylate are preferably used.

In the present invention, a nitrogen-containing silane compound may be added as a curing catalyst. Examples of the nitrogen-containing silane compound include silane compounds containing an imidazole ring, such as N-(3-triethoxysilylpropyl)-4,5-dihydroimidazole.

When a curing catalyst is used, the amount of the curing catalyst is 0.01 parts by mass to 10 parts by mass, or 0.01 parts by mass to 5 parts by mass, or 0.01 parts by mass to 3 parts by mass relative to 100 parts by mass of the polysiloxane [A].

### <Stabilizer>

The stabilizer may be incorporated for the purpose of, for example, stabilization of the aforementioned hydrolysis condensate of the hydrolyzable silane mixture. Specific examples of the stabilizer that may be incorporated include an organic acid, water, an alcohol, or any combination of these.

Examples of the organic acid include oxalic acid, malonic acid, methylmalonic acid, succinic acid, maleic acid, malic acid, tartaric acid, phthalic acid, citric acid, glutaric acid, lactic acid, and salicylic acid. Of these, oxalic acid or maleic acid is preferred. When an organic acid is incorporated, the amount thereof is 0.1 to 5.0% by mass relative to the mass of the aforementioned hydrolysis condensate of the hydrolyzable silane mixture. Such an organic acid may also serve as a pH adjuster.

The water may be, for example, pure water, ultrapure water, or ion-exchange water. When water is used, the amount thereof may be 1 part by mass to 20 parts by mass relative to 100 parts by mass of the resist underlayer film-forming composition.

The alcohol is preferably an alcohol that easily evaporates (volatilizes) by heating after application of the composition. Examples of the alcohol include methanol, ethanol, propanol, i-propanol, and butanol. When an alcohol is incorporated, the amount thereof may be 1 part by mass to 20 parts by mass relative to 100 parts by mass of the resist underlayer film-forming composition.

### <Organic Polymer>

Incorporation of the aforementioned organic polymer compound into the resist underlayer film-forming composition enables adjustment of, for example, the dry etching rate (the amount of reduction in film thickness per unit time), attenuation coefficient, or refractive index of a film (resist underlayer film) formed from the composition. No particular limitation is imposed on the organic polymer compound, and it is appropriately selected from among various organic polymers (polycondensation polymer and addition polymerization polymer) depending on the purpose of addition thereof.

Specific examples of the organic polymer compound include addition polymerization polymers and polycondensation polymers, such as polyester, polystyrene, polyimide, acrylic polymer, methacrylic polymer, polyvinyl ether, phenol novolac, naphthol novolac, polyether, polyamide, and polycarbonate.

In the present invention, an organic polymer having an aromatic or heteroaromatic ring that functions as a light-absorbing moiety (e.g., a benzene ring, a naphthalene ring, an anthracene ring, a triazine ring, a quinoline ring, or a quinoxaline ring) can also be suitably used in the case where such a function is required. Specific examples of such an organic polymer compound include, but are not limited to, addition polymerization polymers containing, as structural units, addition polymerizable monomers (e.g., benzyl acrylate, benzyl methacrylate, phenyl acrylate, naphthyl acrylate, anthryl methacrylate, anthrylmethyl methacrylate, styrene, hydroxystyrene, benzyl vinyl ether, and N-phenylmaleimide); and polycondensation polymers such as phenol novolac and naphthol novolac.

When an addition polymerization polymer is used as an organic polymer compound, the polymer compound may be a homopolymer or a copolymer.

An addition polymerizable monomer is used for the production of the addition polymerization polymer. Specific examples of the addition polymerizable monomer include, but are not limited to, acrylic acid, methacrylic acid, an acrylate ester compound, a methacrylate ester compound, an acrylamide compound, a methacrylamide compound, a vinyl compound, a styrene compound, a maleimide compound, maleic anhydride, and acrylonitrile.

Specific examples of the acrylate ester compound include, but are not limited to, methyl acrylate, ethyl acrylate, normal hexyl acrylate, i-propyl acrylate, cyclohexyl acrylate, benzyl acrylate, phenyl acrylate, anthrylmethyl acrylate, 2-hydroxyethyl acrylate, 3-chloro-2-hydroxypropyl acrylate, 2-hydroxypropyl acrylate, 2,2,2-trifluoroethyl acrylate, 2,2,2-trichloroethyl acrylate, 2-bromoethyl acrylate, 4-hydroxybutyl acrylate, 2-methoxyethyl acrylate, tetrahydrofurfuryl acrylate, 2-methyl-2-adamantyl acrylate, 5-acryloyloxy-6-hydroxynorbornene-2-carboxylic-6-lactone, 3-acryloxypropyltriethoxysilane, and glycidyl acrylate.

Specific examples of the methacrylate ester compound include, but are not limited to, methyl methacrylate, ethyl methacrylate, normal hexyl methacrylate, i-propyl methacrylate, cyclohexyl methacrylate, benzyl methacrylate, phenyl methacrylate, anthrylmethyl methacrylate, 2-hydroxyethyl methacrylate, 2-hydroxypropyl methacrylate, 2,2,2-trifluoroethyl methacrylate, 2,2,2-trichloroethyl methacrylate, 2-bromoethyl methacrylate, 4-hydroxybutyl methacrylate, 2-methoxyethyl methacrylate, tetrahydrofurfuryl methacrylate, 2-methyl-2-adamantyl methacrylate, 5-methacryloyloxy-6-hydroxynorbornene-2-carboxylic-6-lactone, 3-methacryloxypropyltriethoxysilane, glycidyl methacrylate, 2-phenylethyl methacrylate, hydroxyphenyl methacrylate, and bromophenyl methacrylate.

Specific examples of the acrylamide compound include, but are not limited to, acrylamide, N-methylacrylamide, N-ethylacrylamide, N-benzylacrylamide, N-phenylacrylamide, N,N-dimethylacrylamide, and N-anthrylacrylamide.

Specific examples of the methacrylamide compound include, but are not limited to, methacrylamide, N-methylmethacrylamide, N-ethylmethacrylamide, N-benzylmethacrylamide, N-phenylmethacrylamide, N,N-dimethylmethacrylamide, and N-anthrylmethacrylamide.

Specific examples of the vinyl compound include, but are not limited to, vinyl alcohol, 2-hydroxyethyl vinyl ether, methyl vinyl ether, ethyl vinyl ether, benzyl vinyl ether, vinyl acetate, vinyltrimethoxysilane, 2-chloroethyl vinyl ether, 2-methoxyethyl vinyl ether, vinylnaphthalene, and vinylanthracene.

Specific examples of the styrene compound include, but are not limited to, styrene, hydroxystyrene, chlorostyrene, bromostyrene, methoxystyrene, cyanostyrene, and acetylstyrene.

Examples of the maleimide compound include, but are not limited to, maleimide, N-methylmaleimide, N-phenylmaleimide, N-cyclohexylmaleimide, N-benzylmaleimide, and N-hydroxyethylmaleimide.

When a polycondensation polymer is used as the polymer, the polymer is, for example, a polycondensation polymer composed of a glycol compound and a dicarboxylic acid compound. Examples of the glycol compound include diethylene glycol, hexamethylene glycol, and butylene glycol. Examples of the dicarboxylic acid compound include succinic acid, adipic acid, terephthalic acid, and maleic anhydride. Examples of the polymer include, but are not limited to, polyesters, polyamides, and polyimides, such as polypyromellitimide, poly(p-phenyleneterephthalamide), polybutylene terephthalate, and polyethylene terephthalate.

When the organic polymer compound contains a hydroxy group, the hydroxy group may be crosslinked with, for example, a hydrolysis condensate.

The organic polymer compound generally has a weight average molecular weight of 1,000 to 1,000,000. In the case of incorporation of the organic polymer compound, from the viewpoints of sufficiently achieving the functional effect of the polymer and preventing the precipitation of the polymer in the composition, the weight average molecular weight may be, for example, 3,000 to 300,000, or 5,000 to 300,000, or 10,000 to 200,000.

These organic polymer compounds may be used alone or in combination of two or more species.

When the silicon-containing resist underlayer film-forming composition of the present invention contains an organic polymer compound, the amount of the organic polymer compound cannot be univocally determined, since the amount should be appropriately determined in consideration of, for example, the function of the organic polymer compound. The amount of the organic polymer compound is generally 1 to 200% by mass relative to the mass of the aforementioned polysiloxane [A]. From the viewpoint of, for example, preventing the precipitation of the polymer compound in the composition, the amount is, for example, 100% by mass or less, preferably 50% by mass or less, more preferably 30% by mass or less. From the viewpoint of, for example, sufficiently achieving the effect of the polymer compound, the amount is, for example, 5% by mass or more, preferably 10% by mass or more, more preferably 30% by mass or more.

### <Acid Generator>

Examples of the acid generator include a thermal acid generator and a photoacid generator, and a photoacid generator is preferably used.

Examples of the photoacid generator include, but are not limited to, an onium salt compound, a sulfonimide compound, and a disulfonyldiazomethane compound. The photoacid generator may also serve as a curing catalyst depending on the type thereof, for example, a nitrate salt, a carboxylate salt (e.g., maleate), or a hydrochloride salt of an onium salt compound described below.

Examples of the thermal acid generator include, but are not limited to, tetramethylammonium nitrate.

Specific examples of the onium salt compound include, but are not limited to, iodonium salt compounds, such as diphenyliodonium hexafluorophosphate, diphenyliodonium trifluoromethanesulfonate, diphenyliodonium nonafluoro normal butanesulfonate, diphenyliodonium perfluoro normal octanesulfonate, diphenyliodonium camphorsulfonate, bis(4-t-butylphenyl) iodonium camphorsulfonate, and bis(4-t-butylphenyl) iodonium trifluoromethanesulfonate; and sulfonium salt compounds, such as triphenylsulfonium hexafluoroantimonate, triphenylsulfonium nonafluoro normal butanesulfonate, triphenylsulfonium camphorsulfonate, triphenylsulfonium trifluoromethanesulfonate, triphenylsulfonium nitrate, triphenylsulfonium trifluoroacetate, triphenylsulfonium maleate, and triphenylsulfonium chloride.

Specific examples of the sulfonimide compound include, but are not limited to, N-(trifluoromethanesulfonyloxy) succinimide, N-(nonafluoro normal butane sulfonyloxy) succinimide, N-(camphorsulfonyloxy) succinimide, and N-(trifluoromethanesulfonyloxy) naphthalimide.

Specific examples of the disulfonyldiazomethane compound include, but are not limited to, bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

When the silicon-containing resist underlayer film-forming composition of the present invention contains an acid generator, the amount of the acid generator cannot be univocally determined, since the amount should be appropriately determined in consideration of, for example, the type of the acid generator. The amount of the acid generator is generally 0.01 to 5% by mass relative to the mass of the polysiloxane [A].

From the viewpoint of, for example, preventing the precipitation of the acid generator in the composition, the amount is preferably 3% by mass or less, more preferably 1% by mass or less. From the viewpoint of, for example, sufficiently achieving the effect of the acid generator, the amount is preferably 0.1% by mass or more, more preferably 0.5% by mass or more.

These acid generators may be used alone or in combination of two or more species. A photoacid generator and a thermal acid generator may be used in combination.

### <Surfactant>

When the resist underlayer film-forming composition is applied onto a substrate, a surfactant effectively prevents formation of, for example, pinholes and striations. Examples of the surfactant include a nonionic surfactant, an anionic surfactant, a cationic surfactant, a silicon-containing surfactant, a fluorine-containing surfactant, and a UV-curable surfactant. Specific examples of the surfactant include, but are not limited to, nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkylaryl ethers, such as polyoxyethylene octylphenol ether and polyoxyethylene nonylphenol ether, polyoxyethylene-polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-containing surfactants, such as trade names EFTOP (registered trademark) EF301, EF303, and EF352 (available from Mitsubishi Materials Electronic Chemicals Co., Ltd. (former Tohkem Products Corporation)), trade names MEGAFAC (registered trademark) F171, F173, R-08, R-30, R-30N, and R-40 LM (available from DIC Corporation), Fluorad FC430 and FC431 (available from 3M Japan Limited), trade name Asahi Guard (registered trademark) AG710 (available from AGC Inc.), and trade names SURFLON (registered trademark) S-382, SC101, SC102, SC103, SC104, SC105, and SC106 (available from AGC Seimi Chemical Co., Ltd.); and Organosiloxane Polymer KP341 (available from Shin-Etsu Chemical Co., Ltd.).

These surfactants may be used alone or in combination of two or more species.

When the silicon-containing resist underlayer film-forming composition of the present invention contains a surfactant, the amount of the surfactant is generally 0.0001 to 5% by mass, preferably 0.001 to 4% by mass, more preferably 0.01 to 3% by mass, relative to the mass of the polysiloxane [A].

### <Rheology Controlling Agent>

The rheology controlling agent is added for the purpose of mainly improving the fluidity of the resist underlayer film-forming composition, in particular, improving the uniformity of the thickness of a film to be formed or improving the fillability of the composition into holes on a baking step. Specific examples of the rheology controlling agent include phthalic acid derivatives, such as dimethyl phthalate, diethyl phthalate, di-i-butyl phthalate, dihexyl phthalate, and butyl i-decyl phthalate; adipic acid derivatives, such as di-normal butyl adipate, di-i-butyl adipate, di-i-octyl adipate, and octyl decyl adipate; maleic acid derivatives, such as di-normal butyl maleate, diethyl maleate, and dinonyl maleate; oleic acid derivatives, such as methyl oleate, butyl oleate, and tetrahydrofurfuryl oleate; and stearic acid derivatives, such as normal butyl stearate and glyceryl stearate.

When such a rheology controlling agent is used, the amount of the rheology controlling agent added is generally less than 30% by mass relative to the total solid content of the composition.

### <Adhesion Aid>

The adhesion aid is added for the purpose of mainly improving the adhesion between a substrate or a resist and a film (resist underlayer film) formed from the silicon-containing resist underlayer film-forming composition, in particular, suppressing or preventing the peeling of the resist during development. Specific examples of the adhesion aid include chlorosilanes, such as trimethylchlorosilane, dimethylvinylchlorosilane, methyldiphenylchlorosilane, and chloromethyldimethylchlorosilane; alkoxysilanes, such as trimethylmethoxysilane, dimethyldiethoxysilane, methyldimethoxysilane, and dimethylvinylethoxysilane; silazanes, such as hexamethyldisilazane, N,N′-bis(trimethylsilyl) urea, dimethyltrimethylsilylamine, and trimethylsilylimidazole; additional silanes, such as γ-chloropropyltrimethoxysilane, γ-aminopropyltriethoxysilane, and y-glycidoxypropyltrimethoxysilane; heterocyclic compounds, such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine; and urea or thiourea compounds, such as 1,1-dimethylurea and 1,3-dimethylurea.

When such an adhesion aid is used, the amount of the adhesion aid added is generally less than 5% by mass, preferably less than 2% by mass, relative to the total solid content of the composition.

### <pH Adjuster>

The pH adjuster to be added may be, for example, an acid having one or two or more carboxylate groups, such as an organic acid described above in <Stabilizer>, or a bisphenol sulfone compound such as bisphenol S or a bisphenol S derivative. When a pH adjuster is used, the amount of the pH adjuster added may be 0.01 to 20 parts by mass, or 0.01 to 10 parts by mass, or 0.01 to 5 parts by mass, relative to 100 parts by mass of the polysiloxane [A].

Specific examples of bisphenol S and bisphenol S derivatives include, but are not limited to, those described below.

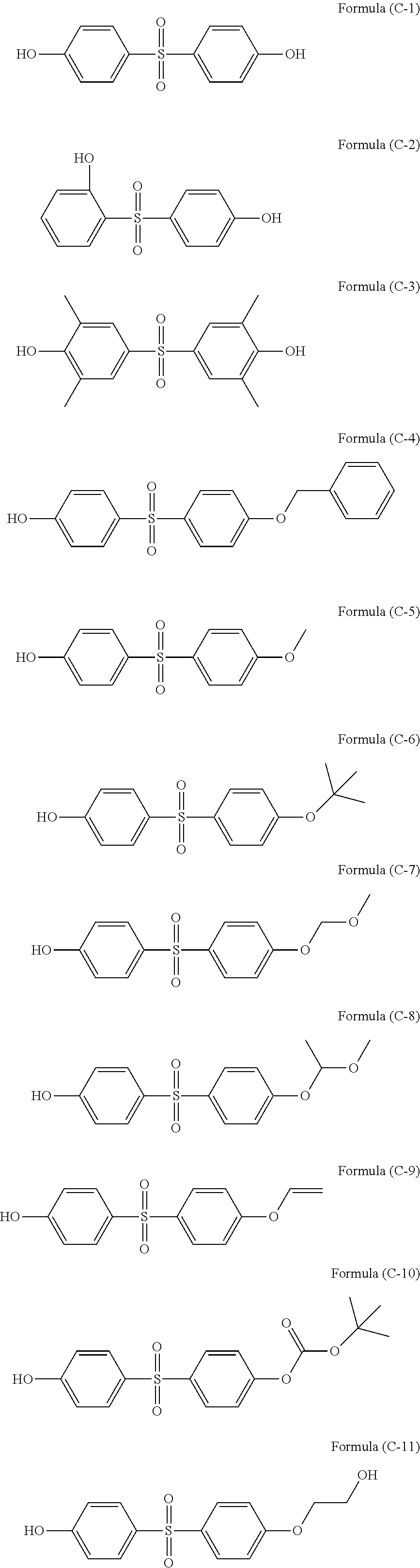

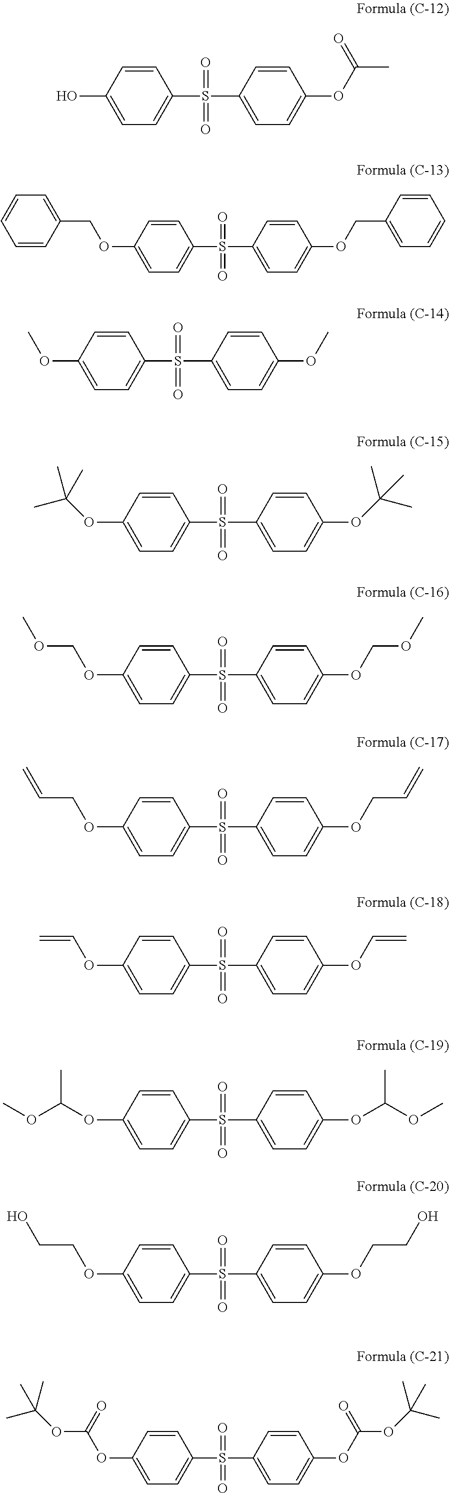

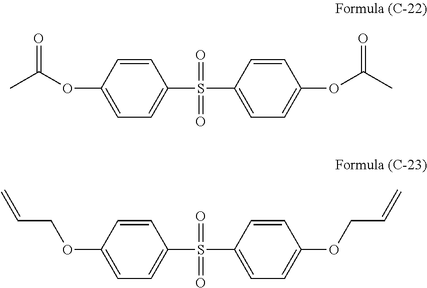

### <Metal Oxide>

Examples of the metal oxide that may be added to the silicon-containing resist underlayer film-forming composition of the present invention include, but are not limited to, oxides of a combination of one or more selected from among metals, such as tin (Sn), titanium (Ti), aluminum (Al), zirconium (Zr), zinc (Zn), niobium (Nb), tantalum (Ta), and W (tungsten), and semimetals, such as boron (B), silicon (Si), germanium (Ge), arsenic (As), antimony (Sb), and tellurium (Te).

### [Pattern Formation Method and Semiconductor Device Production Method]

Next will be described, as one embodiment of the present invention, a pattern formation method using the silicon-containing resist underlayer film-forming composition of the present invention, and a semiconductor device production method.

Firstly, the silicon-containing resist underlayer film-forming composition of the present invention is applied onto a substrate used for the production of a precise integrated circuit device [e.g., a semiconductor substrate such as a silicon wafer coated with a silicon oxide film, a silicon nitride film, or a silicon oxynitride film, a silicon nitride substrate, a quartz substrate, a glass substrate (including alkali-free glass, low alkali glass, or crystallized glass), a glass substrate coated with an ITO (indium tin oxide) film or an IZO (indium zinc oxide) film, a plastic (e.g., polyimide or PET) substrate, a substrate coated with a low dielectric constant material (low-k material), or a flexible substrate] by an appropriate application method with, for example, a spinner or a coater. Thereafter, the composition is cured through baking by heating means (e.g., a hot plate), to thereby form a resist underlayer film. Hereinafter, unless otherwise specified, the term “resist underlayer film (silicon-containing resist underlayer film)” refers to a film formed from the silicon-containing resist underlayer film-forming composition of the present invention.

The baking is performed under appropriately determined conditions; i.e., a baking temperature of 40° C. to 400° C. or 80° C. to 250° C. and a baking time of 0.3 minutes to 60 minutes. Preferably, the baking temperature is 150° C. to 250° C., and the baking time is 0.5 minutes to 2 minutes.

The thus-formed resist underlayer film has a thickness of, for example, 10 nm to 1,000 nm, or 20 nm to 500 nm, or 50 nm to 300 nm, or 100 nm to 200 nm, or 10 to 150 nm.

The resist underlayer film-forming composition used for formation of the aforementioned resist underlayer film may be the resist underlayer film-forming composition subjected to filtration with a nylon filter. The expression “resist underlayer film-forming composition subjected to filtration with a nylon filter” as used herein refers to a composition which has been subjected to filtration with a nylon filter during production of the resist underlayer film-forming composition or after mixing of all the components.

In this embodiment of the present invention, an organic underlayer film is formed on the aforementioned substrate, and then the resist underlayer film is formed on the organic underlayer film. However, in some embodiments, an organic underlayer film may be omitted.

No particular limitation is imposed on the organic underlayer film used herein, and the organic underlayer film may be arbitrarily selected from among those conventionally used in a lithographic process.

In the present embodiment, the organic underlayer film is formed on the substrate, and the resist underlayer film is formed on the organic underlayer film, followed by formation of a resist film on the resist underlayer film as described below. This constitution can narrow the pattern width of a photoresist film. Thus, even when the photoresist film is formed thinly for preventing pattern collapse, the substrate can be processed through selection of an appropriate etching gas described below. For example, the silicon-containing resist underlayer film of the present invention can be processed by using, as an etching gas, a fluorine-containing gas that achieves a significantly high etching rate for the photoresist film. The organic underlayer film can be processed by using, as an etching gas, an oxygen-containing gas that achieves a significantly high etching rate for the silicon-containing resist underlayer film of the present invention. The substrate can be processed by using, as an etching gas, a fluorine-containing gas that achieves a significantly high etching rate for the organic underlayer film.

The substrate and application method usable in this process are the same as those described above.

Subsequently, a layer of, for example, a photoresist material (resist film) is formed on the aforementioned resist underlayer film. The resist film can be formed by a well-known method. Specifically, the resist film can be formed by application of a coating-type resist material (e.g., a photoresist film-forming composition) onto the resist underlayer film, and subsequent baking of the resist material.

The resist film has a thickness of, for example, 10 nm to 10,000 nm, or 100 nm to 2,000 nm, or 200 nm to 1,000 nm, or 30 nm to 200 nm.

No particular limitation is imposed on the photoresist material used for the resist film formed on the resist underlayer film, so long as the material is sensitive to light used for exposure (e.g., KrF excimer laser or ArF excimer laser). The material may be either of negative photoresist and positive photoresist materials. Examples of the material include, but are not limited to, a positive photoresist material formed of a novolac resin and a 1,2-naphthoquinone diazide sulfonic acid ester; a chemically amplified photoresist material formed of a binder having a group that decomposes with an acid to thereby increase an alkali dissolution rate and a photoacid generator; a chemically amplified photoresist material formed of a low-molecular-weight compound that decomposes with an acid to thereby increase the alkali dissolution rate of the photoresist material, an alkali-soluble binder, and a photoacid generator; and a chemically amplified photoresist material formed of a binder having a group that decomposes with an acid to thereby increase an alkali dissolution rate, a low-molecular-weight compound that decomposes with an acid to thereby increase the alkali dissolution rate of the photoresist material, and a photoacid generator.

Specific examples of commercially available products include, but are not limited to, trade name APEX-E (available from Shipley), trade name PAR710 (available from Sumitomo Chemical Company, Limited), trade name AR2772JN (available from JSR Corporation), and trade name SEPR430 (available from Shin-Etsu Chemical Co., Ltd.). Other examples include fluorine atom-containing polymer-based photoresist materials described in, for example, Proc. SPIE, Vol. 3999, 330-334 (2000), Proc. SPIE, Vol. 3999, 357-364 (2000), and Proc. SPIE, Vol. 3999, 365-374 (2000).

The resist film formed on the aforementioned resist underlayer film may be, in place of the photoresist film, a resist film for electron beam lithography (may also be referred to as “electron beam resist film”) or a resist film for EUV lithography (may also be referred to as “EUV resist film”). Thus, the silicon-containing resist underlayer film-forming composition of the present invention can be used for formation of a resist underlayer film for electron beam lithography or a resist underlayer film for EUV lithography. In particular, the composition of the present invention is suitable as a composition for formation of a resist underlayer film for EUV lithography.

The electron beam resist material may be either of negative and positive materials. Specific examples of the resist material include a chemically amplified resist material formed of an acid generator and a binder having a group that decomposes with an acid to thereby change an alkali dissolution rate; a chemically amplified resist material formed of an alkali-soluble binder, an acid generator, and a low-molecular-weight compound that decomposes with an acid to thereby change the alkali dissolution rate of the resist material; a chemically amplified resist material formed of an acid generator, a binder having a group that decomposes with an acid to thereby change an alkali dissolution rate, and a low-molecular-weight compound that decomposes with an acid to thereby change the alkali dissolution rate of the resist material; a non-chemically amplified resist material formed of a binder having a group that decomposes with electron beams to thereby change an alkali dissolution rate; and a non-chemically amplified resist material formed of a binder having a moiety that is cut with electron beams to thereby change an alkali dissolution rate. Also in the case of use of such an electron beam resist material, a resist film pattern can be formed by using electron beams as an irradiation source in the same manner as in the case of using the photoresist material.

The aforementioned EUV resist material may be a methacrylate resin-based resist material or a hydroxystyrene resin-based resist.

Subsequently, light exposure is performed on the resist film formed above the resist underlayer film through a predetermined mask (reticle). The light exposure may involve the use of, for example, a KrF excimer laser (wavelength: 248 nm), an ArF excimer laser (wavelength: 193 nm), an F2 excimer laser (wavelength: 157 nm), EUV (wavelength: 13.5 nm), or electron beams.

After the light exposure, post exposure bake may be performed if necessary. The post exposure bake is performed under appropriately determined conditions; i.e., a heating temperature of 70° C. to 150° C. and a heating time of 0.3 minutes to 10 minutes.

Subsequently, development is performed with a developer (e.g., an alkaline developer). When, for example, a positive photoresist film is used, an exposed portion of the photoresist film is removed to thereby form a pattern of the photoresist film.

Examples of the developer (alkaline developer) include alkaline aqueous solutions (alkaline developers), for example, aqueous solutions of alkali metal hydroxides, such as potassium hydroxide and sodium hydroxide; aqueous solutions of quaternary ammonium hydroxides, such as tetramethylammonium hydroxide, tetraethylammonium hydroxide, and choline; and aqueous solutions of amines, such as ethanolamine, propylamine, and ethylenediamine. Such a developer may further contain a surfactant, etc. The development is performed under appropriately determined conditions; i.e., a temperature of 5 to 50° C. and a time of 10 seconds to 600 seconds.

The present invention may involve the use of an organic solvent as a developer. Thus, development is performed with a developer (solvent) after light exposure. When, for example, a negative photoresist film is used, an unexposed portion of the photoresist film is removed to thereby form a pattern of the photoresist film.

Examples of the developer (organic solvent) include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Such a developer may further contain a surfactant, etc. The development is performed under appropriately determined conditions; i.e., a temperature of 5° C. to 50° C. and a time of 10 seconds to 600 seconds.

The resultant patterned photoresist film (upper layer) is used as a protective film to thereby remove the resist underlayer film (intermediate layer). Subsequently, the patterned resist underlayer film (intermediate layer) is used as a protective film to thereby remove the organic underlayer film (lower layer). Finally, the patterned resist underlayer film (intermediate layer) and the patterned organic underlayer film (lower layer) are used as protective films to thereby process the substrate.

The resist underlayer film (intermediate layer) is removed (patterned) through dry etching by using the patterned resist film (upper layer) as a protective film. The dry etching can be performed with any of gases, such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, and dichloroborane.

The dry etching of the resist underlayer film is preferably performed with a halogen-containing gas. In general, a resist film (photoresist film) formed of an organic substance is hard to remove by dry etching with a halogen-containing gas. In contrast, the silicon-containing resist underlayer film, which contains numerous silicon atoms, is quickly removed by dry etching with a halogen-containing gas. Therefore, a reduction in the thickness of the photoresist film in association with the dry etching of the resist underlayer film can be suppressed. Consequently, the photoresist film can be used in the form of thin film. Thus, the dry etching of the resist underlayer film is preferably performed with a fluorine-containing gas. Examples of the fluorine-containing gas include, but are not limited to, tetrafluoromethane (CF₄), perfluorocyclobutane (C₄F₈), perfluoropropane (C₃F₈), trifluoromethane, and difluoromethane (CH₂F₂).

Subsequently, when the organic underlayer film is present between the substrate and the resist underlayer film, the patterned resist film (upper layer) (if remains) and the patterned resist underlayer film (intermediate layer) are used as protective films to thereby remove (pattern) the organic underlayer film (lower layer). The organic underlayer film (lower layer) is preferably removed (patterned) by dry etching with an oxygen-containing gas (e.g., oxygen gas or oxygen/carbonyl sulfide (COS) mixed gas), since the silicon-containing resist underlayer film of the present invention, which contains numerous silicon atoms, is less likely to be removed by dry etching with an oxygen-containing gas.

Thereafter, the patterned resist underlayer film (intermediate layer) and, if desired, the patterned organic underlayer film (lower layer) are used as protective films to thereby process (pattern) the (semiconductor) substrate. The (semiconductor) substrate is preferably processed (patterned) by dry etching with a fluorine-containing gas.

Examples of the fluorine-containing gas include tetrafluoromethane (CF₄), perfluorocyclobutane (C₄F₈), perfluoropropane (C₃F₈), trifluoromethane, and difluoromethane (CH₂F₂).

The resist underlayer film is removed after removal (patterning) of the organic underlayer film or after processing (patterning) of the substrate. The resist underlayer film may be removed by dry etching or wet etching.

The dry etching of the resist underlayer film is preferably performed with a fluorine-containing gas as described in the aforementioned patterning. Examples of the fluorine-containing gas include, but are not limited to, tetrafluoromethane (CF₄), perfluorocyclobutane (C₄F₈), perfluoropropane (C₃F₈), trifluoromethane, and difluoromethane (CH₂F₂).

Examples of the chemical used for wet etching of the resist underlayer film include dilute hydrofluoric acid (hydrofluoric acid), buffered hydrofluoric acid (mixture of HF and NH₄F), an aqueous solution containing hydrochloric acid and hydrogen peroxide (SC-2 chemical), an aqueous solution containing sulfuric acid and hydrogen peroxide (SPM chemical), an aqueous solution containing hydrofluoric acid and hydrogen peroxide (FPM chemical), and an alkaline solution such as an aqueous solution containing ammonia and hydrogen peroxide (SC-1 chemical). Examples of the above-described alkaline solution include, besides the aforementioned ammonia-hydrogen peroxide mixture (SC-1 chemical) prepared by mixing of ammonia, hydrogen peroxide, and water, an aqueous solution containing 1 to 99% by mass of ammonia, tetramethylammonium hydroxide (TMAH), tetraethylammonium hydroxide, tetrapropylammonium hydroxide, tetrabutylammonium hydroxide, choline hydroxide, benzyltrimethylammonium hydroxide, benzyltriethylammonium hydroxide, DBU (diazabicycloundecene), DBN (diazabicyclononene), hydroxylamine, 1-butyl-1-methylpyrrolidinium hydroxide, 1-propyl-1-methylpyrrolidinium hydroxide, 1-butyl-1-methylpiperidinium hydroxide, 1-propyl-1-methylpiperidinium hydroxide, mepiquat hydroxide, trimethylsulfonium hydroxide, a hydrazine compound, an ethylenediamine compound, or guanidine. These chemicals may be used in combination.

An organic anti-reflective coating may be formed on the resist underlayer film before formation of the resist film. No particular limitation is imposed on the composition used for formation of the anti-reflective coating, and, for example, the composition may be appropriately selected from anti-reflective coating compositions that have been conventionally used in a lithographic process. The anti-reflective coating can be formed by a commonly used method, for example, application of the composition with a spinner or a coater, and subsequent baking of the composition.

The substrate to which the silicon-containing resist underlayer film-forming composition of the present invention is applied may have an organic or inorganic anti-reflective coating formed thereon by, for example, a CVD process. The resist underlayer film may be formed on the anti-reflective coating. Even in the case where the resist underlayer film of the present invention is formed on the organic underlayer film formed on the substrate, the substrate used may have an organic or inorganic anti-reflective coating formed thereon by, for example, a CVD process.

The resist underlayer film formed from the silicon-containing resist underlayer film-forming composition of the present invention may absorb light used in a lithographic process depending on the wavelength of the light. In such a case, the resist underlayer film can function as an anti-reflective coating having the effect of preventing reflection of light from the substrate.

Furthermore, the resist underlayer film can be used as, for example, a layer for preventing the interaction between the substrate and the resist film (e.g., photoresist film); a layer having the function of preventing the adverse effect, on the substrate, of a material used for the resist film or a substance generated during the exposure of the resist film to light; a layer having the function of preventing diffusion of a substance generated from the substrate during heating and baking to the upper resist film; and a barrier layer for reducing a poisoning effect of a dielectric layer of the semiconductor substrate on the resist film.

The resist underlayer film can be applied to a substrate having via holes for use in a dual damascene process, and can be used as an embedding material to fill up the holes. The resist underlayer film can also be used as a planarization material for planarizing the surface of a semiconductor substrate having irregularities.

The resist underlayer film functions as an underlayer film of EUV resist film or a hard mask. In addition, the resist underlayer film can be used as, for example, an anti-reflective underlayer coating of EUV resist film capable of, without intermixing with the EUV resist film, preventing the reflection, from a substrate or an interface, of exposure light undesirable for EUV exposure (wavelength: 13.5 nm), such as UV (ultraviolet) light or DUV (deep ultraviolet) light (ArF light, KrF light). Thus, the resist underlayer film can efficiently prevent the light reflection as the underlayer film of the EUV resist film. When the resist underlayer film is used as an EUV resist underlayer film, the film can be processed in the same manner as in the photoresist underlayer film.

A semiconductor substrate can be suitably processed by using a semiconductor processing substrate including the above-described resist underlayer film of the present invention and a semiconductor substrate.

A semiconductor substrate can be precisely processed at high reproducibility by the above-described semiconductor element production method including a step of forming an organic underlayer film; a step of forming a silicon-containing resist underlayer film on the organic underlayer film from the silicon-containing resist underlayer film-forming composition of the present invention; and a step of forming a resist film on the silicon-containing resist underlayer film. Thus, it is expected that the method can stably produce a semiconductor element.

### EXAMPLES

The present invention will next be described in more detail with reference to Synthesis Examples and Examples, but the present invention should not be construed as being limited only to the following Examples.

The molecular weight of a polysiloxane prepared in each of the following Examples is determined by GPC analysis in terms of polystyrene.

The GPC analysis can be performed under, for example, the following conditions: GPC apparatus (trade name: HLC-8220GPC, available from Tosoh Corporation), GPC columns (trade name: Shodex (registered trademark) KF803L, KF802, and KF801, available from Showa Denko K.K.), column temperature of 40° C., tetrahydrofuran serving as an eluent (elution solvent), flow amount (flow rate) of 1.0 mL/min, and polystyrene (available from Showa Denko K.K.) as a standard sample.

### [1] Synthesis of Polymer (Hydrolysis Condensate)

### Synthesis Example 1

Five Esterified Products Between (2-(7-oxabicyclo[4.1.0]3-heptanyl)ethyl) trimethoxysilane and carboxylic acid compounds shown in Table 1 below (hereinafter the products may be referred to as “ester group-containing silanes 1 to 5”) were used, and polymers (polysiloxanes) of Synthesis Examples 1-1 to 1-5 were synthesized according to the procedure described below.

In a 100-mL flask, 9.37 g of tetraethoxysilane was mixed with 4.68 g of methyltriethoxysilane, each of the esterified products between (2-(7-oxabicyclo[4.1.0]3-heptanyl)ethyl) trimethoxysilane and carboxylic acid compounds (ester group-containing silanes 1 to 5, the amount used is shown in Table 1), and 23.07 g of propylene glycol monoethyl ether. While the resultant mixture was stirred with a magnetic stirrer, a mixture of 0.14 g of 3-N,N-dimethylaminopropyltrimethoxysilane and 8.31 g of 0.2 M aqueous nitric acid solution was added dropwise to the mixture.

After completion of the dropwise addition, the flask was transferred to an oil bath set at 60° C., and the mixture was refluxed for 1,200 minutes. Thereafter, methanol, ethanol, and water (i.e., reaction by-products) were distilled off under reduced pressure for concentration, to thereby produce an aqueous hydrolysis condensate (polymer) solution.

Further, propylene glycol monoethyl ether was added to the solution so as to achieve a solvent proportion of propylene glycol monoethyl ether of 100% and a concentration of 13% by mass in terms of solid residue content at 150° C.

The resultant polymer was found to contain a polysiloxane containing a structure of the following Formula (11). The group R in Formula (11) corresponds to a group derived from a carboxylic acid compound forming the ester structure in ester group-containing silanes 1 to 5.

The weight average molecular weight of the resultant polymer (as determined by GPC analysis in terms of polystyrene) is also shown in Table 1.

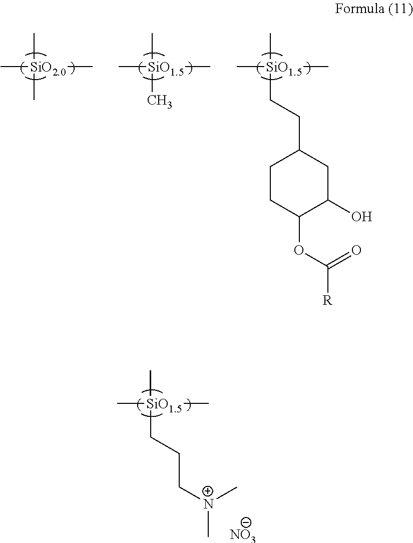

TABLE 1

| | Ester group-containing silane | | | Polymer |
|---|---|---|---|---|
| Polymer | No. | Carboxylic acid compound | Amount used* | Mw |
| Synthesis | Ester group- | Norbornenecarboxylic acid | 5 mol % | 1,890 |
| Example 1-1 | containing silane 1 | | | |
| Synthesis | Ester group- | Phthalic acid | 5 mol % | 1,720 |
| Example 1-2 | containing silane 2 | | | |
| Synthesis | Ester group- | Benzoic acid | 5 mol % | 1,664 |
| Example 1-3 | containing silane 3 | | | |
| Synthesis | Ester group- | Norbornenecarboxylic acid analog | 5 mol % | 1,753 |
| Example 1-4 | containing silane 4 | 1 (3a,4,7,7a-tetrahydro-4,7- | | |
| | | ethanoisobenzofuran-1,3-dione) | | |
| Synthesis | Ester group- | Norbornenecarboxylic acid analog | 5 mol % | 1,822 |
| Example 1-5 | containing silane 5 | 2 (3a,4,7,7a-tetrahydro-4,7- | | |
| | | epoxyisobenzofuran-1,3-dione) | | |

*Amount used: corresponding to the amount (mol %) of an ester group-containing silane used, relative to the total amount (100 mol %) of all silane compounds used for the preparation of a hydrolysis condensate (polymer).

### Comparative Synthesis Example 1

The same procedure as in Synthesis Example 1-1 was performed, except that 0.924 g of 2-(7-oxabicyclo[4.1.0]3-heptanyl)ethyl) trimethoxysilane and 0.518 g of norbornenecarboxylic acid were added in place of the aforementioned ester group-containing silane 1, to thereby produce a polymer (polysiloxane) of Comparative Synthesis Example 1 (Mw: 1,638).

### Synthesis Example 2

Five esterified products between trimethoxy (3-(2-oxiranylmethoxy) propyl) silane and carboxylic acid compounds shown in Table 2 below (hereinafter the products may be referred to as “ester group-containing silanes 6 to 10”) were used, and polymers (polysiloxanes) of Synthesis Examples 2-1 to 2-5 were synthesized.

In a 100-mL flask, 9.37 g of tetraethoxysilane was mixed with 4.68 g of methyltriethoxysilane, each of the esterified products between trimethoxy (3-(2-oxiranylmethoxy) propyl) silane and carboxylic acid compounds (ester group-containing silanes 6 to 10, the amount used is shown in Table 2), and 23.07 g of propylene glycol monoethyl ether. While the resultant mixture was stirred with a magnetic stirrer, 9.46 g of 0.2 M aqueous nitric acid solution was added dropwise to the mixture.

After completion of the dropwise addition, the flask was transferred to an oil bath set at 60° C., and the mixture was refluxed for 1,200 minutes. Thereafter, methanol, ethanol, and water (i.e., reaction by-products) were distilled off under reduced pressure for concentration, to thereby produce an aqueous hydrolysis condensate (polymer) solution.

Further, propylene glycol monoethyl ether was added to the solution so as to achieve a solvent proportion of propylene glycol monoethyl ether of 100% and a concentration of 13% by mass in terms of solid residue content at 150° C.

The resultant polymer was found to contain a polysiloxane containing a structure of the following Formula (12). The group R in Formula (12) corresponds to a group derived from a carboxylic acid compound forming the ester structure in ester group-containing silanes 6 to 10.

The weight average molecular weight of the resultant polymer (as determined by GPC analysis in terms of polystyrene) is also shown in Table 2.

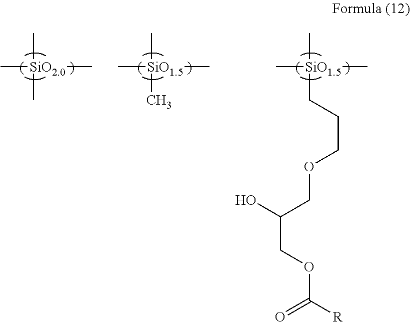

TABLE 2

| | Ester group-containing silane | | | |
|---|---|---|---|---|
| | | Carboxylic acid | Amount | Polymer |
| Polymer | No. | compound | used* | Mw |
| Synthesis | Ester group- | Norbornenecarboxylic | 5 mol % | 3,861 |
| Example 2-1 | containing silane 6 | acid | | |
| Synthesis | Ester group- | 4-Pentynoic acid | 5 mol % | 4,123 |
| Example 2-2 | containing silane 7 | | | |
| Synthesis | Ester group- | 5-Heptenoic acid | 5 mol % | 4,018 |
| Example 2-3 | containing silane 8 | | | |
| Synthesis | Ester group- | Norbornenedicarboxylic | 5 mol % | 4,250 |
| Example 2-4 | containing silane 9 | acid | | |
| Synthesis | Ester group- | Norbornenedicarboxylic | 5 mol % | 3,762 |
| Example 2-5 | containing silane 10 | anhydride | | |

*Amount used: corresponding to the amount (mol %) of an ester group-containing silane used, relative to the total amount (100 mol %) of all silane compounds used for the preparation of a hydrolysis condensate (polymer).

### Comparative Synthesis Example 2

The same procedure as in Synthesis Example 2-1 was performed, except that 0.887 g of (trimethoxy (3-(2-oxiranylmethoxy) propyl) silane and 0.518 g of norbornenecarboxylic acid were added in place of the aforementioned ester group-containing silane 6, to thereby produce a polymer (polysiloxane) of Comparative Synthesis Example 2 (Mw: 3,113).

[2] Preparation of Resist Underlayer Film-Forming Composition Each of the polysiloxanes (polymers) produced in the aforementioned Synthesis Examples, an additive, a curing catalyst, and a solvent were mixed in proportions shown in Table 3, and the resultant mixture was filtered with a fluororesin-made filter (0.1 μm), to thereby prepare a resist underlayer film-forming composition (Examples 1 to 10 and Comparative Examples 1 and 2). In Table 3, the amount of each component added is shown by part(s) by mass.

Although the composition was prepared from the solution containing the hydrolysis condensate (polymer) produced in each Synthesis Example, the amount of each polymer shown in Table 3 corresponds not to the amount of the polymer solution, but to the amount of the polymer itself.

In Table 3, DIW denotes ultrapure water; PGME, propylene glycol monomethyl ether; and PGEE, propylene glycol monoethyl ether.

Furthermore, MA denotes maleic acid; and TPSNO3, triphenylsulfonium nitrate.

TABLE 3

| | Polymer | Additive | Curing agent | Solvent | | |
|---|---|---|---|---|---|---|
| Example 1 | Synthesis Example 1-1 | MA | — | PGME | PEGG | DIW |
| (part(s) by mass) | 1 | 0.02 | — | 8 | 80 | 12 |
| Example 2 | Synthesis Example 1-2 | MA | — | PGME | PEGG | DIW |
| (part(s) by mass) | 1 | 0.02 | — | 8 | 80 | 12 |
| Example 3 | Synthesis Example 1-3 | MA | — | PGME | PEGG | DIW |
| (part(s) by mass) | 1 | 0.02 | — | 8 | 80 | 12 |
| Example 4 | Synthesis Example 1-4 | MA | — | PGME | PEGG | DIW |
| (part(s) by mass) | 1 | 0.02 | — | 8 | 80 | 12 |
| Example 5 | Synthesis Example 1-5 | MA | — | PGME | PEGG | DIW |
| (part(s) by mass) | 1 | 0.02 | — | 8 | 80 | 12 |
| Example 6 | Synthesis Example 2-1 | MA | TPSNO3 | PGME | PEGG | DIW |
| (part(s) by mass) | 1 | 0.02 | 0.01 | 8 | 80 | 12 |
| Example 7 | Synthesis Example 2-2 | MA | TPSNO3 | PGME | PEGG | DIW |
| (part(s) by mass) | 1 | 0.02 | 0.01 | 8 | 80 | 12 |
| Example 8 | Synthesis Example 2-3 | MA | TPSNO3 | PGME | PEGG | DIW |
| (part(s) by mass) | 1 | 0.02 | 0.01 | 8 | 80 | 12 |
| Example 9 | Synthesis Example 2-4 | MA | TPSNO3 | PGME | PEGG | DIW |
| (part(s) by mass) | 1 | 0.02 | 0.01 | 8 | 80 | 12 |
| Example 10 | Synthesis Example 2-5 | MA | TPSNO3 | PGME | PEGG | DIW |
| (part(s) by mass) | 1 | 0.02 | 0.01 | 8 | 80 | 12 |
| Comparative | Comparative Synthesis | MA | — | PGME | PEGG | DIW |
| Example 1 | Example 1 | | | | | |
| (part(s) by mass) | 1 | 0.02 | — | 8 | 80 | 12 |
| Comparative | Comparative Synthesis | MA | TPSNO3 | PGME | PEGG | DIW |
| Example 2 | Example 2 | | | | | |
| (part(s) by mass) | 1 | 0.02 | 0.01 | 8 | 80 | 12 |

[3] Preparation of Organic Resist Underlayer Film-Forming Composition. In a nitrogen atmosphere, a 300-mL four-necked flask was charged with 40.0 g of 1,2-epoxy-4-(2-oxiranyl) cyclohexane adduct of 2,2-bis(hydroxymethyl)-1-butanol (trade name: EHPE3150, available from Daicel Corporation), 20.3 g of 9-anthracenecarboxylic acid, 13.7 g of benzoic acid (extra pure, available from KANTO CHEMICAL CO., INC.), 1.5 g of benzyltriethylammonium (BTEAC, available from Tokyo Chemical Industry Co., Ltd.), and 117.0 g of propylene glycol monomethyl ether (PGME) serving as a solvent, and these materials were mixed in the flask. The resultant mixture was refluxed at 142° C. for 20 hours, to thereby allow reaction to proceed. After completion of the reaction, the resultant mixture was purified with an ion-exchange resin, to thereby produce a yellow solution containing a polymer. The resultant polymer was found to have a weight average molecular weight of 4,100 as determined by GPC analysis in terms of standard polystyrene.

5 g of the above-produced polymer solution (polymer solid content: 16% by mass) was mixed with 0.2 g of tetraethoxymethyl glycoluril serving as a crosslinking agent, 0.03 g of pyridinium p-toluenesulfonate serving as a catalyst, 0.0008 g of MEGAFAC (registered trademark) R-30 (trade name, available from DIC Corporation) serving as a fluorine-containing surfactant, 6.4 g of propylene glycol monomethyl ether, and 4.5 g of propylene glycol monomethyl ether acetate, to thereby prepare a solution. Thereafter, the solution was filtered with a polyethylene-made microfilter (pore size: 0.10 μm), and then filtered with a polyethylene-made microfilter (pore size: 0.05 μm), to thereby prepare an organic resist underlayer film-forming composition used for a lithographic process using a multilayer film.

[4] Formation of Resist Pattern by Electron Beam (EB) Exposure:

### Positive Solvent Development

The aforementioned organic resist underlayer film-forming composition was applied onto a silicon wafer with a spinner, and then baked on a hot plate at 215° C. for 60 seconds, to thereby form an organic underlayer film (layer A) having a thickness of 200 nm.

The composition prepared in Example 1 was applied onto the organic underlayer film by spin coating, and then heated at 215° C. for one minute, to thereby form a resist underlayer film (layer B) having a thickness of 20 nm.

An EUV resist solution (hydroxystyrene resin-based resist) was applied onto the resist underlayer film by spin coating, and then heated at 110° C. for 60 seconds, to thereby form an EUV resist film (layer C). The resist film was subjected to drawing (light exposure) with an EB drawing apparatus (ELS-G130) available from Elionix under the following conditions: exposure range of 200 to 800 uC/cm² with 40 uC/cm² step.

After completion of the drawing, post exposure bake (PEB, at 90° C. for 60 seconds) was performed, and then the resist film was cooled on a cooling plate to room temperature, followed by development with an alkaline developer (NMD-3, 2.38% aqueous tetramethylammonium hydroxide solution, available from TOKYO OHKA KOGYO CO., LTD.) for 30 seconds and rinsing treatment, to thereby form a resist pattern.

Each of the compositions prepared in Examples 2 to 10 and Comparative Examples 1 and 2 was used, and a resist pattern was formed through the same procedure as described above.

Each of the thus-formed resist patterns was evaluated for formation of a 25 nm line-and-space. In the pattern observation, evaluation “Good” was given to the case where pattern collapse did not occur in a relatively wide area even at a low exposure range, and no significant residue was generated; and evaluation “Collapse” was given to the case where pattern collapse occurred in a wide area.

Critical dimension SEM was used to determine the resist pattern dimension at the maximum exposure (limit exposure) at which a resist pattern did not collapse (i.e., pattern collapse threshold (min CD)).

In each of Examples 1 to 5 (corresponding to Comparative Example 1) or in each of Examples 6 to 10 (corresponding to Comparative Example 2), when the min CD was improved by 1 to 15% (a reduction in min CD by 1 to 15%) as compared with that in the corresponding Comparative Example, evaluation “Good” in the aforementioned pattern observation was changed to “Relatively good,” whereas when the min CD was improved by 15% or more (a reduction in min CD by 15% or more) as compared with that in the corresponding Comparative Example, evaluation “Good” in the aforementioned pattern observation was changed to “Better.”

The results are shown in Tables 4 to 6. Although the resist pattern formation conditions and evaluation methods are standardized as described above, some variations may occur depending on, for example, the apparatus environment. The results shown in each of Tables 4 to 6 correspond to those obtained by performing evaluations of Comparative Example and Example in parallel (in the same apparatus environment).

TABLE 4

| | Polysiloxane | | | Pattern |
|---|---|---|---|---|
| | | Reference: Group R- | | shape |
| | | derived carboxylic | min CD | (25 |
| | | acid compound* | (nm) | nmL/S) |
| Comparative | Comparative | Norbornenecarboxylic | 18.11 | Collapse |
| Example 1 | Synthesis | acid* | | |
| | Example 1 | | | |
| Example 1 | Synthesis | Norbornenecarboxylic | 16.43 | Good |
| | Example 1-1 | acid | | |

*In Comparative Synthesis Example 1, the polysiloxane was produced by addition of [2-(7-oxabicyclo[4.1.0]3-heptanyl)ethyl]trimethoxysilane and norbornenecarboxylic acid as monomers in place of the ester group-containing silane 1.

TABLE 5

| | Polysiloxane | | | Pattern |
|---|---|---|---|---|
| | | Reference: Group R- | | shape |
| | | derived carboxylic | min CD | (25 |
| | | acid compound* | (nm) | nmL/S) |
| Comparative | Comparative | Norbornenecarboxylic | 16.81 | Collapse |
| Example 1 | Synthesis | acid* | | |
| | Example 1 | | | |
| Example 2 | Synthesis | Phthalic acid | — | Good |
| | Example 1-2 | | | |
| Example 3 | Synthesis | Benzoic acid | 16.08 | Good |
| | Example 1-3 | | | |
| Example 4 | Synthesis | Norbornenecarboxylic | 16.06 | Good |
| | Example 1-4 | acid analog 1 | | |
| Example 5 | Synthesis | Norbornenecarboxylic | 16.26 | Good |
| | Example 1-5 | acid analog 2 | | |
| Example 1 | Synthesis | Norbornenecarboxylic | 15.39 | Good |
| | Example 1-1 | acid | | |

*In Comparative Synthesis Example 1, the polysiloxane was produced by addition of [2-(7-oxabicyclo[4.1.0]3-heptanyl)ethyl]trimethoxysilane and norbornenecarboxylic acid as monomers in place of the ester group-containing silane 1.

TABLE 6

| | Polysiloxane | | | Pattern |
|---|---|---|---|---|
| | | Reference: Group R- | min | shape |
| | | derived carboxylic | CD | (25 |
| | | acid compound* | (nm) | nmL/S) |
| Comparative | Comparative | Norbornenecarboxylic | 25.19 | Collapse |
| Example 2 | Synthesis | acid* | | |
| | Example 2 | | | |
| Example 6 | Synthesis | Norbornenecarboxylic | 23.65 | Good |
| | Example 2-1 | acid | | |
| Example 7 | Synthesis | 4-Pentynoic acid | 24.85 | Good |
| | Example 2-2 | | | |
| Example 8 | Synthesis | 5-Heptenoic acid | 20.75 | Better |
| | Example 2-3 | | | |
| Example 9 | Synthesis | Norbornenedicarboxylic | 21.52 | Good |
| | Example 2-4 | acid | | |
| Example 10 | Synthesis | Norbornenedicarboxylic | 21.48 | Good |
| | Example 2-5 | anhydride | | |

*In Comparative Synthesis Example 2, the polysiloxane was produced by addition of trimethoxy[3-(2-oxiranylmethoxy)propyl]silane and norbornenecarboxylic acid as monomers in place of the ester group-containing silane 6.

The results shown above in Tables 4 to 6 indicated that the resist underlayer film formed from each of the silicon-containing resist underlayer film-forming compositions of Examples 1 to 5 achieves a pattern collapse threshold of 20 nm or less in the resist pattern formed above the resist underlayer film, and the resist underlayer film formed from each of the silicon-containing resist underlayer film-forming compositions of Examples 6 to 10 achieves a pattern collapse threshold of 25 nm or less in the resist pattern formed above the resist underlayer film.

The results also indicated that each of the resist underlayer films enables formation of a good pattern in the resist film formed above the resist underlayer film without causing collapse of a pattern having a 25 nm line-and-space.

### INDUSTRIAL APPLICABILITY

The silicon-containing resist underlayer film-forming composition of the present invention can be used for fine processing by lithography using a photoresist in the production of a semiconductor device. In particular, the composition is effectively used for fine patterning in an extreme ultraviolet lithographic process.

1. A silicon-containing resist underlayer film-forming composition comprising:
[A] a polysiloxane containing a siloxane unit structure having an ester structure; and
[B] a solvent.

2. The silicon-containing resist underlayer film-forming composition according to claim 1, wherein the siloxane unit structure having an ester structure contained in the polysiloxane [A] has an ester structure formed by reaction between a hydroxy group and/or an epoxy group and a compound selected from the group consisting of a carboxylic acid, a dicarboxylic acid, and a dicarboxylic anhydride.

3. The silicon-containing resist underlayer film-forming composition according to claim 2, wherein the carboxylic acid, the dicarboxylic acid, and the dicarboxylic anhydride has at least one group selected from the group consisting of an alicyclic group, an aromatic ring group, a cyano group, an alkenyl group, and an alkynyl group.

4. The silicon-containing resist underlayer film-forming composition according to claim 1, wherein the amount of the siloxane unit structure having an ester structure contained in the polysiloxane [A] is 0.1% by mole to 10% by mole relative to the total amount by mole of all siloxane unit structures contained in the polysiloxane [A].

5. The silicon-containing resist underlayer film-forming composition according to claim 1, wherein the polysiloxane [A] further contains a siloxane unit structure having an organic group containing a quaternary ammonium nitrate structure.

6. The silicon-containing resist underlayer film-forming composition according to claim 1, wherein the polysiloxane [A] contains a hydrolysis condensate [I] containing a siloxane unit structure having an ester structure; and
the hydrolysis condensate [I] is a hydrolysis condensate of a hydrolyzable silane containing at least one hydrolyzable silane of the following Formula (1): 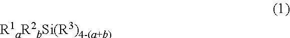
(wherein R¹ is a group bonded to the silicon atom and is of the following Formula (1-1): 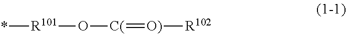
(in Formula (1-1), R¹⁰¹ is a C₂₋₂₀ alkylene group, C₆₋₁₂ arylene group, or combination of these that possibly contains an ether bond or is substitutable with a hydroxy group, and R¹⁰² is an organic group having at least one group selected from the group consisting of a substitutable alicyclic group, a substitutable aromatic ring group, a cyano group, an alkenyl group, and an alkynyl group);
R² is a group bonded to the silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an epoxy group, an acryloyl group, a methacryloyl group, a mercapto group, an amino group, an amide group, an alkoxy group, a sulfonyl group, or a cyano group, or any combination of these;
R³ is a group or atom bonded to the silicon atom, and is each independently an alkoxy group, an aralkyloxy group, an acyloxy group, or a halogen atom;
a is an integer of 1; b is an integer of 0 to 2; and a+b is an integer of 1 to 3).

7. The silicon-containing resist underlayer film-forming composition according to claim 6, wherein the amount of at least one hydrolyzable silane of Formula (1) contained in the hydrolyzable silane is 0.1% by mole to 10% by mole relative to the total amount by mole of all hydrolyzable silanes contained in the hydrolyzable silane.

8. The silicon-containing resist underlayer film-forming composition according to claim 6, wherein the polysiloxane [A] contains a hydrolysis condensate [I-1] containing a siloxane unit structure having an ester structure and a siloxane unit structure having an organic group containing a quaternary ammonium nitrate structure; and the hydrolysis condensate [I-1] is a hydrolysis condensate of a mixture of the hydrolyzable silane of Formula (1), a hydrolyzable silane containing a hydrolyzable silane of the following Formula (2) containing an amino group-containing organic group, and nitric acid: 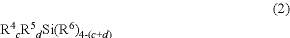
(wherein R⁴ is a group bonded to the silicon atom, and is an amino group-containing organic group;
R⁵ is a group bonded to the silicon atom, and is each independently a substitutable alkyl group, a substitutable aryl group, a substitutable aralkyl group, a substitutable halogenated alkyl group, a substitutable halogenated aryl group, a substitutable halogenated aralkyl group, a substitutable alkoxyalkyl group, a substitutable alkoxyaryl group, a substitutable alkoxyaralkyl group, or a substitutable alkenyl group, or an organic group containing an acryloyl group, a methacryloyl group, a mercapto group, an amino group, an amide group, an alkoxy group, a sulfonyl group, or a cyano group, or any combination of these;
R⁶ is a group or atom bonded to the silicon atom, and is each independently an alkoxy group, an aralkyloxy group, an acyloxy group, or a halogen atom;
c is an integer of 1; d is an integer of 0 to 2; and c+d is an integer of 1 to 3).

9. The silicon-containing resist underlayer film-forming composition according to claim 1, wherein the composition comprises a curing catalyst.

10. The silicon-containing resist underlayer film-forming composition according to claim 1, wherein the solvent [B] contains water.

11. The silicon-containing resist underlayer film-forming composition according to claim 1, wherein the composition further comprises a pH adjuster.

12. The silicon-containing resist underlayer film-forming composition according to claim 1, wherein the composition further comprises a metal oxide.

13. The silicon-containing resist underlayer film-forming composition according to claim 1, wherein the composition is used for formation of a resist underlayer film for EUV lithography.

14. A resist underlayer film, which is a cured product of the silicon-containing resist underlayer film-forming composition according to claim 1.

15. A semiconductor processing substrate comprising a semiconductor substrate and the resist underlayer film according to claim 14.

16. A semiconductor element production method comprising:
a step of forming an organic underlayer film on a substrate;
a step of forming, on the organic underlayer film, a silicon-containing resist underlayer film from the silicon-containing resist underlayer film-forming composition according to claim 1; and
a step of forming a resist film on the silicon-containing resist underlayer film.

17. The production method according to claim 16, wherein the step of forming a silicon-containing resist underlayer film involves the use of the silicon-containing resist underlayer film-forming composition subjected to filtration with a nylon filter.

18. A pattern formation method comprising:
a step of forming an organic underlayer film on a semiconductor substrate;
a step of applying, onto the organic underlayer film, the silicon-containing resist underlayer film-forming composition according to claim 1, and baking the composition, to thereby form a silicon-containing resist underlayer film;
a step of applying a resist film-forming composition onto the silicon-containing resist underlayer film, to thereby form a resist film;
a step of exposing the resist film to light, and developing the resist film, to thereby form a resist pattern;
a step of etching the silicon-containing resist underlayer film with the resist pattern as a mask; and
a step of etching the organic underlayer film with the patterned silicon-containing resist underlayer film as a mask.
